(19) United States
(12) Patent Application Publication
(10) Pub. No.: US 2023/0263058 A1
(43) Pub. Date: Aug. 17, 2023

(54) ORGANIC COMPOUND AND ORGANIC LIGHT-EMITTING ELEMENT

(71) Applicant: CANON KABUSHIKI KAISHA, Tokyo (JP)

(72) Inventors: HIROKI OHRUI, Tokyo (JP); JUN KAMATANI, Tokyo (JP); NAOKI YAMADA, Tokyo (JP); HIRONOBU IWAWAKI, Kanagawa (JP); YOSUKE NISHIDE, Kanagawa (JP); HIROKAZU MIYASHITA, Kanagawa (JP)

(21) Appl. No.: 18/168,148

(22) Filed: Feb. 13, 2023

(30) Foreign Application Priority Data
Feb. 15, 2022 (JP) 2022-021454

(51) Int. Cl. H10K 85/60; C07F 5/02; C09K 11/06

(52) U.S. Cl. CPC H10K 85/658; C07F 5/027; C09K 11/06; C09K 2211/1018; H10K 50/13

(57) ABSTRACT

An organic compound represented by the following general formula [1]:

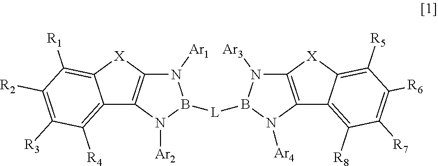

R₁ to R₈ are independently selected from the group consisting of a hydrogen atom, alkyl groups, and the like. Ar₁ to Ar₄ are independently selected from the group consisting of alkyl groups, aryl groups, and the like. L denotes a substituted or unsubstituted arylene group or the like. X is independently selected from the group consisting of an oxygen atom, a sulfur atom, and the like.

### BACKGROUND OF THE INVENTION

### Field of the Invention

The present disclosure relates to an organic compound and an organic light-emitting element including the organic compound.

### Description of the Related Art

An organic light-emitting element (hereinafter sometimes referred to as an “organic electroluminescent element” or an “organic EL element”) is an electronic element that includes a pair of electrodes and an organic compound layer between the electrodes. Electrons and holes are injected from the pair of electrodes to generate an exciton of a light-emitting organic compound in the organic compound layer. When the exciton returns to its ground state, the organic light-emitting element emits light. With recent significant advances in organic light-emitting elements, it is possible to realize low drive voltage, various emission wavelengths, high-speed responsivity, and thin and light light-emitting devices.

sRGB and Adobe RGB standards are used for a color reproduction range for displays, and materials for reproducing these standards have been studied. BT-2020 has recently been proposed as a standard to further expand the color reproduction range.

Light-emitting organic compounds have been actively developed. This is because the development of compounds with good emission properties is important for high-performance organic light-emitting elements.

International Publication No. WO 2010/108579 (PTL 1) describes the following compound 1-a:

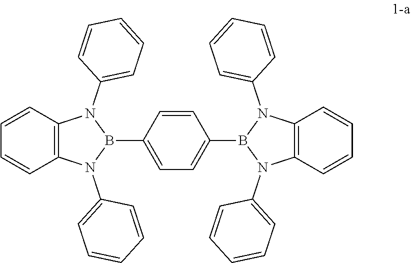 [SMILES: c1ccc(N2B(c3ccc(B4N(c5ccccc5)c5ccccc5N4c4ccccc4)cc3)N(c3ccccc3)c3ccccc32)cc1]

PTL 1 discloses a synthesis example of the compound 1-a but does not describe light emission efficiency or emission color. Furthermore, in consideration of the color reproduction range of blue corresponding to the sRGB, Adobe RGB, and BT2020 standard, further improvement of the color purity of blue light emission is desired. Further improvement of color purity or durability is desired for organic light-emitting elements including these compounds.

### SUMMARY OF THE INVENTION

In view of these problems, the present disclosure provides a blue-light-emitting material with high light emission efficiency and color purity. The present disclosure also provides an organic light-emitting element with high color purity and light emission efficiency.

An organic compound according to the present disclosure is represented by the following general formula [1]:

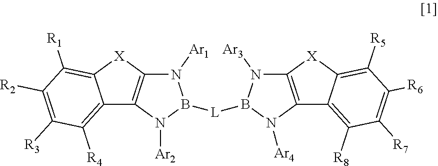

wherein R₁ to R₈ are independently selected from the group consisting of a hydrogen atom, halogen atoms, substituted and unsubstituted alkyl groups, substituted and unsubstituted alkoxy groups, substituted and unsubstituted amino groups, substituted and unsubstituted aryl groups, substituted and unsubstituted aryloxy groups, substituted and unsubstituted heteroaryl groups, substituted and unsubstituted heteroaryloxy groups, cyano groups, substituted and unsubstituted silyl groups, and a deuterium atom,

Ar₁ to Ar₄ are independently selected from the group consisting of substituted and unsubstituted alkyl groups, substituted and unsubstituted aryl groups, and substituted and unsubstituted heteroaryl groups,

L denotes a substituted or unsubstituted arylene group or a substituted or unsubstituted heteroarylene group, and

X is independently selected from the group consisting of an oxygen atom, a sulfur atom, a selenium atom, a tellurium atom, N(Z), and C(W₁)(W₂), wherein Z is independently selected from the group consisting of a hydrogen atom, substituted and unsubstituted alkyl groups, substituted and unsubstituted aryl groups, substituted and unsubstituted heteroaryl groups, and a deuterium atom, and W₁ and W₂ are independently selected from the group consisting of a hydrogen atom, substituted and unsubstituted alkyl groups, substituted and unsubstituted aryl groups, substituted and unsubstituted heteroaryl groups, and a deuterium atom.

Further features of the present disclosure will become apparent from the following description of exemplary embodiments with reference to the attached drawings.

### BRIEF DESCRIPTION OF THE DRAWINGS

FIG. 1 is a table showing the value of LUMO obtained by molecular orbital calculation and the electron orbital of LUMO and HOMO, according to one or more embodiment of the subject innovation.

FIG. 2A is a schematic cross-sectional view of an example of a pixel of a display apparatus according to an embodiment of the present disclosure.

FIG. 2B is a schematic cross-sectional view of an example of a display apparatus including an organic light-emitting element according to an embodiment of the present disclosure.

FIG. 3 is a schematic view of an example of a display apparatus according to an embodiment of the present disclosure.

FIG. 4A is a schematic view of an example of an imaging apparatus according to an embodiment of the present disclosure.

FIG. 4B is a schematic view of an example of electronic equipment according to an embodiment of the present disclosure.

FIG. 5A is a schematic view of an example of a display apparatus according to an embodiment of the present disclosure.

FIG. 5B is a schematic view of an example of a foldable display apparatus.

FIG. 6A is a schematic view of an example of a lighting apparatus according to an embodiment of the present disclosure.

FIG. 6B is a schematic view of an example of a moving body with a vehicle lamp according to an embodiment of the present disclosure.

FIG. 7A is a schematic view of an example of a wearable device according to an embodiment of the present disclosure.

FIG. 7B is a schematic view of another example of a wearable device according to an embodiment of the present disclosure.

FIG. 8A is a schematic view of an example of an image-forming apparatus according to an embodiment of the present disclosure.

FIG. 8B is a schematic view of an example of an exposure light source of an image-forming apparatus according to an embodiment of the present disclosure.

FIG. 8C is a schematic view of an example of an exposure light source of an image-forming apparatus according to an embodiment of the present disclosure.

### DESCRIPTION OF THE EMBODIMENTS

<<Organic Compound>>

An organic compound according to the present embodiment is represented by the following general formula [1].

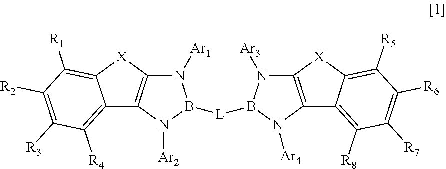

<R₁ to R₈>

In the general formula [1], R₁ to R₈ are independently selected from the group consisting of a hydrogen atom, halogen atoms, substituted and unsubstituted alkyl groups, substituted and unsubstituted alkoxy groups, substituted and unsubstituted amino groups, substituted and unsubstituted aryl groups, substituted and unsubstituted aryloxy groups, substituted and unsubstituted heteroaryl groups, substituted and unsubstituted heteroaryloxy groups, cyano groups, substituted and unsubstituted silyl groups, and a deuterium atom.

Examples of the halogen atoms include, but are not limited to, fluorine, chlorine, bromine, and iodine.

Examples of the alkyl groups include, but are not limited to, a methyl group, an ethyl group, a n-propyl group, an isopropyl group, a n-butyl group, a t-butyl group, a sec-butyl group, an octyl group, a cyclohexyl group, a 1-adamantyl group, and a 2-adamantyl group. Among these, an alkyl group having 1 to 10 carbon atoms can be used.

Examples of the alkoxy groups include, but are not limited to, a methoxy group, an ethoxy group, a propoxy group, a 2-ethyl-octyloxy group, and a benzyloxy group. Among these, an alkoxy group having 1 to 6 carbon atoms can be used.

Examples of the amino groups include, but are not limited to, an N-methylamino group, an N-ethylamino group, an N,N-dimethylamino group, an N,N-diethylamino group, an N-methyl-N-ethylamino group, an N-benzylamino group, an N-methyl-N-benzylamino group, an N,N-dibenzylamino group, an anilino group, an N,N-diphenylamino group, an N,N-dinaphthylamino group, an N,N-difluorenylamino group, an N-phenyl-N-tolylamino group, an N,N-ditolylamino group, an N-methyl-N-phenylamino group, an N,N-dianisolylamino group, an N-mesityl-N-phenylamino group, an N,N-dimesitylamino group, an N-phenyl-N-(4-t-butylphenyl)amino group, an N-phenyl-N-(4-trifluoromethylphenyl)amino group, and an N-piperidyl group.

Examples of the aryl groups include, but are not limited to, a phenyl group, a naphthyl group, an indenyl group, a biphenyl group, a terphenyl group, a fluorenyl group, a phenanthryl group, and a triphenylenyl group. Among these, an aryl group having 6 to 18 carbon atoms can be used.

Examples of the heteroaryl groups include, but are not limited to, a pyridyl group, a pyrazinyl group, a pyrimidinyl group, a triazinyl group, a quinolyl group, an isoquinolyl group, an oxazolyl group, a thiazolyl group, an imidazolyl group, a benzoxazolyl group, a benzothiazolyl group, a benzimidazolyl group, a thienyl group, a furanyl group, a pyrrolyl group, a benzothienyl group, a benzofuranyl group, an indolyl group, a dibenzothiophenyl group, and a dibenzofuranyl group. Among these, a heteroaryl group having 3 to 15 carbon atoms can be used.

Examples of the aryloxy groups and the heteroaryloxy groups include, but are not limited to, a phenoxy group and a thienyloxy group. Among these, an aryloxy group having 6 to 18 carbon atoms and a heteroaryloxy group having 3 to 15 carbon atoms can be used.

Examples of the silyl groups include, but are not limited to, a trimethylsilyl group and a triphenylsilyl group.

Examples of optional substituents of the alkyl groups, the alkoxy groups, the amino groups, the aryl groups, the aryloxy groups, the heteroaryl groups, the heteroaryloxy groups, and the silyl groups include, but are not limited to, alkyl groups, such as a methyl group, an ethyl group, a n-propyl group, an isopropyl group, a n-butyl group, and a t-butyl group; aralkyl groups, such as a benzyl group; aryl groups, such as a phenyl group and a biphenyl group; amino groups, such as a dimethylamino group, a diethylamino group, a dibenzylamino group, a diphenylamino group, and a ditolylamino group; alkoxy groups, such as a methoxy group, an ethoxy group, and a propoxy group; aryloxy groups, such as a phenoxy group; halogen atoms, such as fluorine, chlorine, bromine, and iodine; and a thienyl group, a thiol group, and a cyano group.

<Ar₁ to Ar₄>

In the general formula [1], Ar₁ to Ar₄ are independently selected from the group consisting of substituted and unsubstituted alkyl groups, substituted and unsubstituted aryl groups, and substituted and unsubstituted heteroaryl groups.

Examples of the alkyl groups include, but are not limited to, a methyl group, an ethyl group, a n-propyl group, an isopropyl group, a n-butyl group, a t-butyl group, a sec-butyl group, an octyl group, a cyclohexyl group, a 1-adamantyl group, and a 2-adamantyl group. Among these, an alkyl group having 1 to 10 carbon atoms can be used.

Examples of the aryl groups include, but are not limited to, a phenyl group, a naphthyl group, an indenyl group, a biphenyl group, a terphenyl group, a fluorenyl group, a phenanthryl group, and a triphenylenyl group.

Examples of the heteroaryl groups include, but are not limited to, a pyridyl group, a pyrazinyl group, a pyrimidinyl group, a triazinyl group, a quinolyl group, an isoquinolyl group, an oxazolyl group, a thiazolyl group, an imidazolyl group, a benzoxazolyl group, a benzothiazolyl group, a benzimidazolyl group, a thienyl group, a furanyl group, a pyrrolyl group, benzothienyl group, benzofuranyl group, an indolyl group, a dibenzothiophenyl group, and a dibenzofuranyl group.

Specific examples of optional substituents of the alkyl groups, the aryl groups, and the heteroaryl groups include, but are not limited to, those described for R₁ to R₈.

<L>

In the general formula [1], L denotes a substituted or unsubstituted arylene group or a substituted or unsubstituted heteroarylene group.

Examples of the arylene group include, but are not limited to, divalent groups derived from a phenyl group, a naphthyl group, an indenyl group, a biphenyl group, a terphenyl group, a fluorenyl group, a phenanthryl group, and a triphenylenyl group.

Examples of the heteroarylene group include, but are not limited to, divalent groups derived from a pyridyl group, a pyrazinyl group, a pyrimidinyl group, a triazinyl group, a quinolyl group, an isoquinolyl group, an oxazolyl group, a thiazolyl group, an imidazolyl group, a benzoxazolyl group, a benzothiazolyl group, a benzimidazolyl group, a thienyl group, a furanyl group, a pyrrolyl group, a benzothienyl group, a benzofuranyl group, an indolyl group, a dibenzothiophenyl group, and a dibenzofuranyl group.

Specific examples of optional substituents of the arylene groups and the heteroarylene groups include, but are not limited to, those described for R₁ to R₈.

<X>

In the general formula [1], X is independently selected from the group consisting of an oxygen atom, a sulfur atom, a selenium atom, a tellurium atom, N(Z), and C(W₁)(W₂). Xs may be the same or different.

[Z]

Z is independently selected from the group consisting of a hydrogen atom, substituted and unsubstituted alkyl groups, substituted and unsubstituted aryl groups, substituted and unsubstituted heteroaryl groups, and a deuterium atom.

Examples of the alkyl groups include, but are not limited to, a methyl group, an ethyl group, a n-propyl group, an isopropyl group, a n-butyl group, a t-butyl group, a sec-butyl group, an octyl group, a cyclohexyl group, a 1-adamantyl group, and a 2-adamantyl group. Among these, an alkyl group having 1 to 10 carbon atoms can be used.

Examples of the aryl groups include, but are not limited to, a phenyl group, a naphthyl group, an indenyl group, a biphenyl group, a terphenyl group, a fluorenyl group, a phenanthryl group, and a triphenylenyl group. Among these, an aryl group having 6 to 18 carbon atoms can be used.

Examples of the heteroaryl groups include, but are not limited to, a pyridyl group, a pyrazinyl group, a pyrimidinyl group, a triazinyl group, a quinolyl group, and an isoquinolyl group. Among these, a heteroaryl group having 3 to 15 carbon atoms can be used.

Specific examples of optional substituents of the alkyl groups, the aryl groups, and the heteroaryl groups include, but are not limited to, those described for R₁ to R₈.

[W₁ and W₂]

W₁ and W₂ are independently selected from the group consisting of a hydrogen atom, substituted and unsubstituted alkyl groups, substituted and unsubstituted aryl groups, substituted and unsubstituted heteroaryl groups, and a deuterium atom.

Examples of the alkyl groups include, but are not limited to, a methyl group, an ethyl group, a n-propyl group, an isopropyl group, a n-butyl group, a t-butyl group, a sec-butyl group, an octyl group, a cyclohexyl group, a 1-adamantyl group, and a 2-adamantyl group. Among these, an alkyl group having 1 to 10 carbon atoms can be used.

Examples of the aryl groups include, but are not limited to, a phenyl group, a naphthyl group, an indenyl group, a biphenyl group, a terphenyl group, a fluorenyl group, a phenanthryl group, and a triphenylenyl group. Among these, an aryl group having 6 to 18 carbon atoms can be used.

Examples of the heteroaryl groups include, but are not limited to, a pyridyl group, a pyrazinyl group, a pyrimidinyl group, a triazinyl group, a quinolyl group, and an isoquinolyl group. Among these, a heteroaryl group having 3 to 15 carbon atoms can be used.

Specific examples of optional substituents of the alkyl groups, the aryl groups, and the heteroaryl groups include, but are not limited to, those described for R₁ to R₈.

<Preferred Compounds>

The organic compounds according to the present embodiment particularly include organic compounds represented by the following general formulae [2-1] to [5-2].

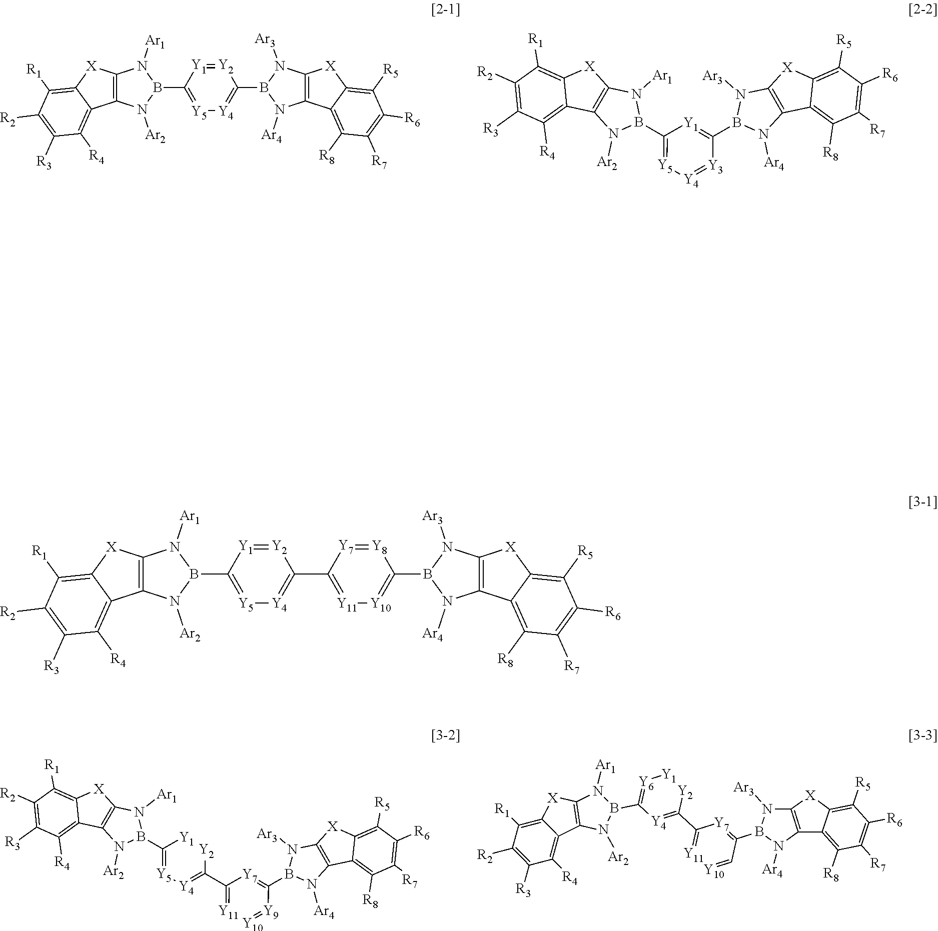

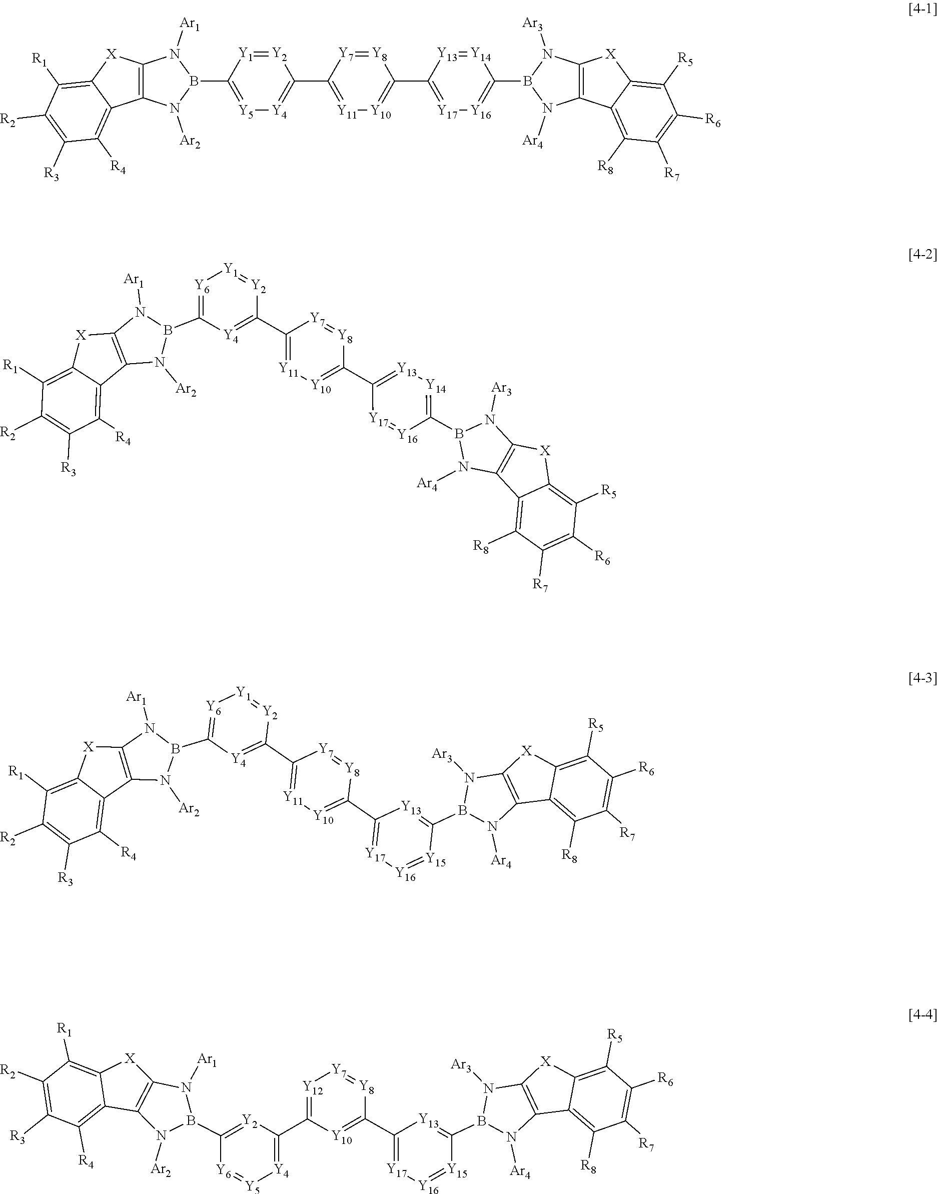

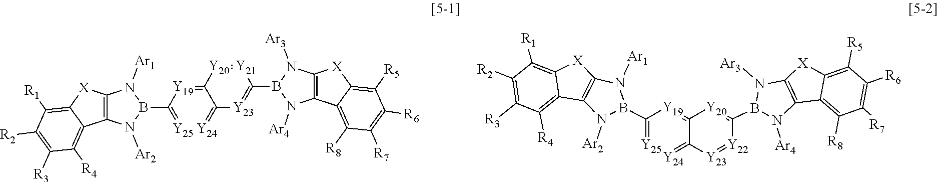

[Y₁ to Y₁₇, Y₁₉ to Y₂₅]

In the general formulae [2-1] to [5-2], Y₁ to Y₁₇ and Y₁₉ to Y₂₅ are independently selected from the group consisting of C(A) and a nitrogen atom.

In the general formula [3-1], [3-2], or [3-3], when Y₂ and Y₇, and Y₄ and Y₁₁ are C(A), A's are optionally bonded together to form a ring.

In the general formula [4-1], [4-2], or [4-3], when Y₂ and Y₇, Y₄ and Y₁₁, Y₈ and Y₁₃, and Y₁₀ and Y₁₇ are C(A), A's are optionally bonded together to form a ring. In the general formula [4-4], when Y₂ and Y₁₂, Y₄ and Y₁₀, Y₈ and Y₁₃, and Y₁₀ and Y₁₇ are C(A), A's are optionally bonded together to form a ring.

{A}

A is independently selected from the group consisting of a hydrogen atom, halogen atoms, substituted and unsubstituted alkyl groups, substituted and unsubstituted aryl groups, substituted and unsubstituted heteroaryl groups, cyano groups, substituted and unsubstituted silyl groups, and a deuterium atom.

Specific examples of the halogen atoms, alkyl groups, aryl groups, heteroaryl groups, and silyl groups include, but are not limited to, those described for R₁ to R₈. Specific examples of optional substituents of the alkyl groups, the aryl groups, the heteroaryl groups, and the silyl groups include, but are not limited to, those described for R₁ to R₈.

Organic compounds represented by the following general formulae [6] to [14] can also be used.

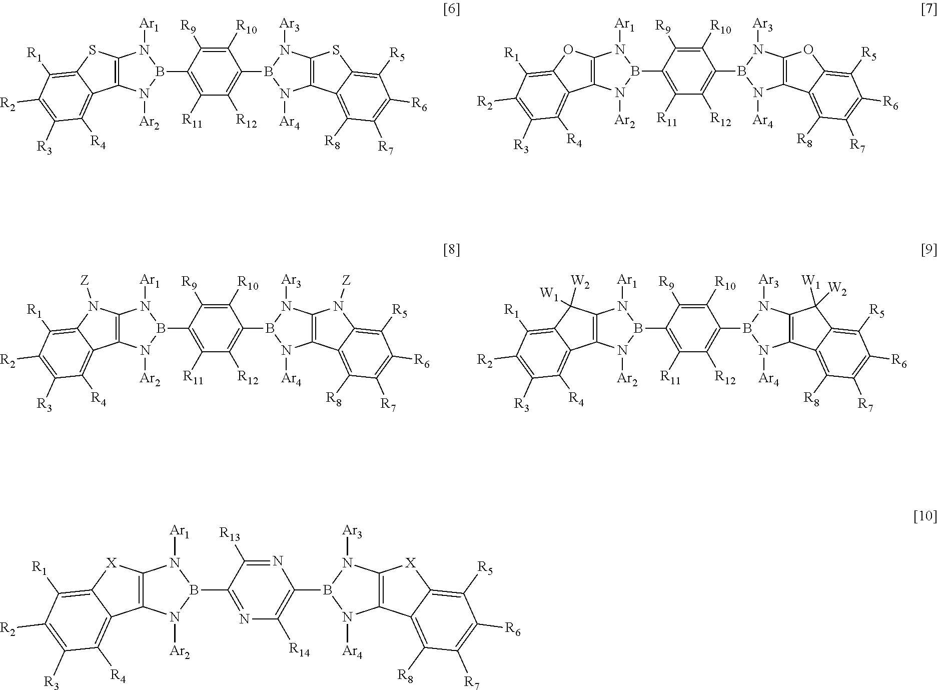

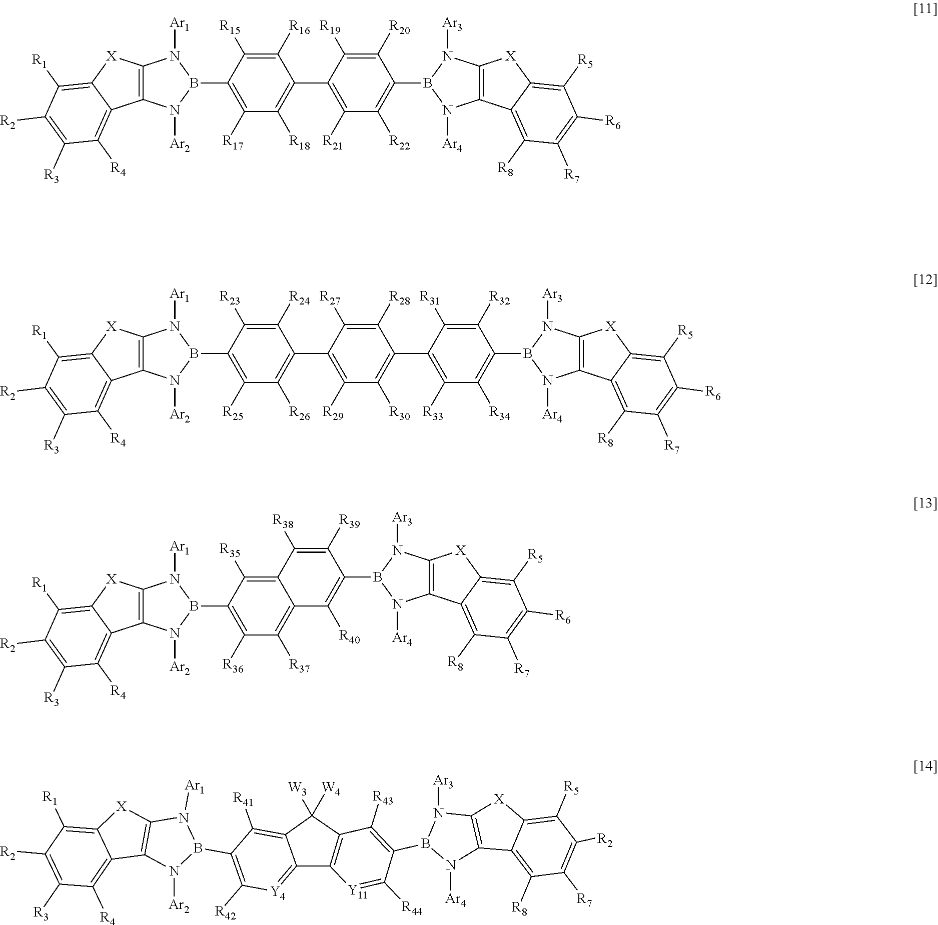

[R₉ to R₄₄]

In the general formulae [6] to [14], R₉ to R₄₄ are independently selected from the group consisting of a hydrogen atom, halogen atoms, substituted and unsubstituted alkyl groups, substituted and unsubstituted aryl groups, substituted and unsubstituted heteroaryl groups, cyano groups, substituted and unsubstituted silyl groups, and a deuterium atom.

Specific examples of the halogen atoms, alkyl groups, aryl groups, heteroaryl groups, and silyl groups include, but are not limited to, those described for R₁ to R₈. Specific examples of optional substituents of the alkyl groups, the aryl groups, the heteroaryl groups, and the silyl groups include, but are not limited to, those described for R₁ to R₈.

In the general formula [11], R₁₆ and R₁₉, and R₁₈ and R₂₁ are optionally bonded together to form a ring.

In the general formula [12], R₂₄ and R₂₇, R₂₆ and R₂₉, R₂₈ and R₃₁, and R₃₀ and R₃₃ are optionally bonded together to form a ring.

[W₃ and W₄]

In the general formula [14], W₃ and W₄ are independently selected from the group consisting of a hydrogen atom, substituted and unsubstituted alkyl groups, substituted and unsubstituted aryl groups, substituted and unsubstituted heteroaryl groups, and a deuterium atom.

Specific examples of the alkyl groups, aryl groups, and heteroaryl groups include, but are not limited to, those described for R₁ to R₈. Specific examples of optional substituents of the alkyl groups, the aryl groups, and the heteroaryl groups include, but are not limited to, those described for R₁ to R₈.

<Synthesis Method>

Next, a method for synthesizing an organic compound according to the present embodiment is described. For example, an organic compound according to the present embodiment is synthesized through the following synthetic route.

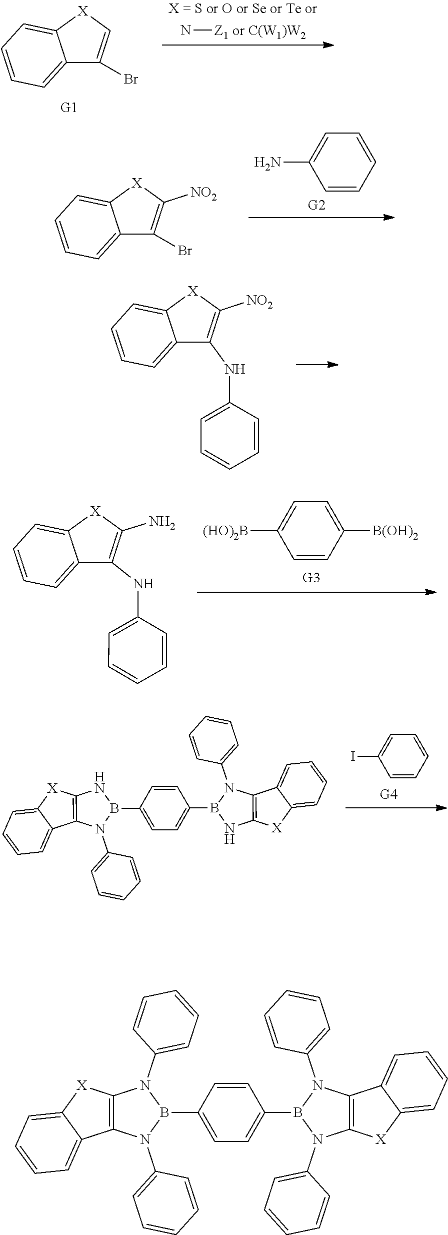

A compound represented by the general formula [1] can be prepared by appropriately changing G1 to G4. The synthesis method is described in detail in exemplary embodiments.

<Characteristics>

An organic compound according to the present embodiment has the following characteristics and has high light emission efficiency and color purity. Furthermore, an organic compound according to the present embodiment can be used to provide an organic light-emitting element with high color purity and light emission efficiency.

(1) The basic skeleton has an emission wavelength in a blue region, which results in high color purity and light emission efficiency.
(2) The organic compound has a low LUMO level and therefore has high stability against oxygen and high durability.

With respect to these characteristics, the properties of the basic skeleton of an organic compound according to the present embodiment are described below in comparison with a comparative compound with a structure similar to the structure of an organic compound according to the present embodiment.

(1) The basic skeleton has an emission wavelength in a blue region, which results in high color purity and light emission efficiency.

In the disclosure of an organic compound represented by the general formula [1], the present inventors have focused on the basic skeleton.

First, for blue light emission with high color purity, the basic skeleton can have high color purity in the blue region. In the present embodiment, the desired emission wavelength region is a blue region with high color purity. More specifically, when the emission intensity at the maximum emission wavelength in a dilute solution is 1.0, the intensity ratio at 460 nm is 0.3 or more. The basic skeleton in the present embodiment is a skeleton suitable for desired blue light emission.

In Table 1, the wavelength in the lowest excited singlet state (S₁) obtained by molecular orbital calculation and the emission spectrum in a dilute toluene solution are compared between exemplary compounds A1, A7, A10, and A13 according to the present embodiment and a comparative compound 1-a. More specifically, after the emission spectrum was measured, the emission intensity at 460 nm was compared on the basis of the maximum emission intensity of 1.0. The emission wavelength was measured by photoluminescence measurement of a dilute toluene solution using F-4500 manufactured by Hitachi, Ltd. at room temperature and at an excitation wavelength of 350 nm.

TABLE 1

| | | S1 (cal.) | PL intensity ratio |
|---|---|---|---|
| | Structural formula | [nm] | @460 nm |
| Exemplary compound A1 | 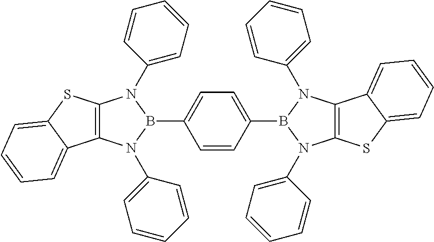 [SMILES: c1ccc(N2B(c3ccc(B4N(c5ccccc5)c5sc6ccccc6c5N4c4ccccc4)cc3)N(c3ccccc3)c3c2sc2ccccc32)cc1] | 361 | 0.5 |
| Exemplary compound A7 | 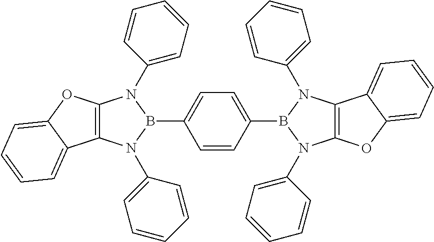 [SMILES: c1ccc(N2B(c3ccc(B4N(c5ccccc5)c5oc6ccccc6c5N4c4ccccc4)cc3)N(c3ccccc3)c3c2oc2ccccc32)cc1] | 348 | 0.3 |
| Exemplary compound A10 | 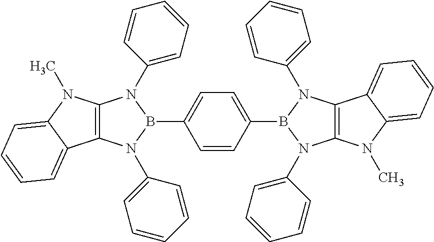 [SMILES: Cn1c2c(c3ccccc31)N(c1ccccc1)B(c1ccc(B3N(c4ccccc4)c4c(n(C)c5ccccc45)N3c3ccccc3)cc1)N2c1ccccc1] | 392 | 0.4 |
| Exemplary compound A13 | 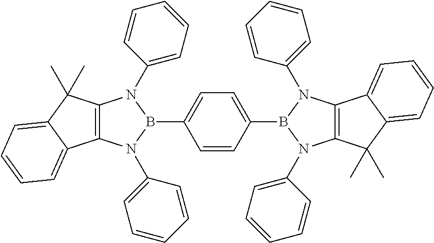 [SMILES: CC1(C)C2=C(c3ccccc31)N(c1ccccc1)B(c1ccc(B3N(c4ccccc4)C4=C(N3c3ccccc3)C(C)(C)c3ccccc34)cc1)N2c1ccccc1] | 370 | 0.6 |
| Comparative compound 1-a | 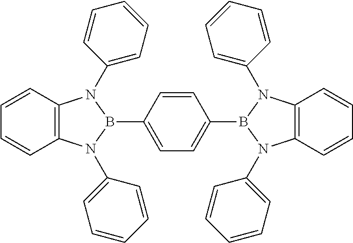 [SMILES: c1ccc(N2B(c3ccc(B4N(c5ccccc5)c5ccccc5N4c4ccccc4)cc3)N(c3ccccc3)c3ccccc32)cc1] | 316 | <0.1 |

Table 1 shows that the compounds of the present embodiment, which are diazaborole derivatives with a fused-ring structure, have a longer S₁ wavelength than the comparative compound 1-a. Furthermore, the emission (PL) intensity at 460 nm, which is a wavelength required for a blue emission wavelength with high color purity, was less than 0.1 in the comparative compound 1-a due to the shorter emission wavelength and 0.3 or more in the compounds according to the present embodiment.

Thus, the compounds according to the present embodiment have a longer emission wavelength and efficiently emit light in the blue region with high color purity. As described above, it has been found that the diazaborole derivatives with the fused-ring structure characteristically emit blue light with high color purity and efficiency.

The LUMO energy, electron orbital distribution, and S₁ energy were visualized by molecular orbital calculation. The calculation method in the molecular orbital calculation method utilized a widely used density functional theory (DFT). B3LYP was used as the functional, and 6-31G* was used as the basis function. The molecular orbital calculation method was performed using widely used Gaussian 09 (Gaussian 09, Revision C. 01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford Conn., 2010.). This method was used for the molecular orbital calculation described in the present specification.

(2) The organic compound has a low LUMO level and therefore has high stability against oxygen and high durability.

In organic semiconductors, with similar band gaps, compounds with a lower HOMO-LUMO level (farther from the vacuum level) have higher stability against oxygen. Thus, lowering the LUMO energy level increases stability against oxygen and improves the durability of the compound itself and the durability of an organic light-emitting element.

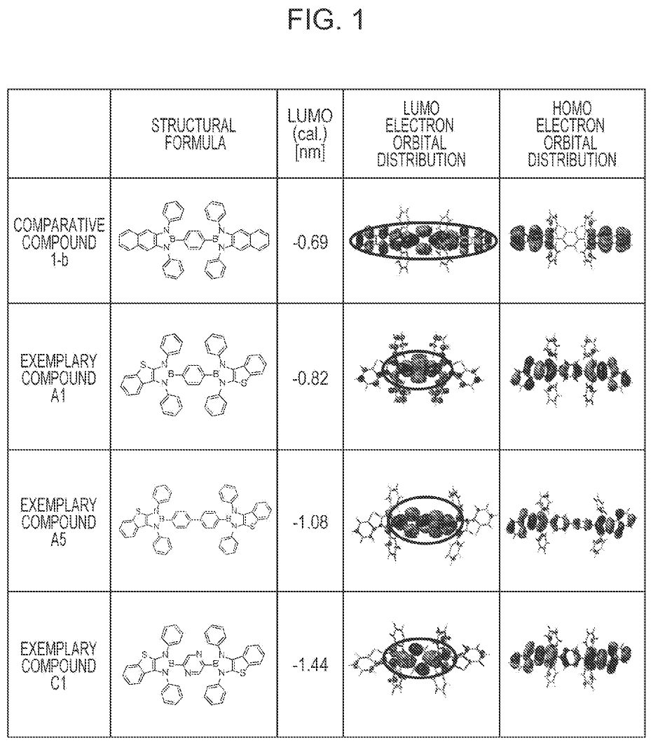

Thus, the present inventors have focused on LUMO. In FIG. 1, the value of LUMO obtained by the molecular orbital calculation and the electron orbital of LUMO and HOMO are compared between the exemplary compounds A1, A5, and C1 according to the present embodiment and a comparative compound 1-b in which benzene rings are condensed in the major-axis direction of the comparative compound 1-a. In the following description, the comparative compound 1-b is used instead of the comparative compound 1-a for comparison based on the same number of π electrons condensed to a cyclic diazaborole skeleton.

In FIG. 1, the orbital distribution of LUMO in the compounds of the present embodiment is less in the aromatic rings in the end portions in the major-axis direction than in the comparative compound 1-b and is localized near the center of the molecule containing two electron-withdrawing boron atoms. Thus, it has been found that the compounds according to the present embodiment are more influenced by the boron atoms and characteristically have a lower LUMO (farther from the vacuum level).

The comparative compound 1-b has a skeleton in which 10 π electrons derived from naphthalene are condensed to a cyclic diazaborole skeleton, and the exemplary compound A1, which is a compound according to the present embodiment, has a skeleton in which 10 π electrons derived from benzothiophene are condensed to a cyclic diazaborole skeleton. Thus, the comparative compound 1-b and the exemplary compound A1 have the same number of π electrons acting on the diazaborole skeleton. However, as described above, in the compounds according to the present embodiment, the LUMO molecular orbital is less distributed around benzothiophene in the end portions in the major-axis direction. Thus, in the compounds according to the present embodiment, the 10 π electrons derived from benzothiophene have little influence on LUMO and, by localizing near the center of the molecule containing two boron atoms, can maintain the electron-withdrawing ability derived from the boron atoms and can realize a low LUMO.

The exemplary compound A5 has two benzene rings as L between two boron atoms and has a structure in which one benzene ring is added to the central portion of the molecular structure of the exemplary compound A1. Like the exemplary compound A1, the exemplary compound A5 has a LUMO molecular orbital localized at the center of the molecule including the two boron atoms. The exemplary compound C1 has an electron-withdrawing group pyrazine as L connecting two boron atoms and, like the exemplary compound A1, has a LUMO molecular orbital localized at the center of the molecule including the two boron atoms.

The organic compounds according to the present embodiment have a low LUMO and therefore have high stability against oxygen. When an organic compound according to the present embodiment is used as a guest in a light-emitting layer of an organic light-emitting element, in particular, a material with a higher LUMO than the organic compound according to the present embodiment (a material with a LUMO closer to the vacuum level) can be used as a host. As shown in the exemplary compounds, an organic compound according to the present embodiment has an orbital distribution of LUMO localized near the center of the molecule and not extending to the end portions in the major-axis direction. Thus, an organic compound according to the present embodiment has a structure in which an electron received by a guest is rarely transmitted to another molecule, and increases the probability of recombination between a hole and an electron in a light-emitting layer and improves light emission efficiency. Furthermore, an organic compound according to the present embodiment has a low LUMO and, when used in an organic light-emitting element, also improves stability against oxygen and durability.

On the other hand, in the comparative compound 1-b, when a material with a higher LUMO is also used as a host, due to the orbital distribution of LUMO uniformly distributed in the major-axis direction, an electron received by a guest is easily transmitted to another molecule, and it is difficult to retain the electron in a light-emitting layer, resulting in a decrease in the light emission efficiency. Furthermore, the comparative compound 1-b has a higher LUMO than the exemplary compounds and has lower stability against oxygen and lower durability.

Furthermore, with respect to the electron orbital of HOMO, the exemplary compounds A1, A5, and C1 have a uniform distribution in the major-axis direction, but the comparative compound 1-b has no orbital in a portion containing two boron atoms and a benzene ring between the two boron atoms, which is significantly different from the orbital distribution of LUMO. Thus, the emission spectrum shows an emission spectrum derived from intramolecular CT and has a wider half-value width, and it is difficult to increase color purity. On the other hand, in organic compounds according to the present embodiment exemplified by the exemplary compounds A1, A5, and C1, although there is a difference in electron orbital between HOMO and LUMO, both the HOMO and LUMO have an electron orbital on the diazaborole structure. Thus, the organic compounds according to the present embodiment can have a small structural change between the ground state and the excited state, a narrow half-value width in the emission spectrum, and high color purity.

As described above, the organic compounds according to the present embodiment have the properties (1) and (2), efficiently emit blue light with higher color purity than the comparative compounds, have a lower LUMO, and are chemically stable. Thus, an organic compound according to the present embodiment can be used to provide an organic light-emitting element with high color purity, light emission efficiency, and durability.

### SPECIFIC EXAMPLES

Specific examples of an organic compound according to the present embodiment are described below. However, the present embodiment is not limited to these examples.

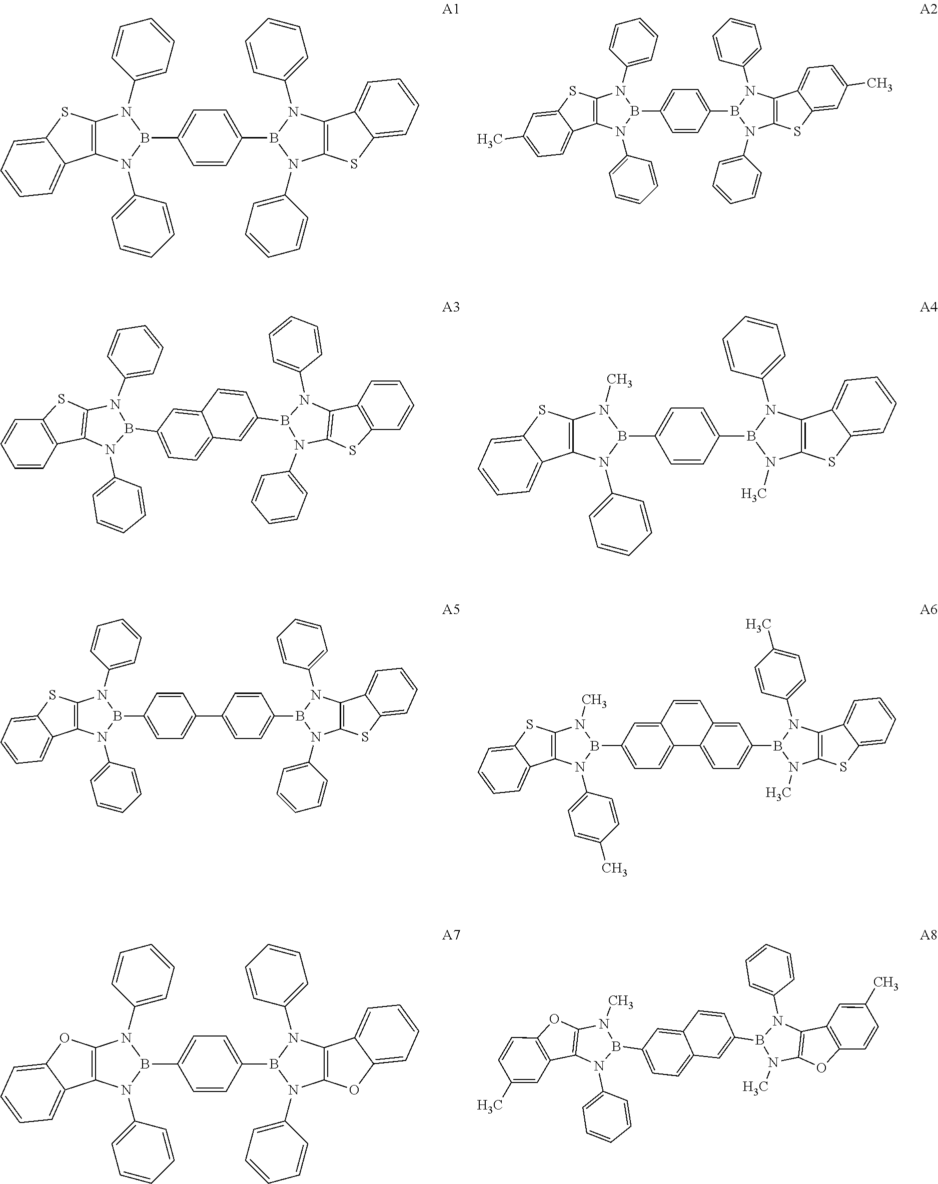

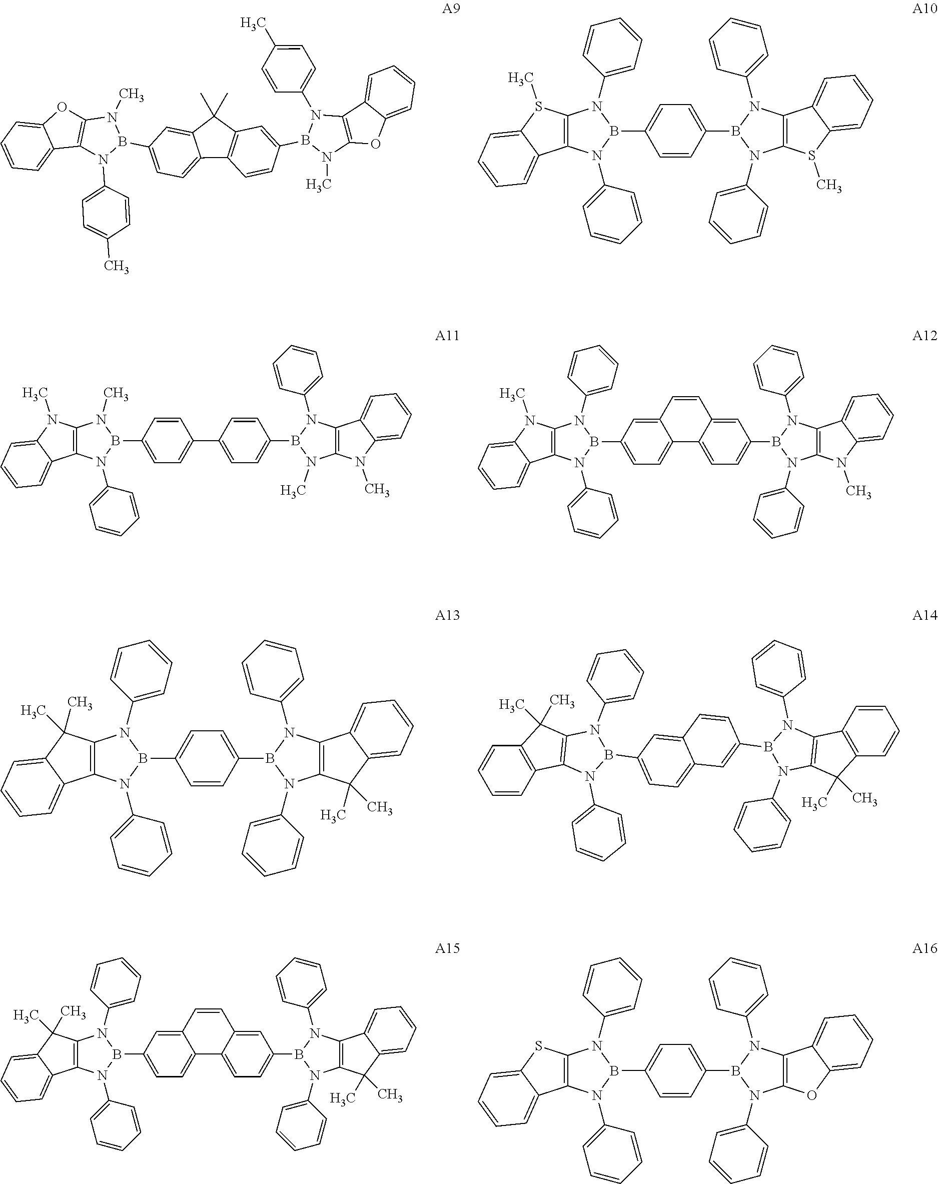

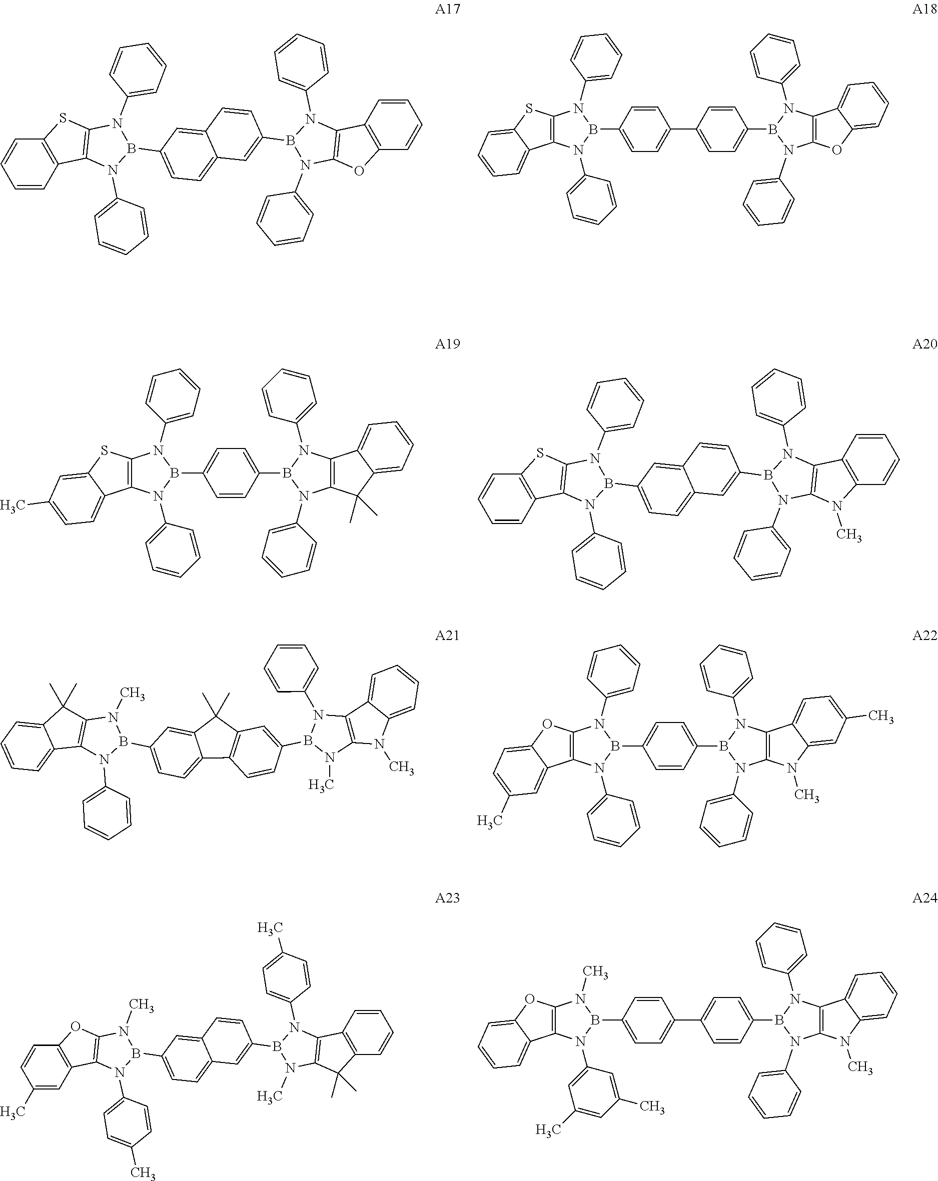

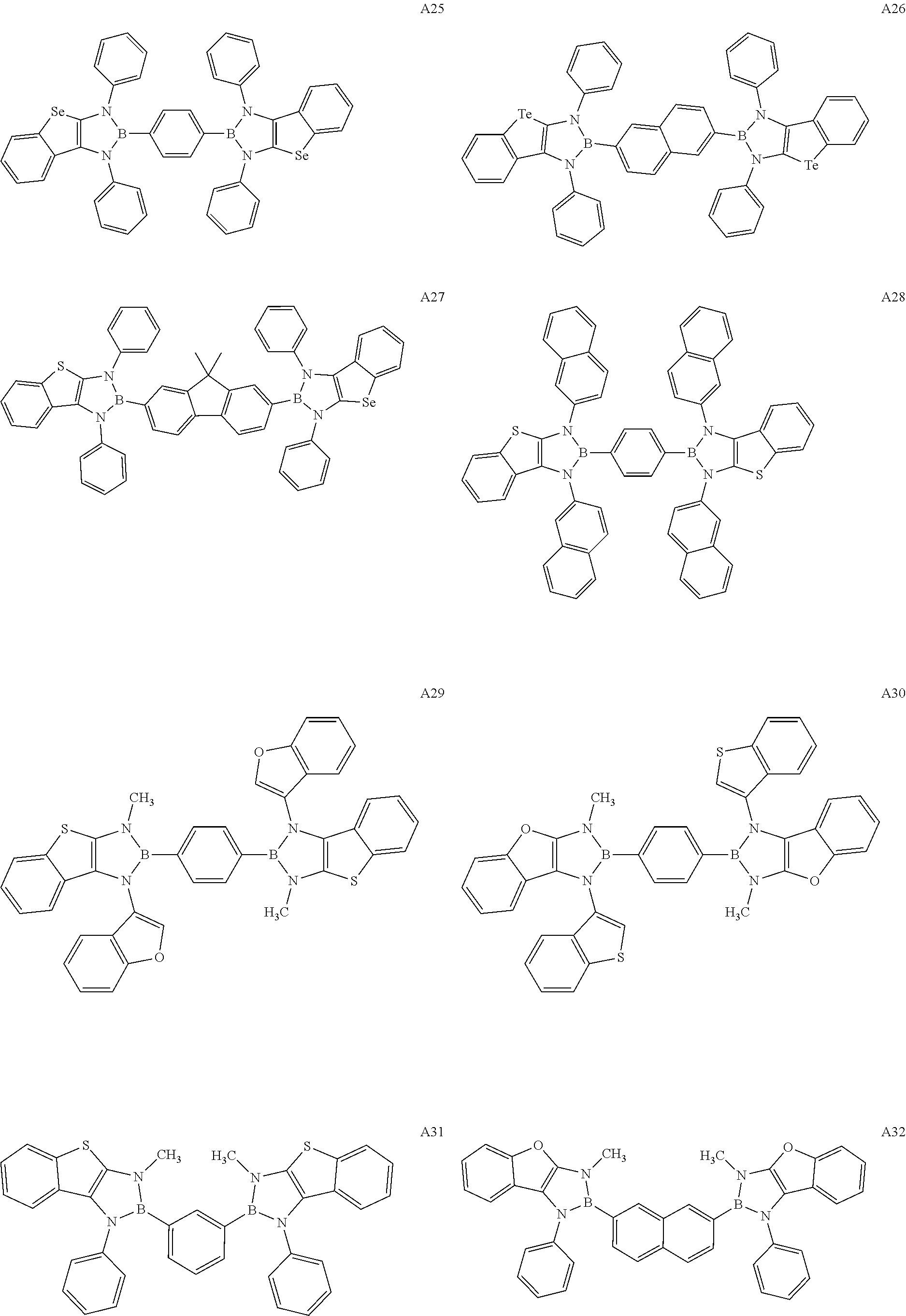

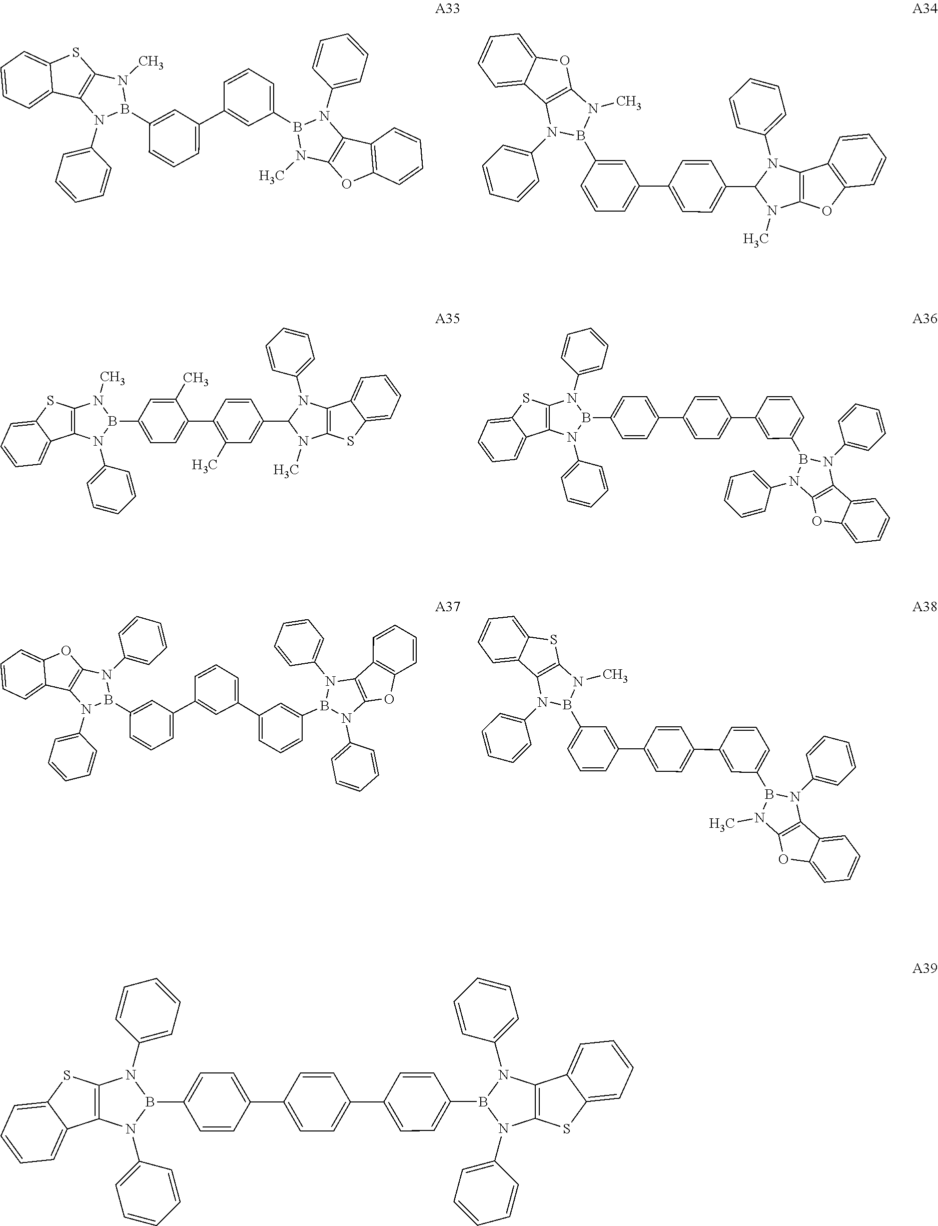

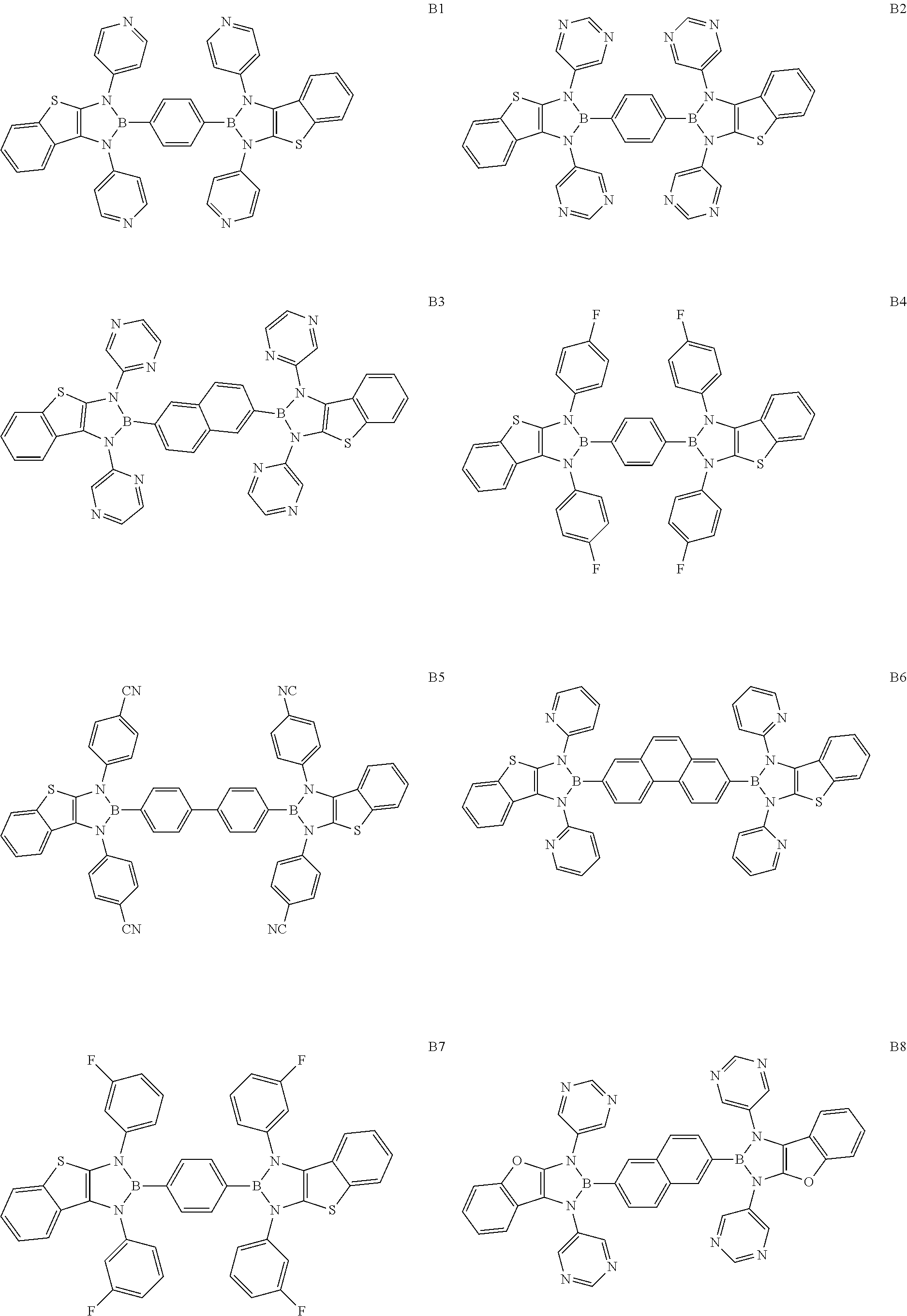

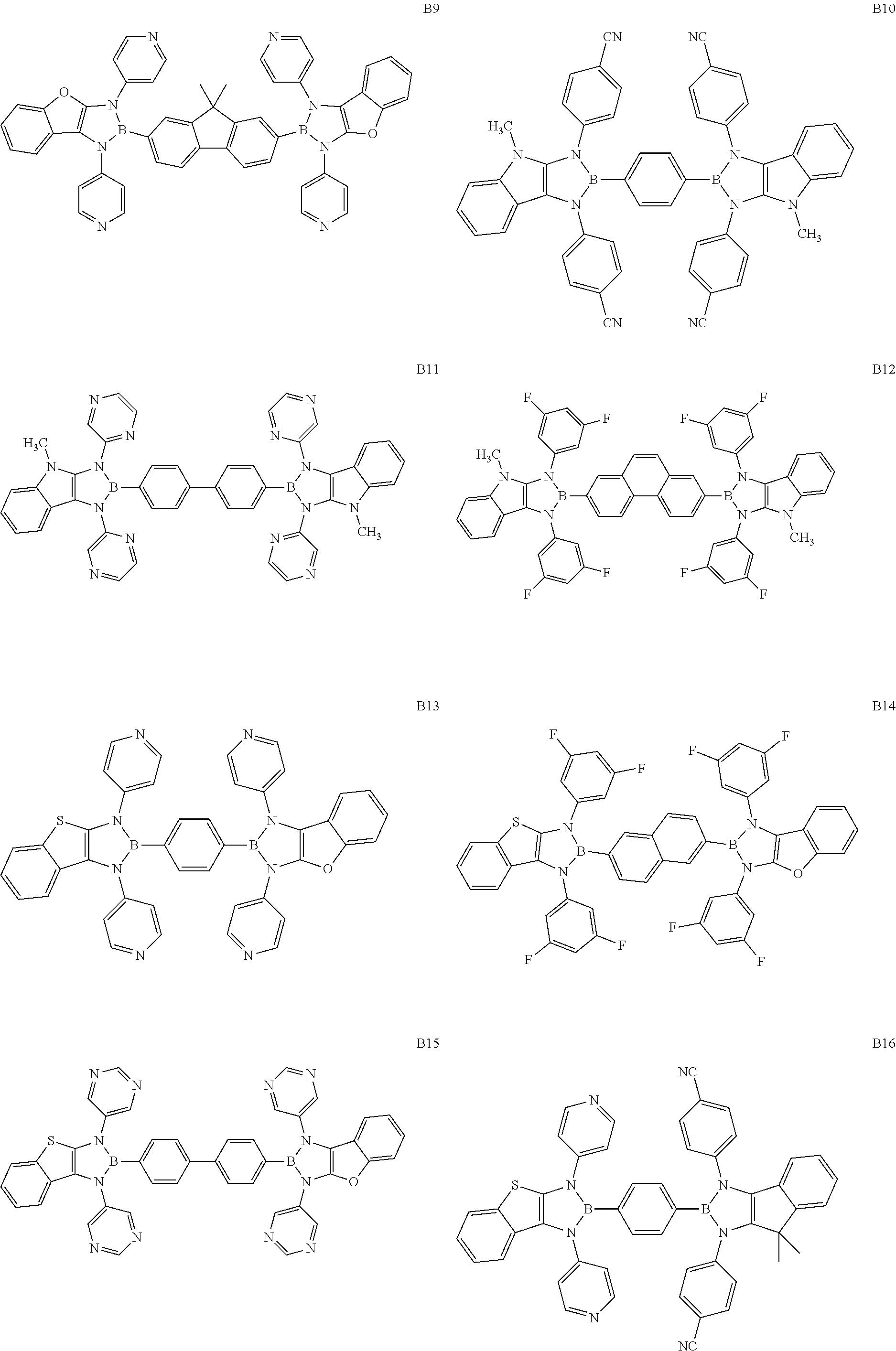

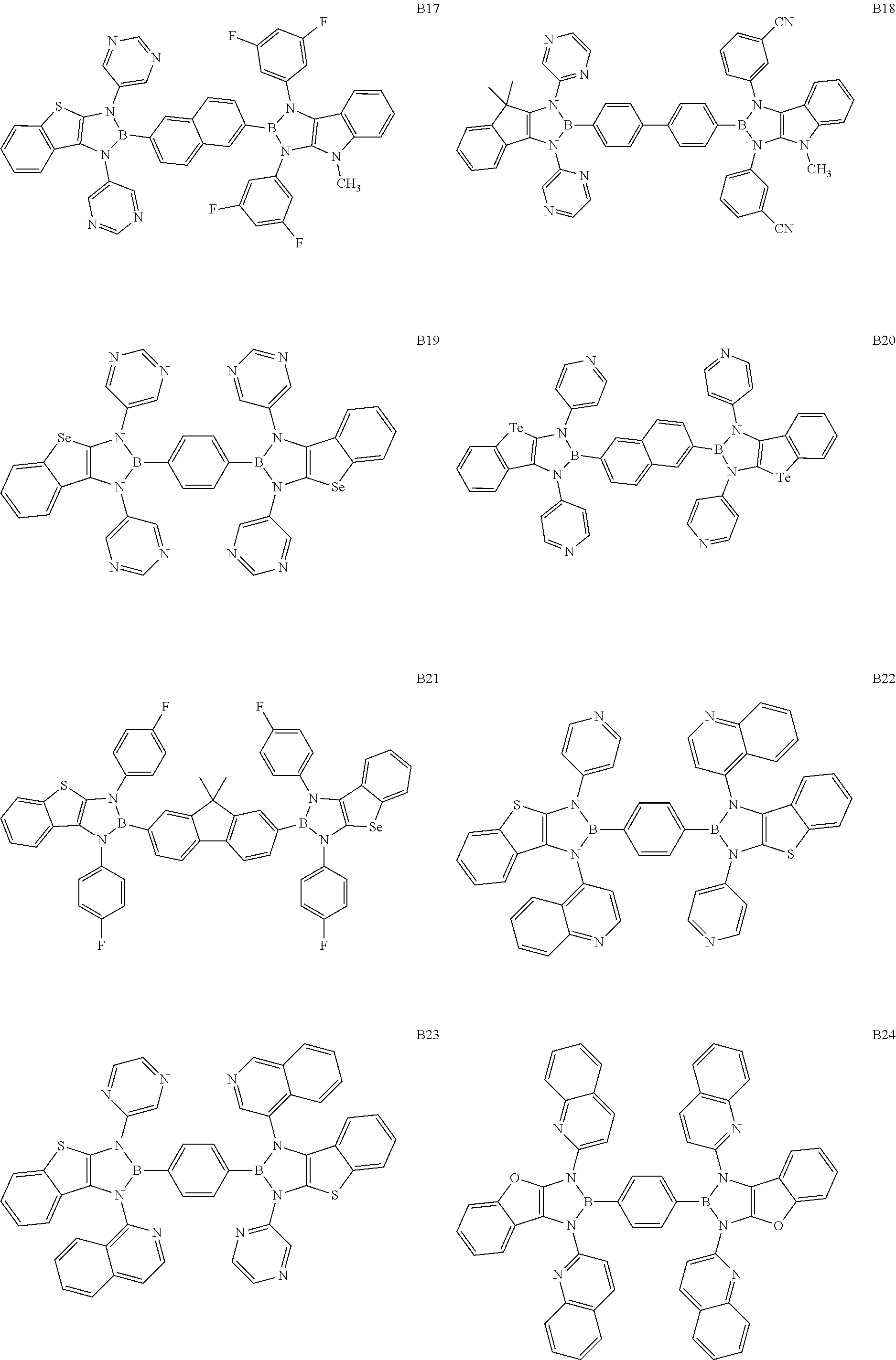

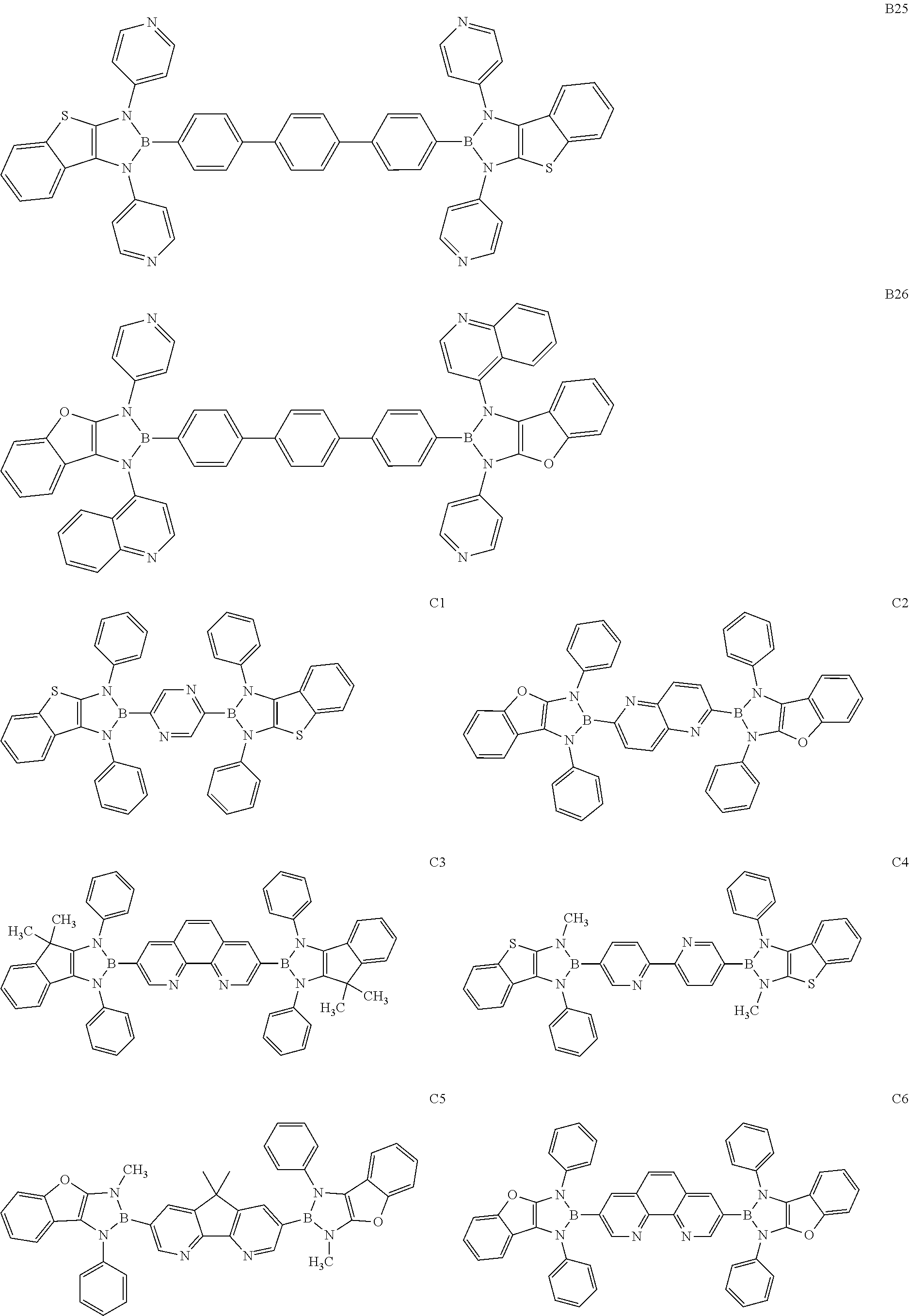

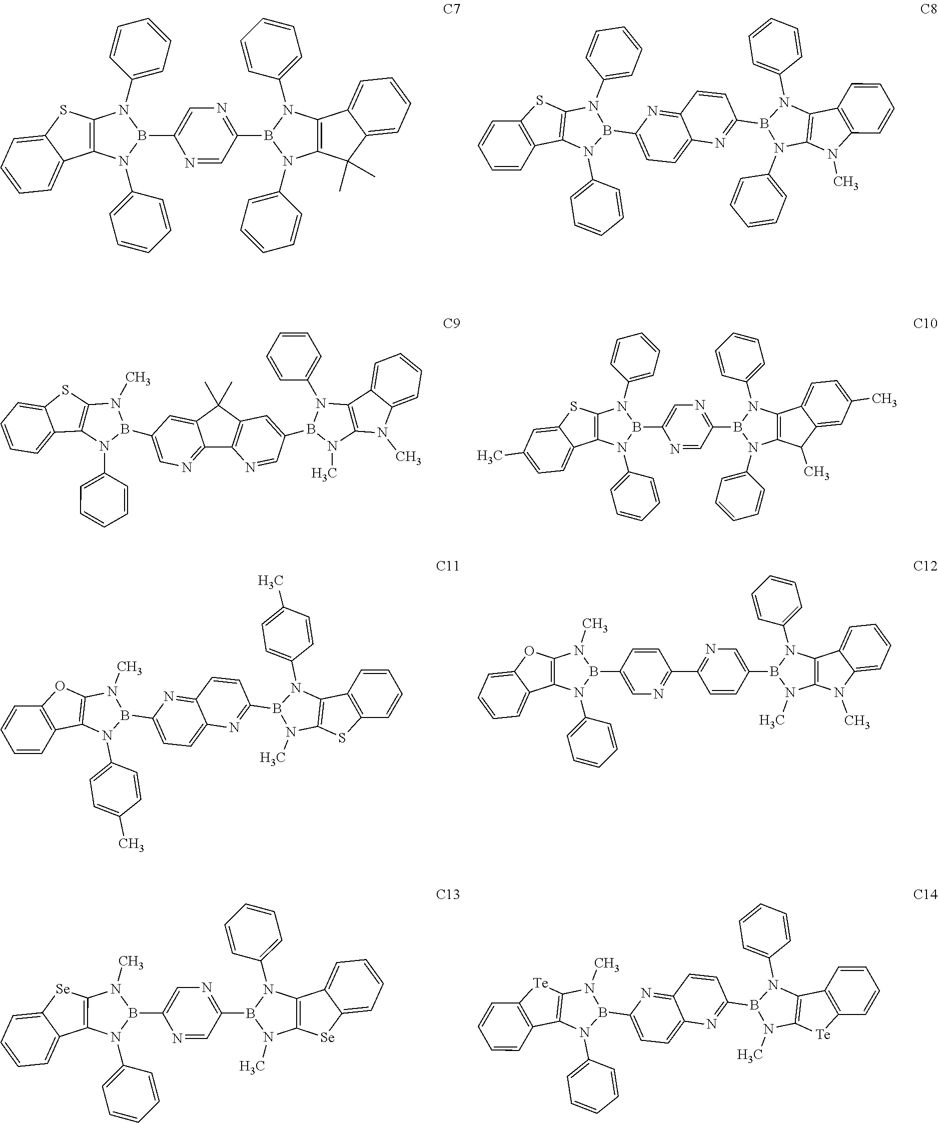

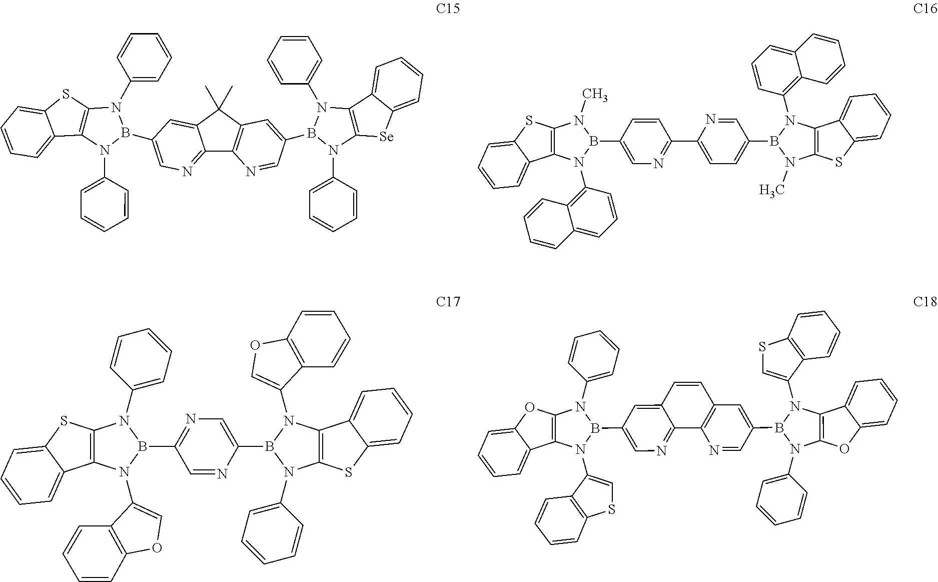 [SMILES: CC1(C)c2cc(B3N(c4ccccc4)c4sc5ccccc5c4N3c3ccccc3)cnc2-c2ncc(B3N(c4ccccc4)c4[se]c5ccccc5c4N3c3ccccc3)cc21 ; CN1B(c2ccc(-c3ccc(B4N(C)c5sc6ccccc6c5N4c4cccc5ccccc45)cn3)nc2)N(c2cccc3ccccc23)c2c1sc1ccccc21 ; c1ccc(N2B(c3cnc(B4N(c5ccccc5)c5sc6ccccc6c5N4c4coc5ccccc45)cn3)N(c3coc4ccccc34)c3c2sc2ccccc32)cc1 ; c1ccc(N2B(c3cnc4c(ccc5cc(B6N(c7ccccc7)c7oc8ccccc8c7N6c6csc7ccccc67)cnc54)c3)N(c3csc4ccccc34)c3c2oc2ccccc32)cc1]

Exemplary compounds belonging to the group A are compounds represented by the formula [1], wherein Ar₁ to Ar₄ denote an aryl group, an alkyl group, a benzofuranyl group, or a benzothienyl group, and L denotes an arylene group. The compounds belonging to the group A emit blue light with a short wavelength and a higher emission intensity. Thus, the compounds belonging to the group A used in a light-emitting layer emit blue light with higher color purity and high light emission efficiency.

Exemplary compounds belonging to the group B are compounds represented by the formula [1], wherein Ar₁ to Ar₄ denote an electron-withdrawing group, such as a heteroaryl group, a cyano group, or a phenyl group with a halogen element, and L denotes an arylene group. Among the compounds according to the present embodiment, the compounds belonging to the group B can have higher electron acceptability and emit blue light with high color purity.

Exemplary compounds belonging to the group C are compounds represented by the formula [1], wherein Ar₁ to Ar₄ denote an aryl group, an alkyl group, a benzofuranyl group, or a benzothienyl group, and L denotes a heteroarylene group. Among the compounds according to the present embodiment, the compounds belonging to the group C can have high electron acceptability and light emission efficiency.

An organic compound according to the present embodiment emits light suitable for blue light emission with high efficiency and has high chemical stability. Thus, an organic compound according to the present embodiment can be used as a constituent material of an organic light-emitting element to provide an organic light-emitting element with good emission properties and high durability.

<<Organic Light-Emitting Element>>

An organic light-emitting element according to the present embodiment includes at least a pair of electrodes, a first electrode and a second electrode, and an organic compound layer between the electrodes. The pair of electrodes may be a positive electrode and a negative electrode. In the organic light-emitting element according to the present embodiment, the organic compound layer may be a single layer or a laminate of a plurality of layers, provided that the organic compound layer has a light-emitting layer. When the organic compound layer is a laminate of a plurality of layers, the organic compound layer may have a hole-injection layer, a hole-transport layer, an electron-blocking layer, a hole/exciton-blocking layer, an electron-transport layer, and/or an electron-injection layer, in addition to the light-emitting layer. The light-emitting layer may be a single layer or a laminate of a plurality of layers.

In the organic light-emitting element according to the present embodiment, at least one layer of the organic compound layers contains an organic compound according to the present embodiment. More specifically, an organic compound according to the present embodiment is contained in one of the light-emitting layer, the hole-injection layer, the hole-transport layer, the electron-blocking layer, the hole/exciton-blocking layer, the electron-transport layer, the electron-injection layer, and the like. An organic compound according to the present embodiment can be contained in the light-emitting layer.

In the organic light-emitting element according to the present embodiment, when an organic compound according to the present embodiment is contained in the light-emitting layer, the light-emitting layer may be composed only of the organic compound according to the present embodiment or may be composed of the organic compound according to the present embodiment and another compound. When the light-emitting layer of the organic light-emitting element according to the present embodiment is composed of the organic compound according to the present embodiment and another compound, the light-emitting layer may be composed of the organic compound according to the present embodiment and a first compound, which is the other compound. The organic light-emitting element according to the present embodiment may further contain a second compound in the light-emitting layer.

When the light-emitting layer is composed of an organic compound according to the present embodiment and another compound, the organic compound according to the present embodiment may be used as a guest material (hereinafter also referred to as a “guest”, “dopant”, or “dopant material”). When an organic compound according to the present embodiment is used as a guest material, the first compound may be a host material (hereinafter also referred to as a “host”). The second compound may also be an assist material (hereinafter also referred to as an “assist”).

An organic compound according to the present embodiment may be used as a host or an assist material in the light-emitting layer.

The host is a compound with the highest mass ratio among the compounds constituting the light-emitting layer. The guest is a compound that has a lower mass ratio than the host among the compounds constituting the light-emitting layer and that is a principal light-emitting compound. The assist material is a compound that has a lower mass ratio than the host among the compounds constituting the light-emitting layer and that assists the guest in emitting light. The assist material is also referred to as a second host.

When an organic compound according to the present embodiment is used as a guest in the light-emitting layer, the concentration of the guest preferably ranges from 0.01% to 20% by mass, more preferably 0.1% to 5% by mass, of the entire light-emitting layer.

When an organic compound according to the present embodiment is used as an assist material in the light-emitting layer, the concentration of the assist material preferably ranges from 5% to 50% by mass, more preferably 10% to 30% by mass, of the entire light-emitting layer.

When an organic compound according to the present embodiment is used as a guest in the light-emitting layer, a material with a higher LUMO level than the organic compound according to the present embodiment (a material with a LUMO level closer to the vacuum level) can be used as a host. This is because the use of the material with a higher LUMO level than the organic compound according to the present embodiment as a host enables the organic compound according to the present embodiment to more effectively receive electrons supplied to the host in the light-emitting layer. In particular, this is because an organic compound according to the present embodiment has high electron acceptability or a low LUMO level, and the use of the material with a higher LUMO level than the organic compound according to the present embodiment as a host therefore enables the organic compound according to the present embodiment to more effectively receive electrons supplied to the host in the light-emitting layer.

The present inventors have conducted various studies and have found that an organic compound according to the present embodiment can be used as a host or guest in a light-emitting layer, particularly as a guest in the light-emitting layer, to provide an element that can efficiently emit bright light and that has very high durability. The light-emitting layer may be monolayer or multilayer or may contain a light-emitting material with another emission color to mix the emission color with the blue emission color of an organic compound according to the present embodiment. The term “multilayer”, as used herein, refers to a laminate of a light-emitting layer and another light-emitting layer. In such a case, the emission color of the organic light-emitting element is not limited to blue. More specifically, the emission color may be white or a neutral color. For white color emission, another light-emitting layer emits light of a color other than blue, such as red or green. Such a layer is formed by vapor deposition or coating. This is described in detail below in exemplary embodiments.

An organic compound according to the present embodiment can be used as a constituent material of an organic compound layer other than the light-emitting layer constituting the organic light-emitting element according to the present embodiment. More specifically, an organic compound according to the present embodiment may be used as a constituent material of an electron-transport layer, an electron-injection layer, a hole-transport layer, a hole-injection layer, and/or a hole-blocking layer. In such a case, the emission color of the organic light-emitting element is not limited to blue. More specifically, the emission color may be white or a neutral color.

<Compound Other than Organic Compounds According to Present Embodiment>

If necessary, an organic compound according to the present embodiment may be used in combination with a known low-molecular-weight or high-molecular-weight hole-injection compound or hole-transport compound, host compound, light-emitting compound, electron-injection compound, or electron-transport compound. Examples of these compounds are described below.

The hole-injection/transport material can be a material with high hole mobility to facilitate the injection of holes from a positive electrode and to transport the injected holes to a light-emitting layer. Furthermore, a material with a high glass transition temperature can be used to reduce degradation of film quality, such as crystallization, in an organic light-emitting element. Examples of the low-molecular-weight or high-molecular-weight material with hole-injection/transport ability include, but are not limited to, triarylamine derivatives, aryl carbazole derivatives, phenylenediamine derivatives, stilbene derivatives, phthalocyanine derivatives, porphyrin derivatives, polyvinylcarbazole, polythiophene, and other electrically conductive polymers. The hole-injection/transport material can also be used for an electron-blocking layer. Specific examples of compounds that can be used as hole-injection/transport materials include, but are not limited to, the following.

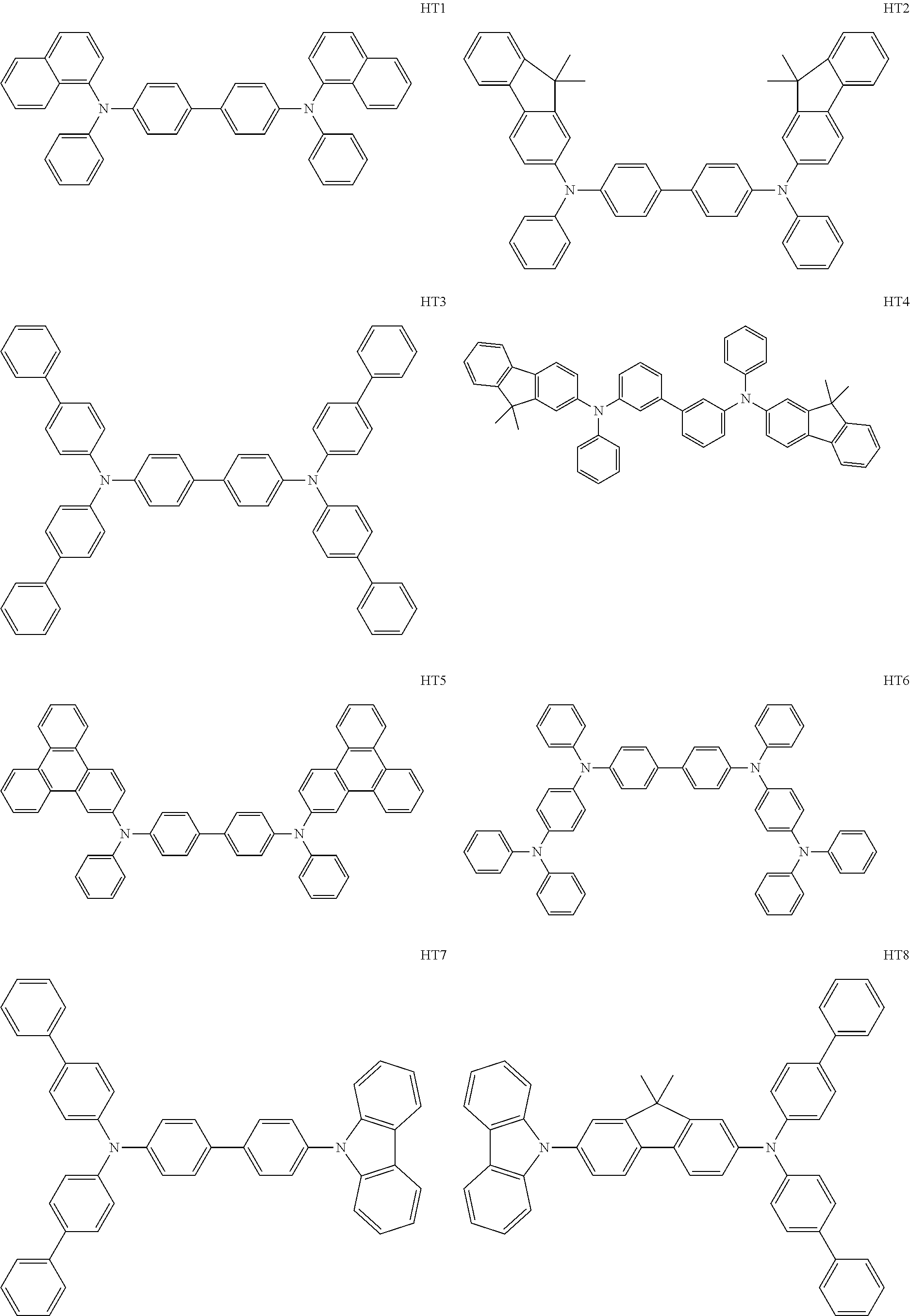

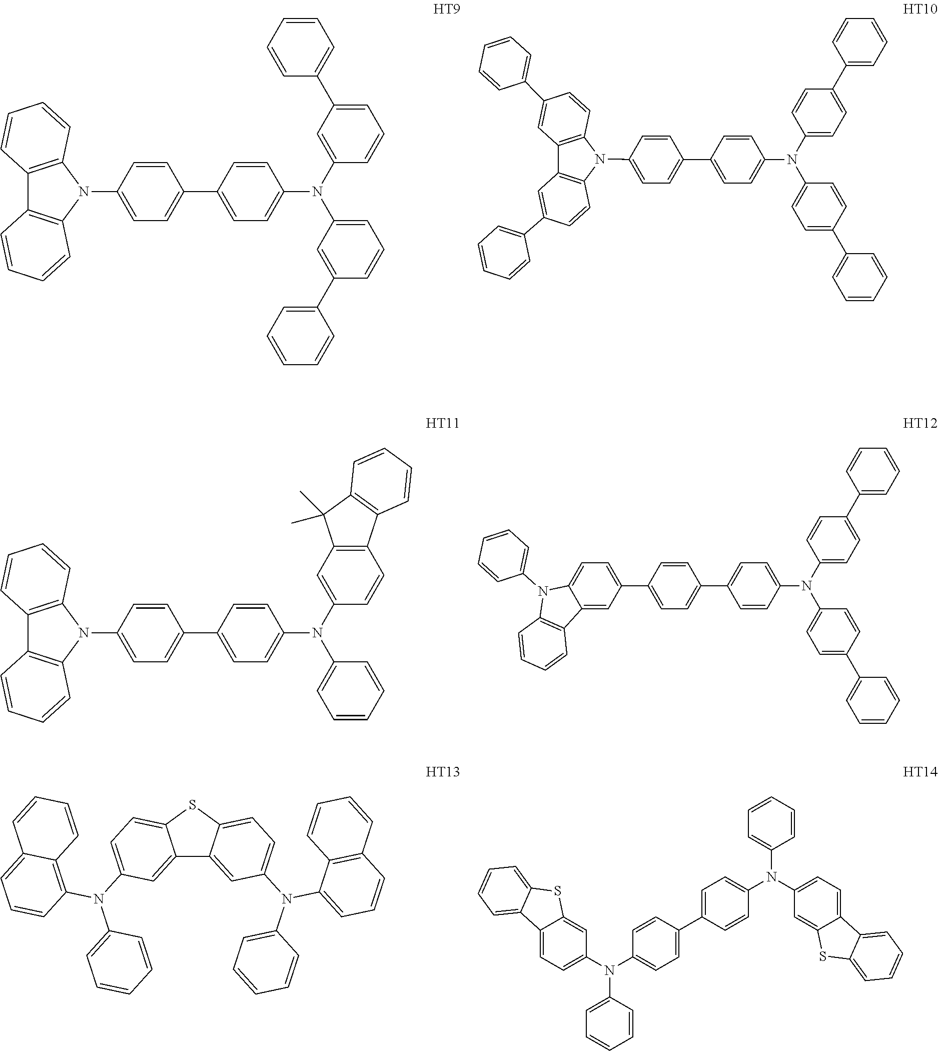

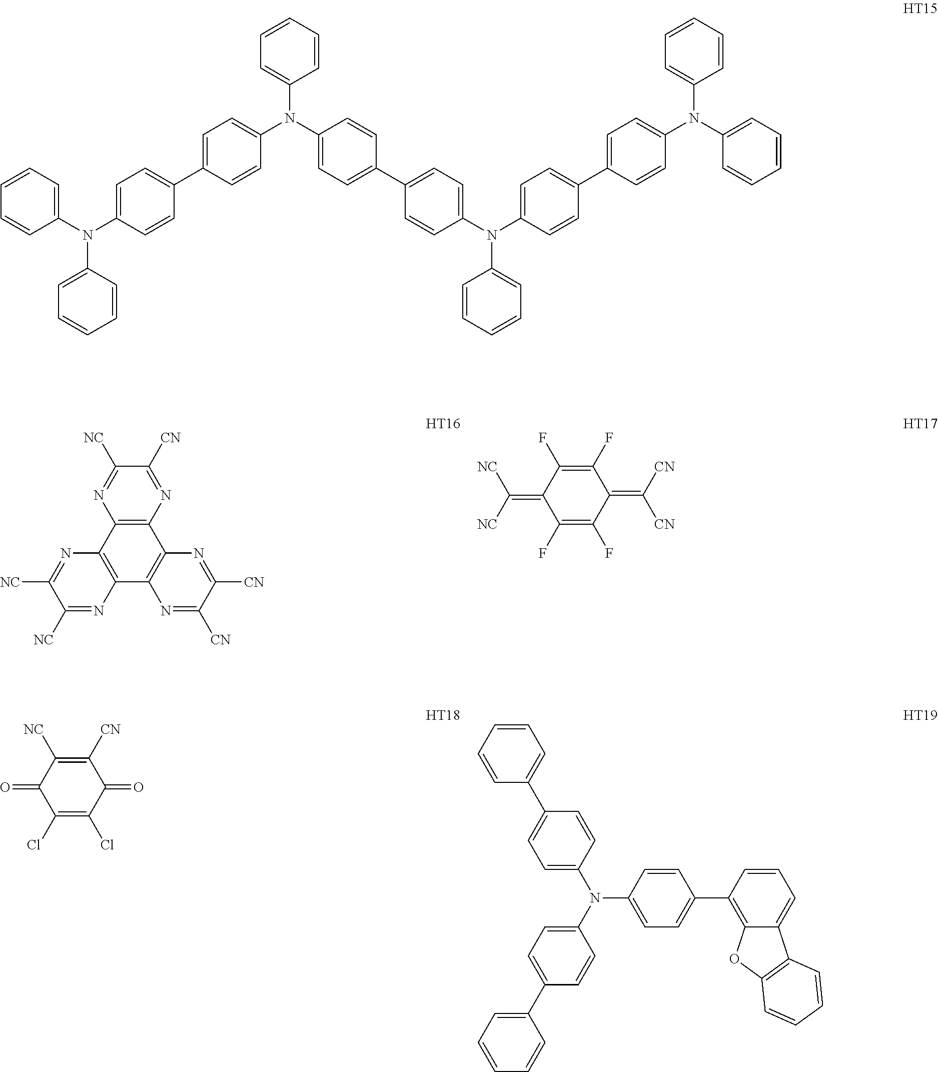 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1 ; N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F ; N#CC1=C(C#N)C(=O)C(Cl)=C(Cl)C1=O ; c1ccc(-c2ccc(N(c3ccc(-c4ccccc4)cc3)c3ccc(-c4cccc5c4oc4ccccc45)cc3)cc2)cc1]

Examples of a light-emitting material mainly related to the light-emitting function include, but are not limited to, fused-ring compounds (for example, fluorene derivatives, naphthalene derivatives, pyrene derivatives, perylene derivatives, tetracene derivatives, anthracene derivatives, rubrene, etc.), quinacridone derivatives, coumarin derivatives, stilbene derivatives, organoaluminum complexes, such as tris(8-quinolinolato)aluminum, iridium complexes, platinum complexes, rhenium complexes, copper complexes, europium complexes, ruthenium complexes, and polymer derivatives, such as poly(phenylene vinylene) derivatives, polyfluorene derivatives, and polyphenylene derivatives. Specific examples of compounds that can be used as light-emitting materials include, but are not limited to, the following.

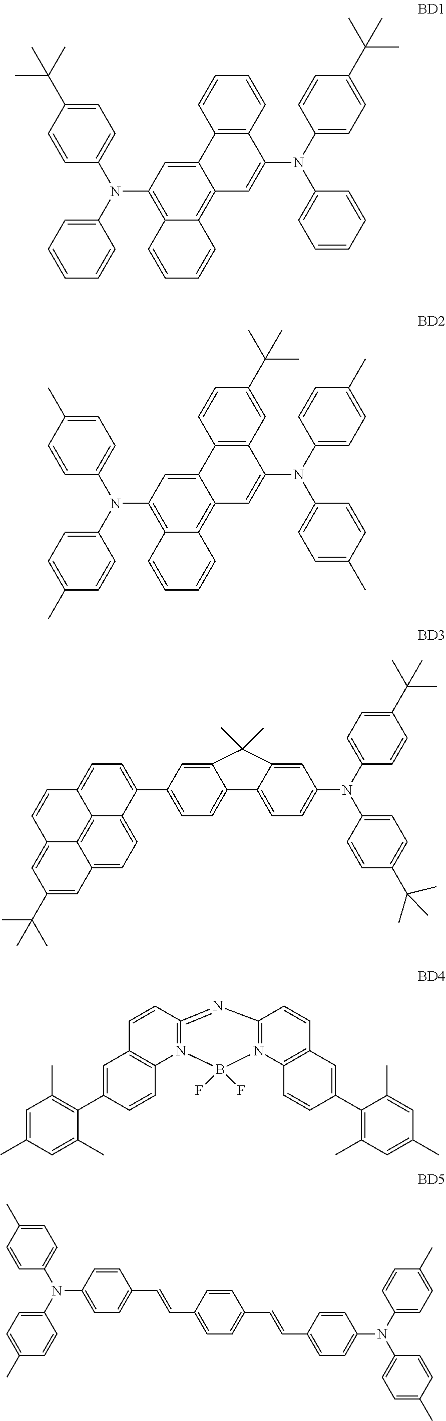

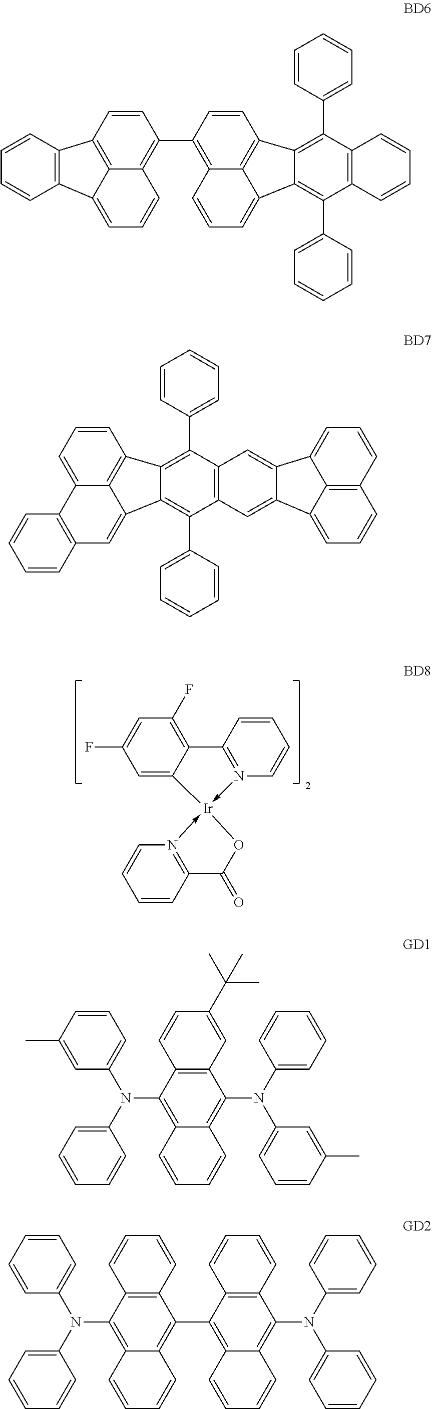

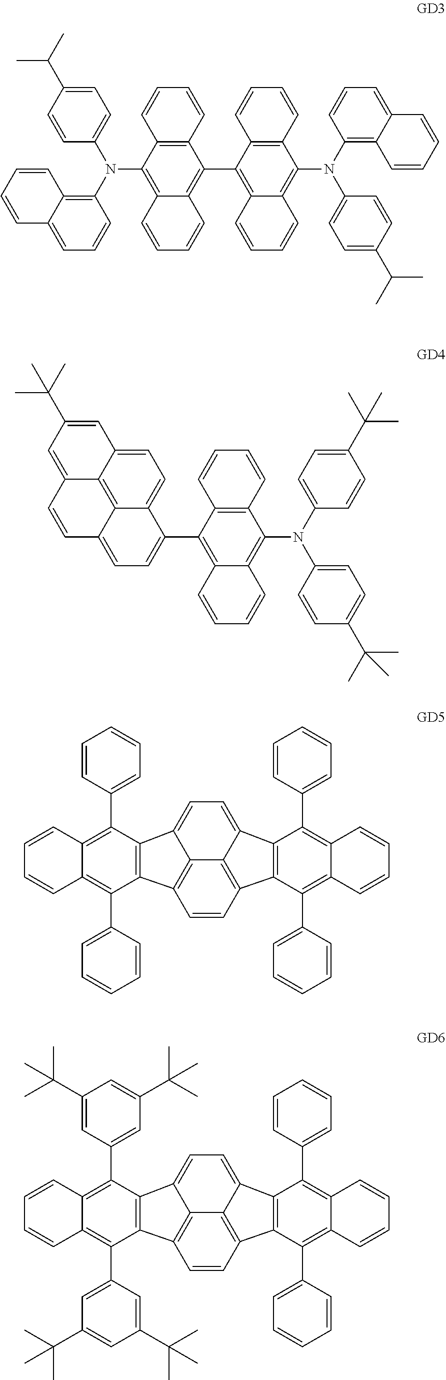

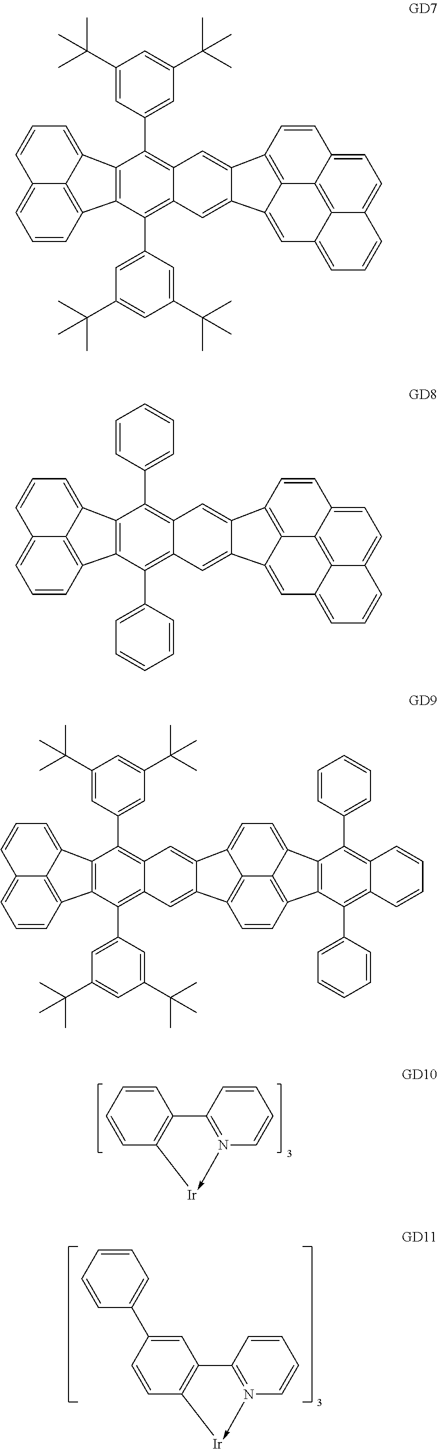

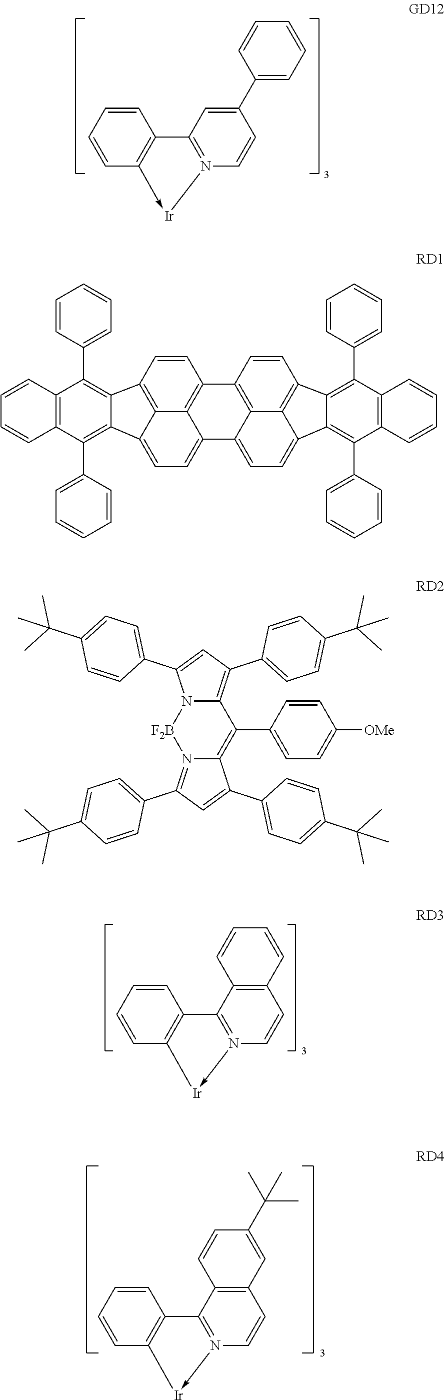

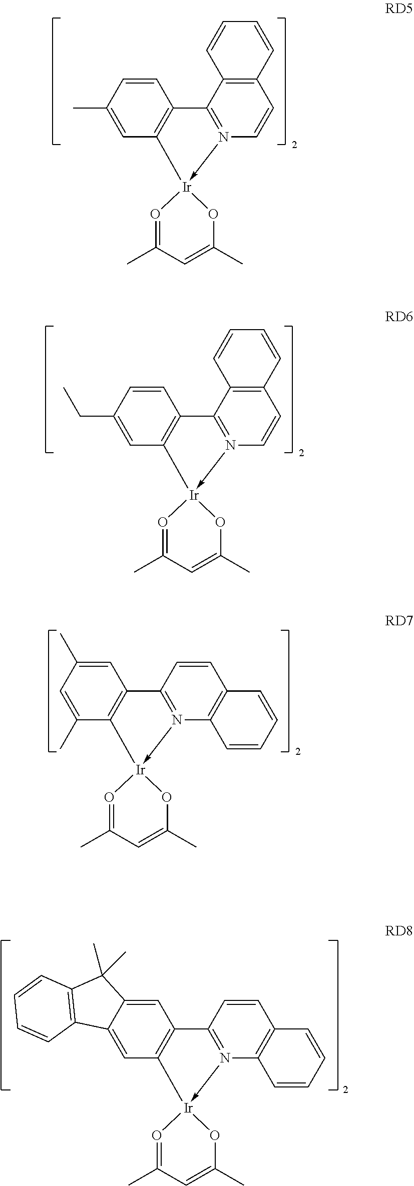

Examples of a light-emitting layer host or a light-emitting assist material in a light-emitting layer include, but are not limited to, aromatic hydrocarbon compounds and derivatives thereof, carbazole derivatives, dibenzofuran derivatives, dibenzothiophene derivatives, organoaluminum complexes, such as tris(8-quinolinolato)aluminum, and organoberyllium complexes. Specific examples of a compound that can be used as a light-emitting layer host or a light-emitting assist material in a light-emitting layer include, but are not limited to, the following.

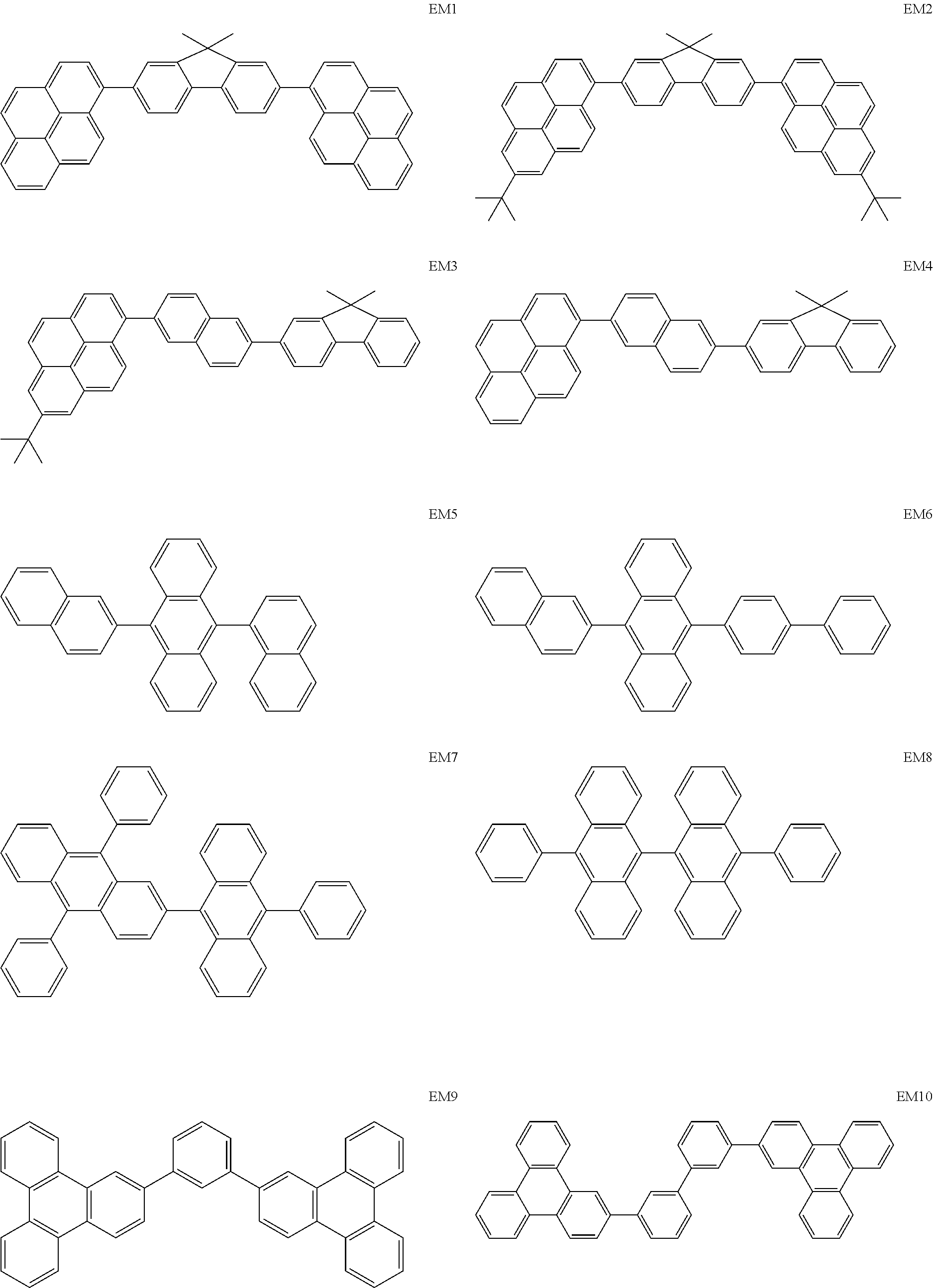

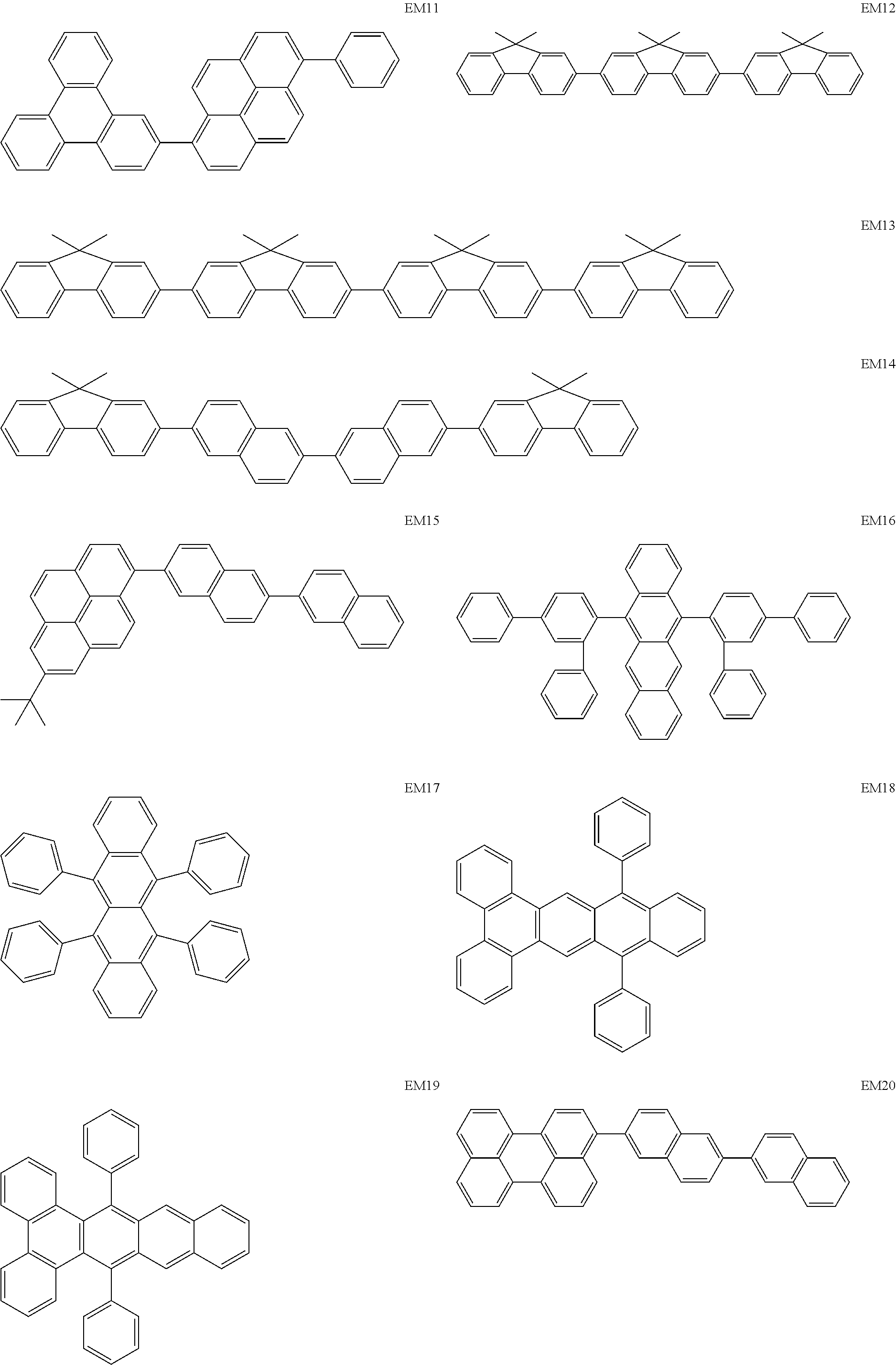

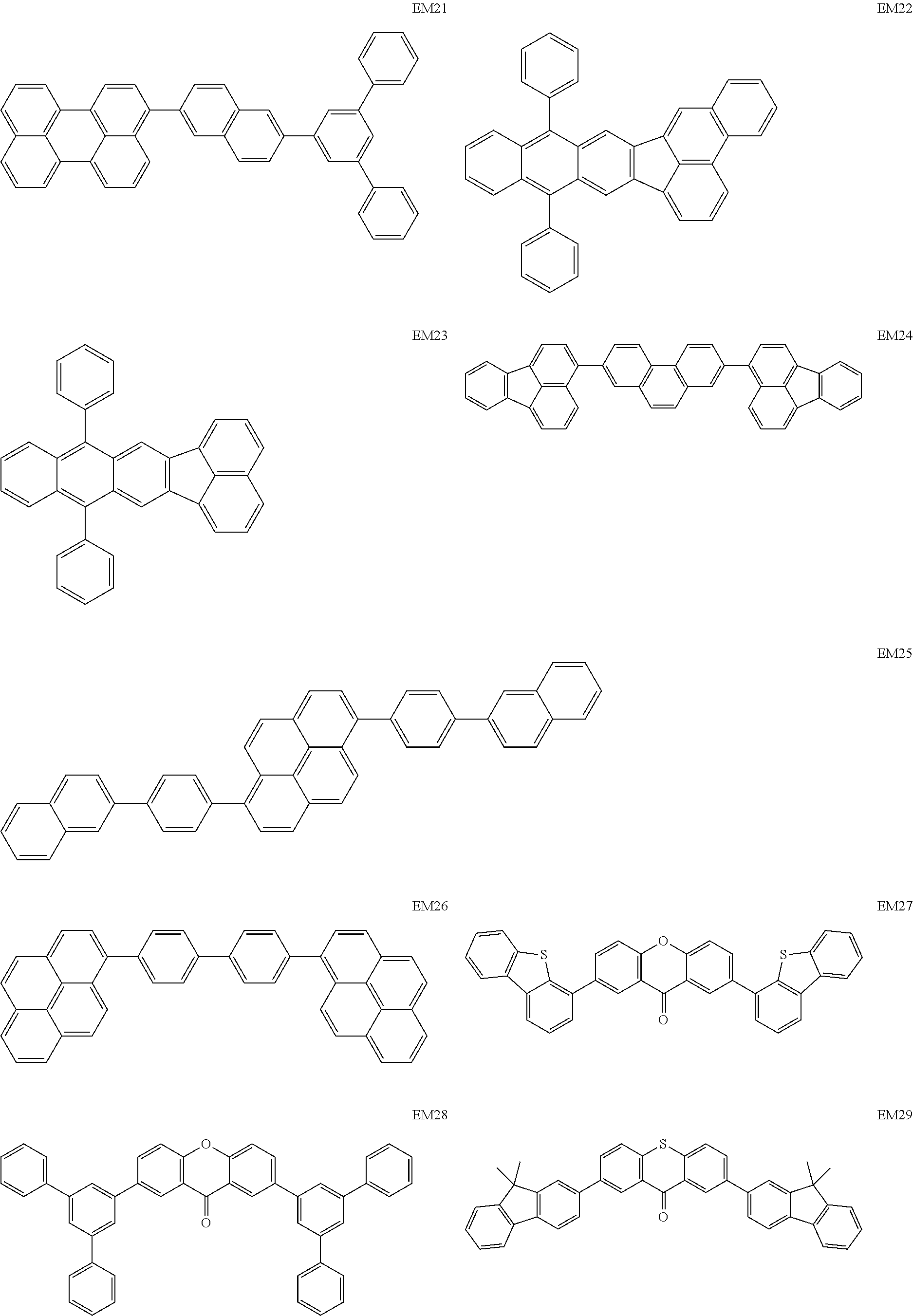

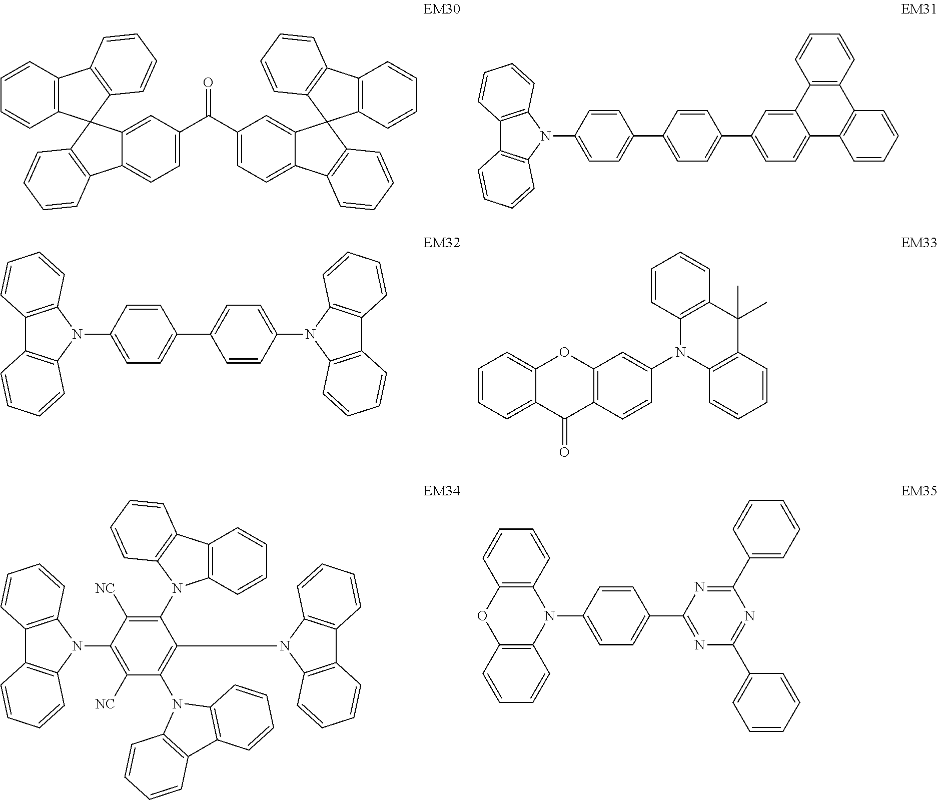

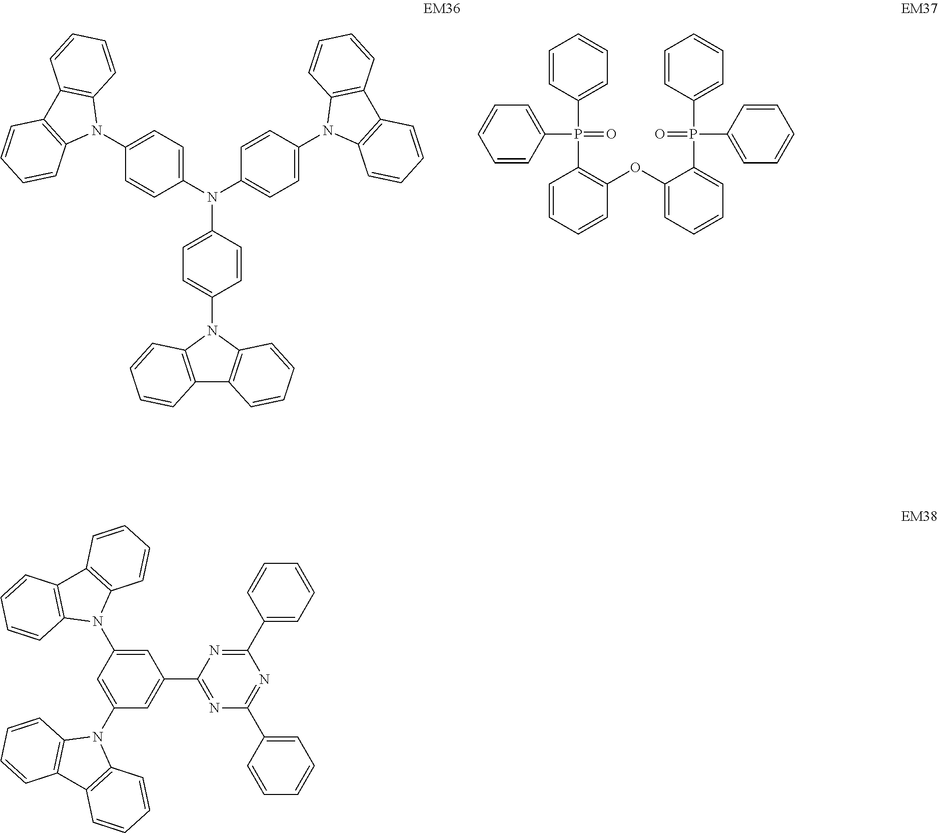 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; O=P(c1ccccc1)(c1ccccc1)c1ccccc1Oc1ccccc1P(=O)(c1ccccc1)c1ccccc1 ; c1ccc(-c2nc(-c3ccccc3)nc(-c3cc(-n4c5ccccc5c5ccccc54)cc(-n4c5ccccc5c5ccccc54)c3)n2)cc1]

An electron-transport material can be selected from materials that can transport electrons injected from the negative electrode to the light-emitting layer and is selected in consideration of the balance with the hole mobility of a hole-transport material and the like. Examples of materials with electron-transport ability include, but are not limited to, oxadiazole derivatives, oxazole derivatives, pyrazine derivatives, triazole derivatives, triazine derivatives, quinoline derivatives, quinoxaline derivatives, phenanthroline derivatives, organoaluminum complexes, and fused-ring compounds (for example, fluorene derivatives, naphthalene derivatives, chrysene derivatives, and anthracene derivatives). Furthermore, the electron-transport material is also suitably used for a hole-blocking layer. Specific examples of compounds that can be used as electron-transport materials include, but are not limited to, the following.

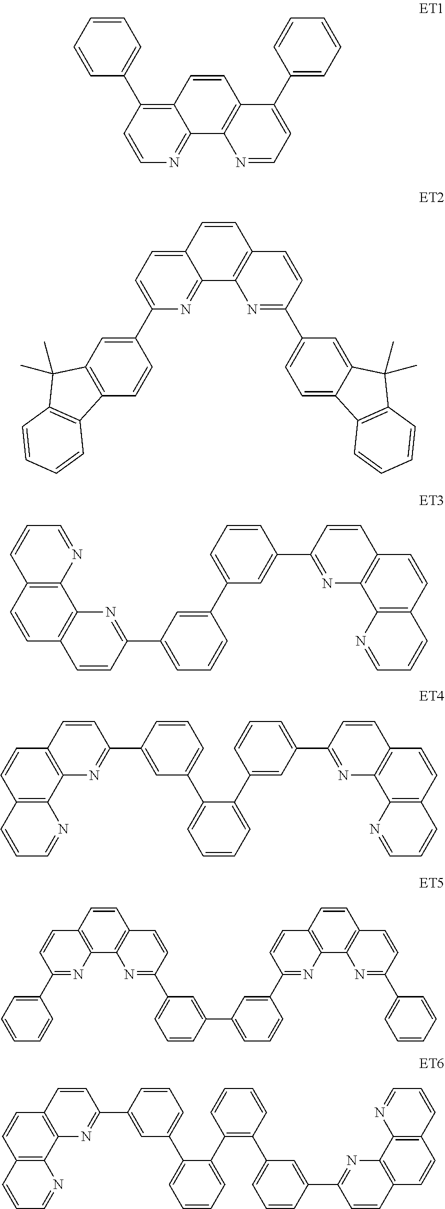

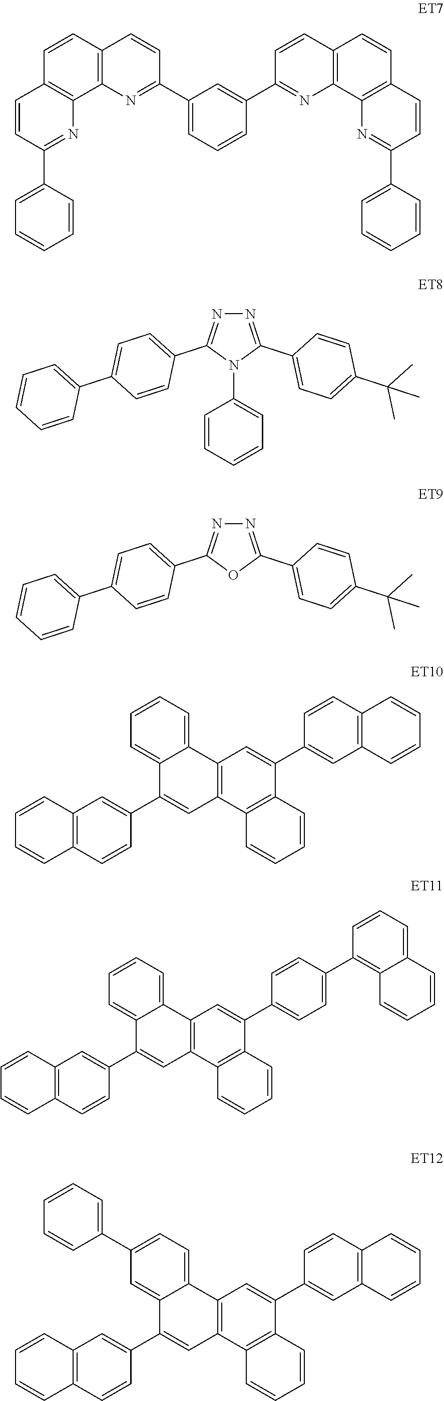

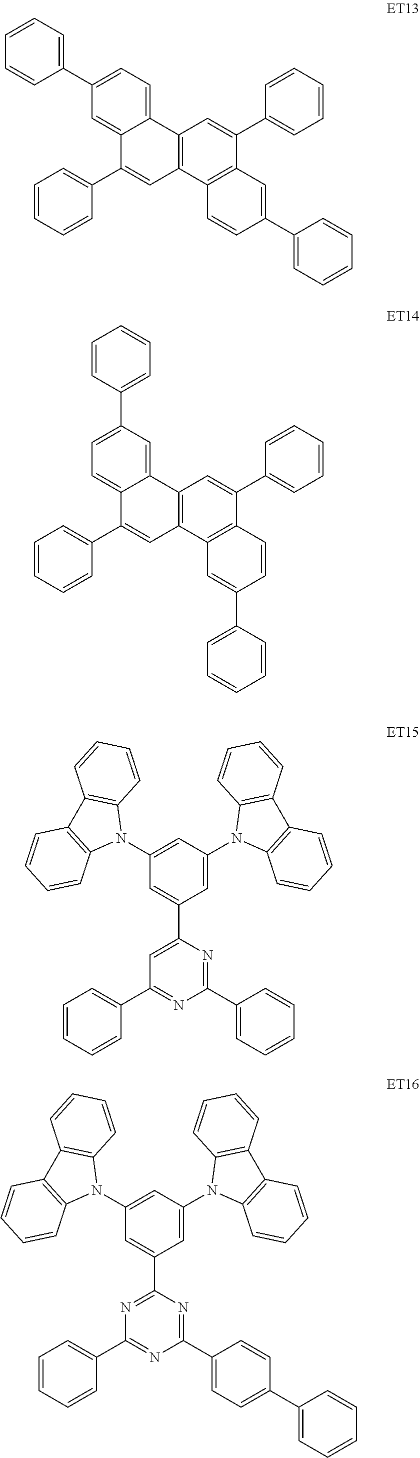

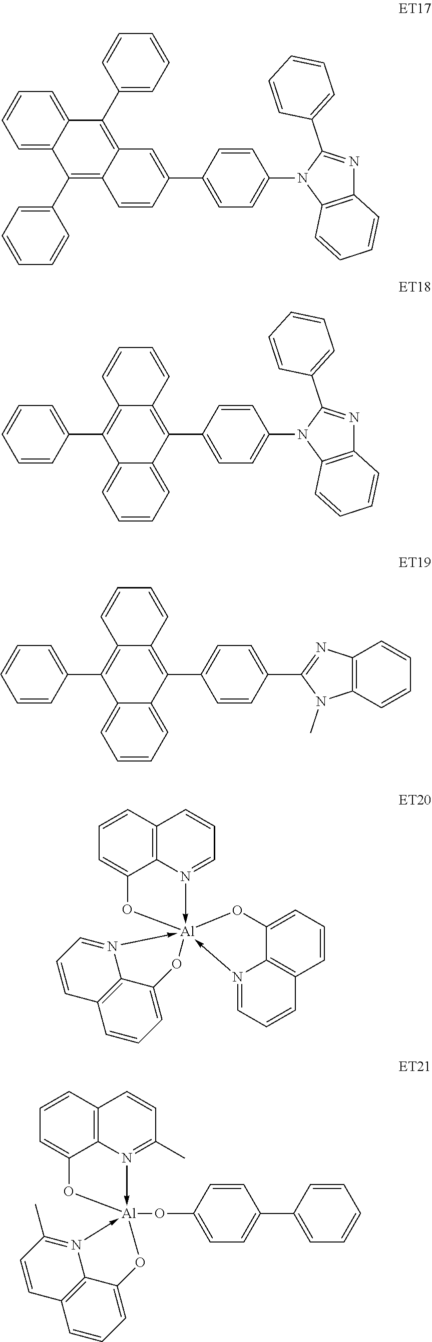

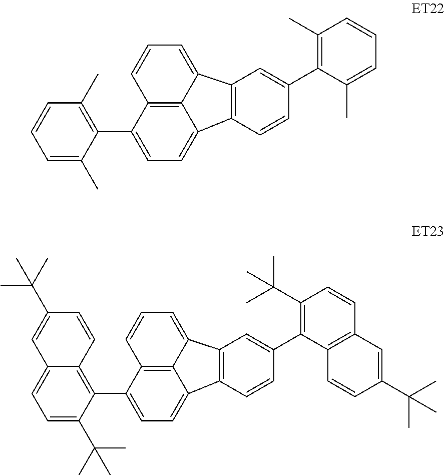

<Structure of Organic Light-Emitting Element>

An organic light-emitting element includes an insulating layer, a first electrode, an organic compound layer, and a second electrode on a substrate. A protective layer, a color filter, a microlens, or the like may be provided on the second electrode. When a color filter is provided, a planarization layer may be provided between the color filter and a protective layer. The planarization layer may be composed of an acrylic resin or the like. The same applies to a planarization layer provided between a color filter and a microlens.

[Substrate]

The substrate may be formed of quartz, glass, silicon wafer, resin, metal, or the like. The substrate may have a switching element, such as a transistor, and wiring, on which an insulating layer may be provided. The insulating layer may be composed of any material, provided that the insulating layer can have a contact hole for wiring between the insulating layer and the first electrode and is insulated from unconnected wires. For example, the insulating layer may be formed of a resin, such as polyimide, silicon oxide, or silicon nitride.

[Electrodes]

A pair of electrodes can be used as electrodes. The pair of electrodes may be a positive electrode and a negative electrode. When an electric field is applied in a direction in which the organic light-emitting element emits light, an electrode with a high electric potential is a positive electrode, and the other electrode is a negative electrode. In other words, the electrode that supplies holes to the light-emitting layer is a positive electrode, and the electrode that supplies electrons is a negative electrode.

A constituent material of the positive electrode can have as large a work function as possible. Examples of the constituent material include metal elements, such as gold, platinum, silver, copper, nickel, palladium, cobalt, selenium, vanadium, and tungsten, mixtures thereof, alloys thereof, and metal oxides, such as tin oxide, zinc oxide, indium oxide, indium tin oxide (ITO), and indium zinc oxide. Electrically conductive polymers, such as polyaniline, polypyrrole, and polythiophene, may also be used.

These electrode materials may be used alone or in combination. The positive electrode may be composed of a single layer or a plurality of layers.

When used as a reflective electrode, for example, chromium, aluminum, silver, titanium, tungsten, molybdenum, an alloy thereof, or a laminate thereof can be used. These materials can also function as a reflective film that does not have a role as an electrode. When used as a transparent electrode, an oxide transparent conductive layer, such as indium tin oxide (ITO) or indium zinc oxide, can be used. However, the present disclosure is not limited thereto. The electrodes may be formed by photolithography.

A constituent material of the negative electrode can be a material with a small work function. For example, an alkali metal, such as lithium, an alkaline-earth metal, such as calcium, a metal element, such as aluminum, titanium, manganese, silver, lead, or chromium, or a mixture thereof may be used. An alloy of these metal elements may also be used. For example, magnesium-silver, aluminum-lithium, aluminum-magnesium, silver-copper, or zinc-silver may be used. A metal oxide, such as indium tin oxide (ITO), may also be used. These electrode materials may be used alone or in combination. The negative electrode may be composed of a single layer or a plurality of layers. Among them, silver can be used, and a silver alloy can be used to reduce the aggregation of silver. As long as the aggregation of silver can be reduced, the alloy may have any ratio. For example, the ratio of silver to another metal may be 1:1, 3:1, or the like.

The negative electrode may be, but is not limited to, an oxide conductive layer, such as ITO, for a top emission element or a reflective electrode, such as aluminum (Al), for a bottom emission element. The negative electrode may be formed by any method. A direct-current or alternating-current sputtering method can achieve good film coverage and easily decrease resistance.

[Organic Compound Layer]

The organic compound layer may be formed of a single layer or a plurality of layers. Depending on their functions, a plurality of layers may be referred to as a hole-injection layer, a hole-transport layer, an electron-blocking layer, a light-emitting layer, a hole-blocking layer, an electron-transport layer, or an electron-injection layer. The organic compound layer is composed mainly of an organic compound and may contain an inorganic atom or an inorganic compound. For example, the organic compound layer may contain copper, lithium, magnesium, aluminum, iridium, platinum, molybdenum, zinc, or the like. The organic compound layer may be located between the first electrode and the second electrode and may be in contact with the first electrode and the second electrode.

An organic compound layer (a hole-injection layer, a hole-transport layer, an electron-blocking layer, a light-emitting layer, a hole-blocking layer, an electron-transport layer, an electron-injection layer, etc.) constituting an organic light-emitting element according to an embodiment of the present disclosure is formed by the following method.

An organic compound layer constituting an organic light-emitting element according to an embodiment of the present disclosure can be formed by a dry process, such as a vacuum evaporation method, an ionized deposition method, sputtering, or plasma. Instead of the dry process, a wet process may also be employed in which a layer is formed by a known coating method (for example, spin coating, dipping, a casting method, an LB method, an ink jet method, etc.) using an appropriate solvent.

A layer formed by a vacuum evaporation method, a solution coating method, or the like undergoes little crystallization or the like and has high temporal stability. When a film is formed by a coating method, the film may also be formed in combination with an appropriate binder resin.

Examples of the binder resin include, but are not limited to, polyvinylcarbazole resins, polycarbonate resins, polyester resins, ABS resins, acrylic resins, polyimide resins, phenolic resins, epoxy resins, silicone resins, and urea resins.

These binder resins may be used alone or in combination as a homopolymer or a copolymer. If necessary, an additive agent, such as a known plasticizer, oxidation inhibitor, and/or ultraviolet absorbent, may also be used.

[Protective Layer]

A protective layer may be provided on the second electrode. For example, a glass sheet with a moisture absorbent may be attached to the second electrode to decrease the amount of water or the like entering the organic compound layer and to reduce the occurrence of display defects. In another embodiment, a passivation film of silicon nitride or the like may be provided on the second electrode to decrease the amount of water or the like entering the organic compound layer. For example, after the second electrode is formed, the negative electrode is transferred to another chamber without breaking the vacuum, and a silicon nitride film with a thickness of 2 m may be formed as a protective layer by a chemical vapor deposition (CVD) method. The protective layer may be formed by the CVD method followed by an atomic layer deposition (ALD) method. A film formed by the ALD method may be formed of any material such as silicon nitride, silicon oxide, or aluminum oxide. Silicon nitride may be further deposited by the CVD method on the film formed by the ALD method. The film formed by the ALD method may have a smaller thickness than the film formed by the CVD method. More specifically, the thickness may be 50% or less or even 10% or less.

[Color Filter]

A color filter may be provided on the protective layer. For example, a color filter that matches the size of the organic light-emitting element may be provided on another substrate and may be bonded to the substrate on which the organic light-emitting element is provided, or a color filter may be patterned on the protective layer by photolithography. The color filter may be composed of a polymer.

[Planarization Layer]

A planarization layer may be provided between the color filter and the protective layer. The planarization layer is provided to reduce the roughness of the underlayer. The planarization layer is sometimes referred to as a material resin layer with any purpose. The planarization layer may be composed of an organic compound and can be composed of a high-molecular-weight compound, though it may be composed of a low-molecular-weight compound.

The planarization layer may be provided above and below the color filter, and the constituent materials thereof may be the same or different. Specific examples include polyvinylcarbazole resins, polycarbonate resins, polyester resins, ABS resins, acrylic resins, polyimide resins, phenolic resins, epoxy resins, silicone resins, and urea resins.

[Microlens]

An organic light-emitting element or an organic light-emitting apparatus may include an optical member, such as a microlens, on the light output side. The microlens may be composed of an acrylic resin, an epoxy resin, or the like. The microlens may be used to increase the amount of light extracted from the organic light-emitting element or the organic light-emitting apparatus and control the direction of the extracted light. The microlens may have a hemispherical shape. For a hemispherical microlens, the vertex of the microlens is a contact point between the hemisphere and a tangent line parallel to the insulating layer among the tangent lines in contact with the hemisphere. The vertex of the microlens in a cross-sectional view can be determined in the same manner. More specifically, the vertex of the microlens in a cross-sectional view is a contact point between the semicircle of the microlens and a tangent line parallel to the insulating layer among the tangent lines in contact with the semicircle.

The midpoint of the microlens can also be defined. In a cross section of the microlens, a midpoint of a line segment from one end point to the other end point of the arc can be referred to as a midpoint of the microlens. A cross section in which the vertex and the midpoint are determined may be perpendicular to the insulating layer.

[Opposite Substrate]

An opposite substrate may be provided on the planarization layer. The opposite substrate is so called because it faces the substrate. The opposite substrate may be composed of the same material as the substrate. When the substrate is a first substrate, the opposite substrate may be a second substrate.

[Pixel Circuit]

An organic light-emitting apparatus including an organic light-emitting element may include a pixel circuit coupled to the organic light-emitting element. The pixel circuit may be of an active matrix type, which independently controls the light emission of a first light-emitting element and a second light-emitting element. The active-matrix circuit may be voltage programmed or current programmed. The drive circuit has a pixel circuit for each pixel. The pixel circuit may include a light-emitting element, a transistor for controlling the luminous brightness of the light-emitting element, a transistor for controlling light emission timing, a capacitor for holding the gate voltage of the transistor for controlling the luminous brightness, and a transistor for GND connection without through the light-emitting element.

A light-emitting apparatus includes a display region and a peripheral region around the display region. The display region includes the pixel circuit, and the peripheral region includes a display control circuit. The mobility of a transistor constituting the pixel circuit may be smaller than the mobility of a transistor constituting the display control circuit. The gradient of the current-voltage characteristics of a transistor constituting the pixel circuit may be smaller than the gradient of the current-voltage characteristics of a transistor constituting the display control circuit. The gradient of the current-voltage characteristics can be determined by so-called Vg-Ig characteristics. A transistor constituting the pixel circuit is a transistor coupled to a light-emitting element, such as a first light-emitting element.

[Pixel]

An organic light-emitting apparatus including an organic light-emitting element may have a plurality of pixels. Each pixel has subpixels that emit light of different colors. For example, the subpixels may have RGB emission colors.

In each pixel, a region also referred to as a pixel aperture emits light. This region is the same as the first region. The pixel aperture may be 15 m or less or 5 m or more. More specifically, the pixel aperture may be 11 m, 9.5 m, 7.4 m, or 6.4 km. The distance between the subpixels may be 10 m or less, more specifically, 8 m, 7.4 m, or 6.4 km.

The pixels may be arranged in a known form in a plan view. Examples include stripe arrangement, delta arrangement, PenTile arrangement, and Bayer arrangement. Each subpixel may have any known shape in a plan view. Examples include quadrangles, such as a rectangle and a rhombus, and a hexagon. As a matter of course, a figure that is not strictly rectangular but is close to rectangular is also included in the rectangle. The shape of each subpixel and the pixel array can be used in combination.

<Applications of Organic Light-Emitting Element>

The organic light-emitting element according to the present embodiment can be used as a constituent of a display apparatus or a lighting apparatus. Other applications include an exposure light source of an electrophotographic image-forming apparatus, a backlight of a liquid crystal display, and a light-emitting apparatus with a color filter in a white light source.

The display apparatus may be an image-information-processing apparatus that includes an image input unit for inputting image information from an area CCD, a linear CCD, a memory card, or the like, includes an information processing unit for processing the input information, and displays an input image on a display unit. The display apparatus may have a plurality of pixels, and at least one of the pixels may include the organic light-emitting element according to the present embodiment and a transistor coupled to the organic light-emitting element.

A display unit of an imaging apparatus or an ink jet printer may have a touch panel function. A driving system of the touch panel function may be, but is not limited to, an infrared radiation system, an electrostatic capacitance system, a resistive film system, or an electromagnetic induction system. The display apparatus may be used for a display unit of a multifunction printer.

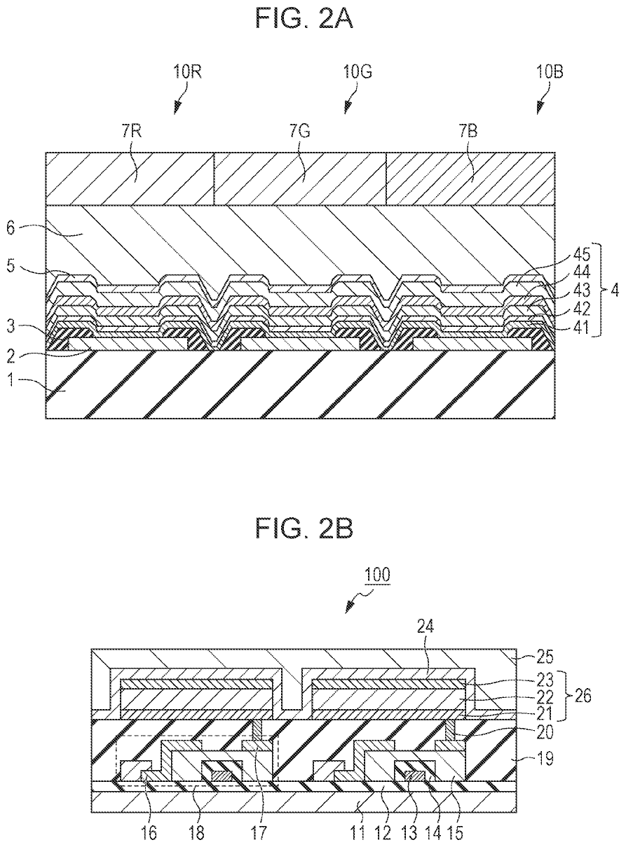

Next, a display apparatus according to the present embodiment is described with reference to the accompanying drawings. FIGS. 2A and 2B are schematic cross-sectional views of an example of a display apparatus that includes an organic light-emitting element and a transistor coupled to the organic light-emitting element. The transistor is an example of an active element. The transistor may be a thin-film transistor (TFT).

FIG. 2A illustrates an example of a pixel serving as a constituent of the display apparatus according to the present embodiment. The pixel has subpixels 10. The subpixels are 10R, 10G, and 10B with different emission colors. The emission colors may be distinguished by the wavelength of light emitted from the light-emitting layer, or light emitted from each subpixel may be selectively transmitted or color-converted with a color filter or the like. Each of the subpixels 10 includes a reflective electrode serving as a first electrode 2, an insulating layer 3 covering an end of the first electrode 2, organic compound layers 4 covering the first electrode 2 and the insulating layer 3, a transparent electrode serving as a second electrode 5, a protective layer 6, and a color filter 7 on an interlayer insulating layer 1.

A transistor and/or a capacitor element may be provided under or inside the interlayer insulating layer 1. The transistor and the first electrode 2 may be electrically connected via a contact hole (not shown) or the like.

The insulating layer 3 is also referred to as a bank or a pixel separation film. The insulating layer 3 covers the ends of the first electrode 2 and surrounds the first electrode 2. A portion not covered with the insulating layer 3 is in contact with the organic compound layers 4 and serves as a light-emitting region.

The organic compound layers 4 include a hole-injection layer 41, a hole-transport layer 42, a first light-emitting layer 43, a second light-emitting layer 44, and an electron-transport layer 45.

The second electrode 5 may be a transparent electrode, a reflective electrode, or a semitransparent electrode.

The protective layer 6 reduces the penetration of moisture into the organic compound layers 4. The protective layer 6 is illustrated as a single layer but may be a plurality of layers. The protective layer 6 may include an inorganic compound layer and an organic compound layer.

The color filter 7 is divided into 7R, 7G, and 7B according to the color. The color filter 7 may be formed on a planarization film (not shown). Furthermore, a resin protective layer (not shown) may be provided on the color filter 7. The color filter 7 may be formed on the protective layer 6. Alternatively, the color filter 7 may be bonded after being provided on an opposite substrate, such as a glass substrate.

A display apparatus 100 in FIG. 2B includes an organic light-emitting element 26 and a TFT 18 as an example of a transistor. The display apparatus 100 includes a substrate 11 made of glass, silicon, or the like and an insulating layer 12 on the substrate 11. An active element, such as the TFT 18, and a gate electrode 13, a gate-insulating film 14, and a semiconductor layer 15 of the active element are provided on the insulating layer 12. The TFT 18 is also composed of a drain electrode 16 and a source electrode 17. The TFT 18 is covered with an insulating film 19. A positive electrode 21 of the organic light-emitting element 26 is coupled to the source electrode 17 through a contact hole 20 formed in the insulating film 19.

The method for electrically connecting the electrodes (the positive electrode 21 and a negative electrode 23) of the organic light-emitting element 26 to the electrodes (the source electrode 17 and the drain electrode 16) of the TFT 18 is not limited to the embodiment illustrated in FIG. 2B. More specifically, it is only necessary to electrically connect either the positive electrode 21 or the negative electrode 23 to either the source electrode 17 or the drain electrode 16 of the TFT 18. TFT refers to a thin-film transistor.

Although an organic compound layer 22 is a single layer in the display apparatus 100 illustrated in FIG. 2B, the organic compound layer 22 may be composed of a plurality of layers. The negative electrode 23 is covered with a first protective layer 24 and a second protective layer 25 for preventing degradation of the organic light-emitting element 26.

Although the display apparatus 100 illustrated in FIG. 2B includes a transistor as a switching element, another element may be used instead as the switching element.

The transistor used in the display apparatus 100 in FIG. 2B is not limited to a transistor including a single crystal silicon wafer and may also be a thin-film transistor including an active layer on an insulating surface of a substrate. The active layer may be single-crystal silicon, non-single-crystal silicon, such as amorphous silicon or microcrystalline silicon, or a non-single-crystal oxide semiconductor, such as indium zinc oxide or indium gallium zinc oxide. The thin-film transistor is also referred to as a TFT element.

The transistor in the display apparatus 100 illustrated in FIG. 2B may be formed within a substrate, such as a Si substrate. The phrase “formed within a substrate” means that the substrate, such as a Si substrate, itself is processed to form the transistor. Thus, the transistor within the substrate can be considered that the substrate and the transistor are integrally formed.

In the organic light-emitting element according to the present embodiment, the luminous brightness is controlled with the TFT, which is an example of a switching element. The organic light-emitting element can be provided in a plurality of planes to display an image at each luminous brightness. The switching element according to the present embodiment is not limited to the TFT and may be a transistor formed of low-temperature polysilicon or an active-matrix driver formed on a substrate, such as a Si substrate. “On a substrate” may also be referred to as “within a substrate”. Whether a transistor is provided within a substrate or a TFT is used depends on the size of a display unit. For example, for an approximately 0.5-inch display unit, an organic light-emitting element can be provided on a Si substrate.

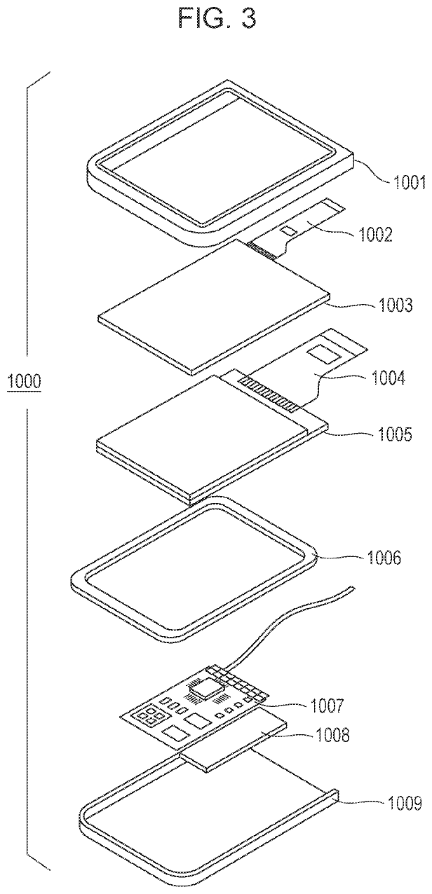

FIG. 3 is a schematic view of an example of the display apparatus according to the present embodiment. A display apparatus 1000 may include a touch panel 1003, a display panel 1005, a frame 1006, a circuit substrate 1007, and a battery 1008 between an upper cover 1001 and a lower cover 1009. The touch panel 1003 and the display panel 1005 are coupled to flexible print circuits FPC 1002 and 1004, respectively. Transistors are printed on the circuit substrate 1007. The battery 1008 may not be provided when the display apparatus is not a mobile device, or may be provided at another position even when the display apparatus is a mobile device.

The display apparatus according to the present embodiment may include color filters of red, green, and blue colors. In the color filters, the red, green, and blue colors may be arranged in a delta arrangement.

The display apparatus according to the present embodiment may be used for a display unit of a mobile terminal. Such a display apparatus may have both a display function and an operation function. Examples of the mobile terminal include mobile phones, such as smartphones, tablets, and head-mounted displays.

The display apparatus according to the present embodiment may be used for a display unit of an imaging apparatus that includes an optical unit with a plurality of lenses and an imaging element for receiving light passing through the optical unit. The imaging apparatus may include a display unit for displaying information acquired by the imaging element. The display unit may be a display unit exposed outside from the imaging apparatus or a display unit located in a finder. The imaging apparatus may be a digital camera or a digital video camera.

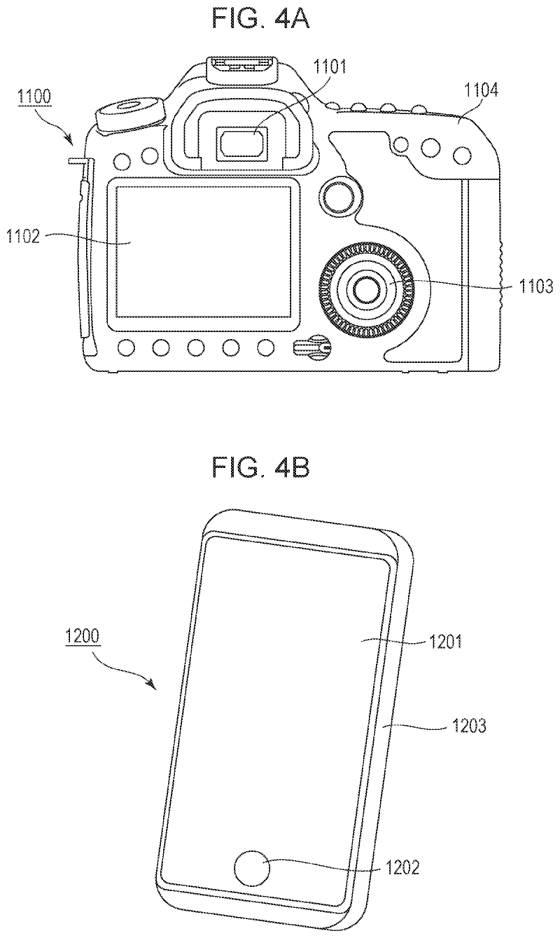

FIG. 4A is a schematic view of an example of the imaging apparatus according to the present embodiment. An imaging apparatus 1100 may include a viewfinder 1101, a rear display 1102, an operating unit 1103, and a housing 1104. The viewfinder 1101 may include the display apparatus according to the present embodiment. In such a case, the display apparatus may display environmental information, imaging instructions, and the like as well as an image to be captured. The environmental information may include the intensity of external light, the direction of external light, the travel speed of the photographic subject, the possibility that the photographic subject is shielded by a shielding material, and the like.

Because the appropriate timing for imaging is a short time, it is better to display information as soon as possible. Thus, a display apparatus including the organic light-emitting element according to the present embodiment can be used. This is because the organic light-emitting element has a high response speed. A display apparatus including the organic light-emitting element can be more suitably used than these apparatuses and liquid crystal displays that require a high display speed.

The imaging apparatus 1100 includes an optical unit (not shown). The optical unit has a plurality of lenses and focuses an image on an imaging element in the housing 1104. The focus of the lenses can be adjusted by adjusting their relative positions. This operation can also be automatically performed. The imaging apparatus may also be referred to as a photoelectric conversion apparatus. The photoelectric conversion apparatus can have, as an imaging method, a method of detecting a difference from a previous image or a method of cutting out a permanently recorded image, instead of taking an image one after another.

FIG. 4B is a schematic view of an example of electronic equipment according to the present embodiment. Electronic equipment 1200 includes a display unit 1201, an operating unit 1202, and a housing 1203. The housing 1203 may include a circuit, a printed circuit board including the circuit, a battery, and a communication unit. The operating unit 1202 may be a button or a touch panel response unit. The operating unit 1202 may be a biometric recognition unit that recognizes a fingerprint and releases the lock. Electronic equipment with a communication unit may also be referred to as communication equipment. The electronic equipment 1200 may have a lens and an imaging element and thereby further have a camera function. An image captured by the camera function is displayed on the display unit 1201. The electronic equipment 1200 may be a smartphone, a notebook computer, or the like.

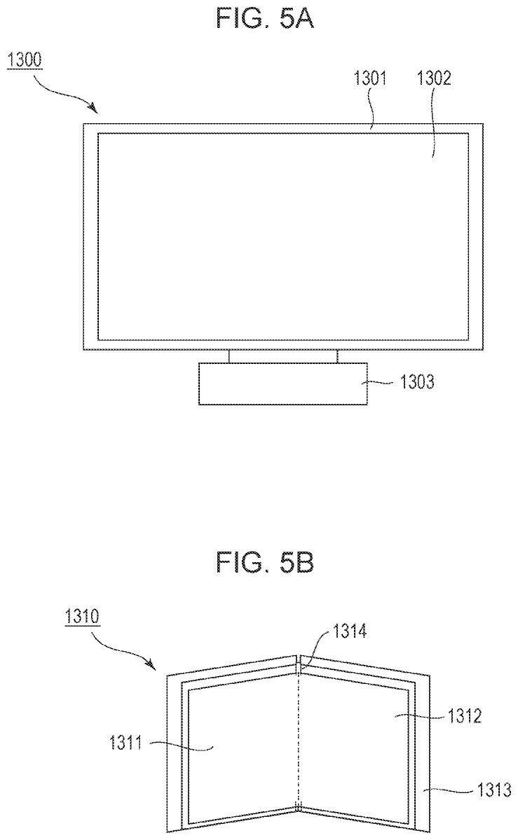

FIGS. 5A and 5B are schematic views of an example of the display apparatus according to the present embodiment. FIG. 5A illustrates a display apparatus, such as a television monitor or a PC monitor. A display apparatus 1300 includes a frame 1301 and a display unit 1302. The light-emitting element according to the present embodiment may be used for the display unit 1302. The frame 1301 and the display unit 1302 are supported by a base 1303. The base 1303 is not limited to the structure illustrated in FIG. 5A. The lower side of the frame 1301 may also serve as the base. The frame 1301 and the display unit 1302 may be bent. The radius of curvature may range from 5000 to 6000 mm.

FIG. 5B is a schematic view of another example of the display apparatus according to the present embodiment. A display apparatus 1310 illustrated in FIG. 5B is configured to be foldable and is a so-called foldable display apparatus. The display apparatus 1310 includes a first display unit 1311, a second display unit 1312, a housing 1313, and a folding point 1314. The first display unit 1311 and the second display unit 1312 may include the light-emitting element according to the present embodiment. The first display unit 1311 and the second display unit 1312 may be a single display apparatus without a joint. The first display unit 1311 and the second display unit 1312 can be divided by a folding point. The first display unit 1311 and the second display unit 1312 may display different images or one image.

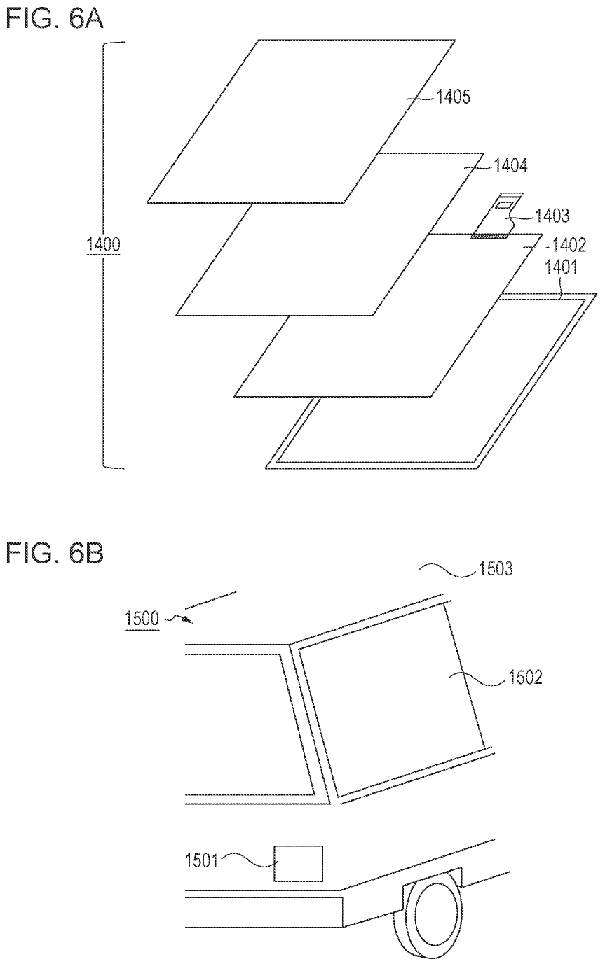

FIG. 6A is a schematic view of an example of a lighting apparatus according to the present embodiment. A lighting apparatus 1400 may include a housing 1401, a light source 1402, a circuit substrate 1403, an optical filter 1404 that transmits light emitted by the light source 1402, and a light-diffusing unit 1405. The light source 1402 may include the organic light-emitting element according to the present embodiment. The optical filter 1404 may be a filter that improves the color rendering properties of the light source. The light-diffusing unit 1405 can effectively diffuse light from the light source and widely spread light as in illumination. The optical filter 1404 and the light-diffusing unit 1405 may be provided on the light output side of the illumination. If necessary, a cover may be provided on the outermost side.

For example, the lighting apparatus is an interior lighting apparatus. The lighting apparatus may emit white light, neutral white light, or light of any color from blue to red. The lighting apparatus may have a light control circuit for controlling such light. The lighting apparatus may include the organic light-emitting element according to the present embodiment and a power supply circuit coupled thereto. The power supply circuit is a circuit that converts an AC voltage to a DC voltage. White has a color temperature of 4200 K, and neutral white has a color temperature of 5000 K. The lighting apparatus may have a color filter.

The lighting apparatus according to the present embodiment may include a heat dissipation unit. The heat dissipation unit releases heat from the apparatus to the outside and may be a metal or liquid silicon with a high specific heat.

FIG. 6B is a schematic view of an automobile as an example of a moving body according to the present embodiment. The automobile has a taillight as an example of a lamp. An automobile 1500 may have a taillight 1501, which comes on when a brake operation or the like is performed.

The taillight 1501 may include the organic light-emitting element according to the present embodiment. The taillight 1501 may include a protective member for protecting the organic light-emitting element. The protective member may be formed of any transparent material with moderately high strength and can be formed of polycarbonate or the like. The polycarbonate may be mixed with a furan dicarboxylic acid derivative, an acrylonitrile derivative, or the like.

The automobile 1500 may have a body 1503 and a window 1502 on the body 1503. The window 1502 may be a transparent display as long as it is not a window for checking the front and rear of the automobile. The transparent display may include the organic light-emitting element according to the present embodiment. In such a case, constituent materials, such as electrodes, of the organic light-emitting element are transparent materials.

The moving body according to the present embodiment may be a ship, an aircraft, a drone, or the like. The moving body may include a body and a lamp provided on the body. The lamp may emit light to indicate the position of the body. The lamp includes the organic light-emitting element according to the present embodiment.

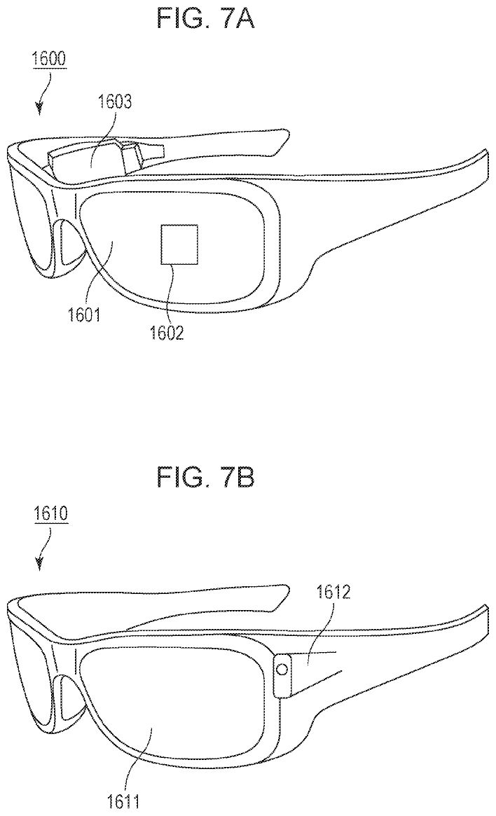

Application examples of the display apparatus according to each of the embodiments are described below with reference to FIGS. 7A and 7B. The display apparatus can be applied to a system that can be worn as a wearable device, such as smart glasses, a head-mounted display (HMID), or smart contact lenses. An imaging and displaying apparatus used in such an application example includes an imaging apparatus that can photoelectrically convert visible light and a display apparatus that can emit visible light.

FIG. 7A is a schematic view of an example of a wearable device according to an embodiment of the present disclosure. FIG. 7A illustrates glasses 1600 (smart glasses) according to one application example. An imaging apparatus 1602, such as a complementary metal-oxide semiconductor (CMOS) sensor or a single-photon avalanche photodiode (SPAD), is provided on the front side of a lens 1601 of the glasses 1600. The display apparatus according to one of the embodiments is provided on the back side of the lens 1601.

The glasses 1600 further include a controller 1603. The controller 1603 functions as a power supply for supplying power to the imaging apparatus 1602 and the display apparatus. The controller 1603 controls the operation of the imaging apparatus 1602 and the display apparatus. The lens 1601 has an optical system for focusing light on the imaging apparatus 1602.

FIG. 7B is a schematic view of another example of a wearable device according to an embodiment of the present disclosure. FIG. 7B illustrates glasses 1610 (smart glasses) according to one application example. The glasses 1610 have a controller 1612, which includes an imaging apparatus corresponding to the imaging apparatus 1602 of FIG. 7A and a display apparatus. A lens 1611 includes an optical system for projecting light from the imaging apparatus of the controller 1612 and the display apparatus, and an image is projected on the lens 1611. The controller 1612 functions as a power supply for supplying power to the imaging apparatus and the display apparatus and controls the operation of the imaging apparatus and the display apparatus.

The controller 1612 may include a line-of-sight detection unit for detecting the line of sight of the wearer. Infrared radiation may be used to detect the line of sight. An infrared radiation unit emits infrared light to an eyeball of a user who is gazing at a display image. Reflected infrared light from the eyeball is detected by an imaging unit including a light-receiving element to capture an image of the eyeball. A reduction unit for reducing light from the infrared radiation unit to a display unit in a plan view is provided to reduce degradation in image quality. The line of sight of the user for the display image is detected from the image of the eyeball captured by infrared imaging. Any known technique can be applied to line-of-sight detection using the image of the eyeball. For example, it is possible to use a line-of-sight detection method based on a Purkinje image obtained by reflection of irradiation light by the cornea. More specifically, a line-of-sight detection process based on a pupil-corneal reflection method is performed. The line of sight of the user is detected by calculating a line-of-sight vector representing the direction (rotation angle) of an eyeball on the basis of an image of a pupil and a Purkinje image included in a captured image of the eyeball using the pupil-corneal reflection method.

A display apparatus according to an embodiment of the present disclosure may include an imaging apparatus including a light-receiving element and may control a display image on the basis of line-of-sight information of a user from the imaging apparatus. More specifically, on the basis of the line-of-sight information, the display apparatus determines a first visibility region at which the user gazes and a second visibility region other than the first visibility region. The first visibility region and the second visibility region may be determined by the controller of the display apparatus or may be received from an external controller. In the display region of the display apparatus, the first visibility region may be controlled to have higher display resolution than the second visibility region. In other words, the second visibility region may have lower resolution than the first visibility region.

The display region has a first display region and a second display region different from the first display region, and the priority of the first display region and the second display region depends on the line-of-sight information. The first visibility region and the second visibility region may be determined by the controller of the display apparatus or may be received from an external controller. A region with a higher priority may be controlled to have higher resolution than another region. In other words, a region with a lower priority may have lower resolution.

The first visibility region or a region with a higher priority may be determined by artificial intelligence (AI). The AI may be a model configured to estimate the angle of the line of sight and the distance to a target ahead of the line of sight from an image of an eyeball using the image of the eyeball and the direction in which the eyeball actually viewed in the image as teaching data. The AI program may be stored in the display apparatus, the imaging apparatus, or an external device. The AI program stored in an external device is transmitted to the display apparatus via communication.

For display control based on visual recognition detection, the present disclosure can be applied to smart glasses further having an imaging apparatus for imaging the outside. Smart glasses can display captured external information in real time.

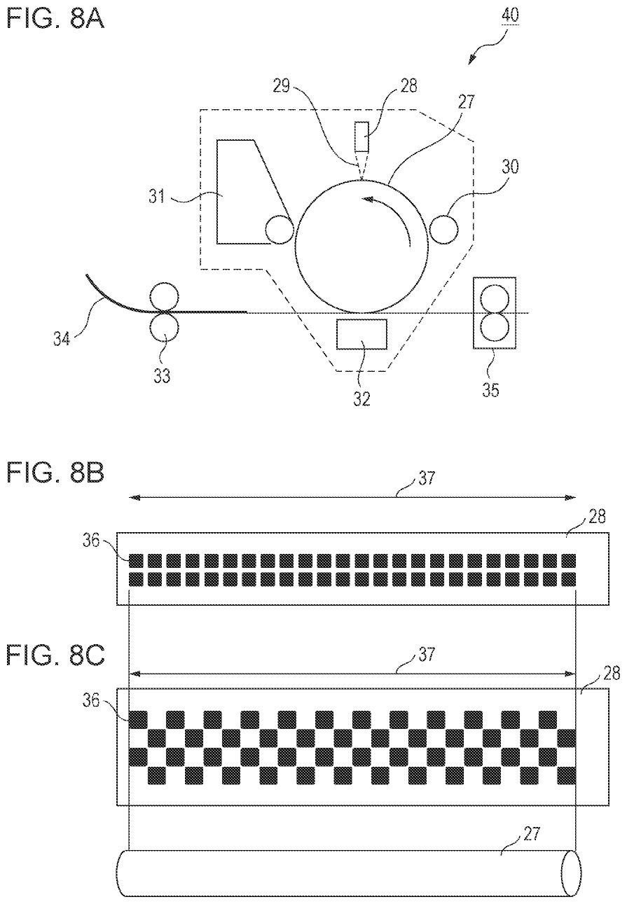

FIG. 8A is a schematic view of an example of an image-forming apparatus according to an embodiment of the present disclosure. An image-forming apparatus 40 is an electrophotographic image-forming apparatus and includes a photosensitive member 27, an exposure light source 28, a charging unit 30, a developing unit 31, a transfer unit 32, a conveying roller 33, and a fixing unit 35. The exposure light source 28 emits light 29, and an electrostatic latent image is formed on the surface of the photosensitive member 27. The exposure light source 28 includes the organic light-emitting element according to the present embodiment. The developing unit 31 contains toner and the like. The charging unit 30 electrifies the photosensitive member 27. The transfer unit 32 transfers a developed image onto a recording medium 34. The conveying roller 33 conveys the recording medium 34. The recording medium 34 is paper, for example. The fixing unit 35 fixes an image on the recording medium 34.

FIGS. 8B and 8C are schematic views of the exposure light source 28 in which a plurality of light-emitting portions 36 are arranged on a long substrate. An arrow 37 indicates a direction parallel to the axis of the photosensitive member and indicates a column direction in which the organic light-emitting elements are arranged. The column direction is the same as the direction of the rotation axis of the photosensitive member 27. This direction can also be referred to as the major-axis direction of the photosensitive member 27. In FIG. 8B, the light-emitting portions 36 are arranged in the major-axis direction of the photosensitive member 27. In FIG. 8C, unlike FIG. 8B, the light-emitting portions 36 are alternately arranged in the column direction in the first and second columns. The first and second columns are arranged at different positions in the row direction. In the first column, the light-emitting portions 36 are arranged at intervals. In the second column, the light-emitting portions 36 are arranged at positions corresponding to the spaces between the light-emitting portions 36 of the first column. Thus, the light-emitting portions 36 are also arranged at intervals in the row direction. The arrangement in FIG. 8C can also be referred to as a grid-like pattern, a staggered pattern, or a checkered pattern, for example.

As described above, an apparatus including the organic light-emitting element according to the present embodiment can be used to stably display a high-quality image for extended periods.

### EXAMPLES

The present disclosure is described below with exemplary embodiments. However, the present disclosure is not limited these exemplary embodiments.

### Exemplary Embodiment 1 (Synthesis of Exemplary Compound A1)

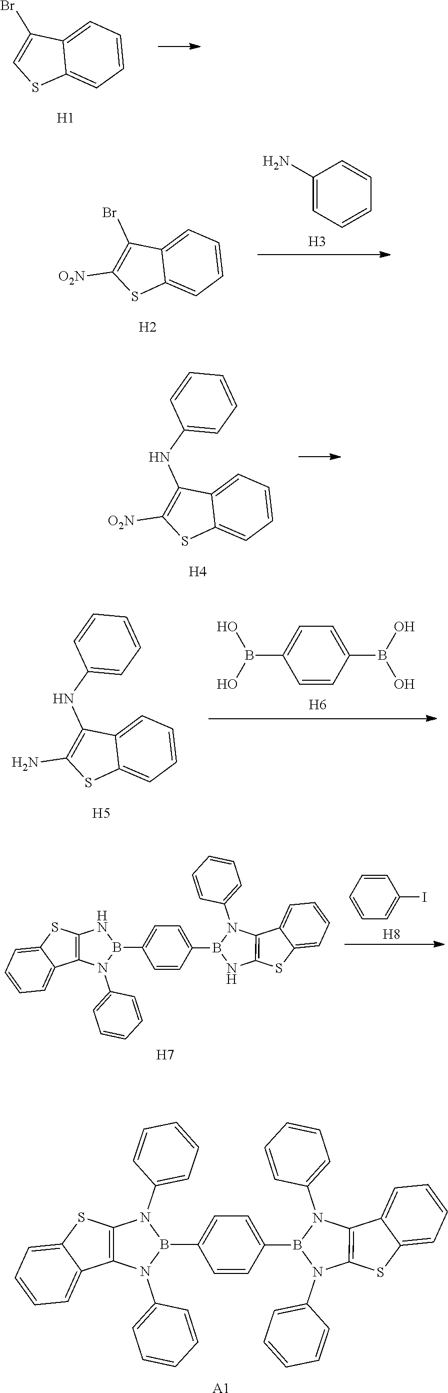

(1) Synthesis of Compound H2

A 300-mL recovery flask was charged with the following compound(s), reagent(s), and solvent(s).

Compound H1: 10.00 g (46.9 mmol)
Glacial acetic acid: 140 ml

The reaction solution was then stirred in a nitrogen stream at room temperature for 10 minutes, and 40 ml of acetic acid and 20 ml of HNO₃ were then mixed together and were gradually added dropwise to the reaction solution. After stirring at room temperature for 5 hours, the reaction solution was quenched with water and was filtered. The resulting filtrate was washed with water and was purified by recrystallization from ethyl acetate/heptane=1/1. Thus, 8.48 g of a yellow compound H2 was prepared (yield: 70%).

(2) Synthesis of Compound H4

A 300-mL recovery flask was charged with the following compound(s), reagent(s), and solvent(s).

Compound H2: 8.40 g (32.6 mmol)
Compound H3: 8.66 g (93.0 mmol)
Triethylamine: 4.95 g (48.9 mmol)

### DMF: 150 ml

The reaction solution was then heated in a nitrogen stream at 120° C. for 30 minutes and was then quenched with water. A solid was isolated by filtration, was washed with water, and was recrystallized from dichloromethane/heptane. Thus, 7.93 g of a yellow compound H4 was prepared (90% yield).

(3) Synthesis of Compound H5

A 300-ml recovery flask was charged with the following compound(s), reagent(s), and solvent(s).

Compound H4: 7.00 g (25.9 mmol)
Acetic acid: 150 ml

### Water: 150 ml

Next, 7.55 g (135 mmol) of an iron powder was added in small quantities to the reaction solution in a nitrogen stream. The reaction solution was stirred at room temperature for 2 hours, was passed through a Celite filter, and was washed with dichloromethane. The combined filtrate was washed with water and aqueous sodium carbonate. The solvent was evaporated, and the residue was then purified by silica gel column chromatography (hexane/dichloromethane=4/1). Thus, 4.05 g of a white compound H5 was prepared (yield: 65%).

(4) Synthesis of Compound H7

A 300-ml recovery flask was charged with the following compound(s), reagent(s), and solvent(s).

Compound H5: 3.00 g (12.5 mmol)
Compound H6: 2.07 g (12.5 mmol)

### Toluene: 150 ml

The reaction solution was then heated to 120° C. in a nitrogen stream and was stirred under reflux for 5 hours. After completion of the reaction, the reaction solution was concentrated, and heptane was added to the reaction solution. The reaction solution was then filtered, and the residue was then dispersed and washed with heptane. Thus, 3.95 g of a white compound H7 was prepared (yield: 55%).

(5) Synthesis of Exemplary Compound A1

A 200-ml recovery flask was charged with the following compound(s), reagent(s), and solvent(s).

Compound H7: 1.50 g (1.32 mmol)
Compound H8: 4.26 g (1.98 mmol)
Pd(OAc)₂: 15 mg (0.06 mmol)
Tri-O-tolylphosphine: 35 mg (0.12 mmol)
tBuOK: 0.67 g (5.90 mmol)

### Xylene: 75 ml

The reaction solution was then heated to 145° C. in a nitrogen stream and was stirred under reflux for 5 hours. After completion of the reaction, the reaction solution was filtered. The residue was purified by silica gel column chromatography (chlorobenzene) and was then recrystallized from toluene. Thus, 0.43 g of a white exemplary compound A1 was prepared (yield: 45%).

The exemplary compound A1 was subjected to mass spectrometry with MALDI-TOF-MS (Autoflex LRF manufactured by Bruker).

### [MALDI-TOF-MS]

Measured value: m/z=726 Calculated value: C₄₆H₃₂B₂N₄S₂=726

### Exemplary Embodiment 2 (Synthesis of Exemplary Compound A4)

Compounds up to the compound H7 were synthesized in the same manner as in Exemplary Embodiment 1.

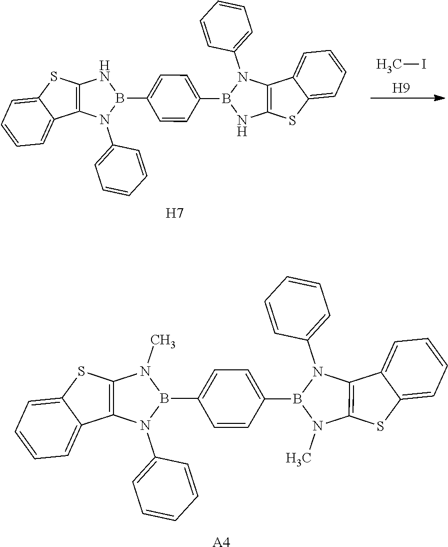

(1) Synthesis of Exemplary Compound A4

A 100-ml recovery flask was charged with the following compound(s), reagent(s), and solvent(s).

Compound H7: 1.50 g (1.32 mmol)
Compound H9: 0.94 g (6.60 mmol)
Triethylamine: 0.80 g (7.92 mmol)

### DMF: 50 ml

The reaction solution was then heated in a nitrogen stream at 120° C. for 30 minutes and was then quenched with water. A solid was isolated by filtration, was washed with water, was purified by silica gel column chromatography (chlorobenzene), and was recrystallized from cyclohexane. Thus, 0.43 g of a white exemplary compound A4 was prepared (yield: 55%).

The exemplary compound A4 was subjected to mass spectrometry with MALDI-TOF-MS (Autoflex LRF manufactured by Bruker).

[MALDI-TOF-MS]

Measured value: m/z=602 Calculated value: C₃₆H₂₈B₂N₄S₂=602

### Exemplary Embodiments 3 to 30 (Synthesis of Exemplary Compounds)

As shown in Tables 2 to 6, exemplary compounds in Exemplary Embodiments 3 to 30 were synthesized in the same manner as in Exemplary Embodiment 1 or 2 except that the raw material H1 of Exemplary Embodiment 1 was changed to a raw material 1, the raw material H3 of Exemplary Embodiment 1 was changed to a raw material 2, the raw material H6 of Exemplary Embodiment 1 was changed to a raw material 3, and the raw material H8 of Exemplary Embodiment 1 or the raw material H9 of Exemplary Embodiment 2 was changed to a raw material 4. Actual values m/z measured by mass spectrometry in the same manner as in Exemplary Embodiment 1 are also shown.

TABLE 2

| Exemplary | | | | Raw |
|---|---|---|---|---|
| embodiment | Exemplary compound | | | material 1 |
| 3 | 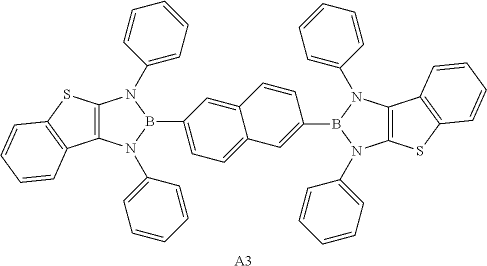 [SMILES: c1ccc(N2B(c3ccc4cc(B5N(c6ccccc6)c6sc7ccccc7c6N5c5ccccc5)ccc4c3)N(c3ccccc3)c3c2sc2ccccc32)cc1 ; "A3"] | | | H1 |
| 4 | 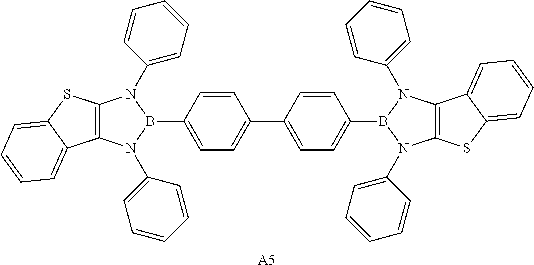 [SMILES: c1ccc(N2B(c3ccc(-c4ccc(B5N(c6ccccc6)c6sc7ccccc7c6N5c5ccccc5)cc4)cc3)N(c3ccccc3)c3c2sc2ccccc32)cc1 ; "A5"] | | | H1 |
| 5 | 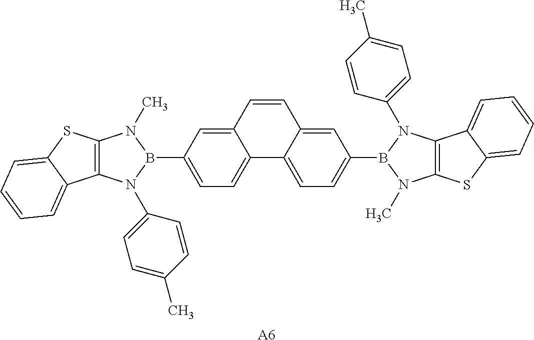 [SMILES: Cc1ccc(N2B(c3ccc4c(ccc5cc(B6N(C)c7sc8ccccc8c7N6c6ccc(C)cc6)ccc54)c3)N(C)c3sc4ccccc4c32)cc1 ; "A6"] | | | H1 |
| 6 | 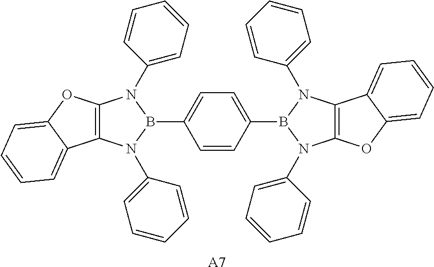 [SMILES: c1ccc(N2B(c3ccc(B4N(c5ccccc5)c5oc6ccccc6c5N4c4ccccc4)cc3)N(c3ccccc3)c3c2oc2ccccc32)cc1 ; "A7"] | | | 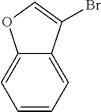 |
| 7 | 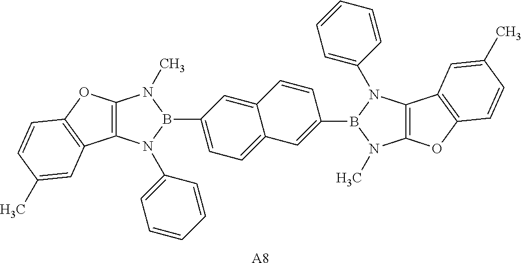 [SMILES: Cc1ccc2oc3c(c2c1)N(c1ccccc1)B(c1ccc2cc(B4N(C)c5oc6ccc(C)cc6c5N4c4ccccc4)ccc2c1)N3C ; "A8"] | | | 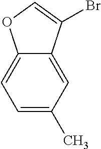 |
| Exemplary | Raw | Raw | Raw | |
| embodiment | material 2 | material 3 | material 4 | m/z |
| 3 | H3 | 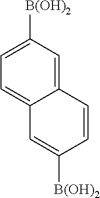 [SMILES: OB(O)c1ccc2cc(B(O)O)ccc2c1] | H8 | 776 |
| 4 | H3 | 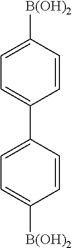 [SMILES: OB(O)c1ccc(-c2ccc(B(O)O)cc2)cc1] | H8 | 802 |
| 5 | 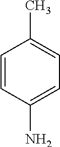 | 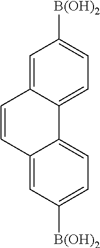 [SMILES: OB(O)c1ccc2c(ccc3cc(B(O)O)ccc32)c1] | H9 | 730 |
| 6 | H3 | H6 | H8 | 694 |
| 7 | H3 | 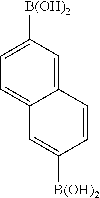 [SMILES: OB(O)c1ccc2cc(B(O)O)ccc2c1] | H9 | 648 |

TABLE 3

| Exemplary | | | | Raw material |
|---|---|---|---|---|
| embodiment | Exemplary compound | | | 1 |
| 8 | 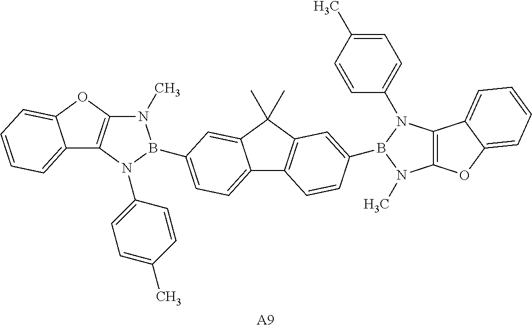 [SMILES: Cc1ccc(N2B(c3ccc4c(c3)C(C)(C)c3cc(B5N(C)c6oc7ccccc7c6N5c5ccc(C)cc5)ccc3-4)N(C)c3oc4ccccc4c32)cc1 ; "A9"] | | | 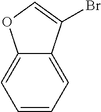 |
| 9 | 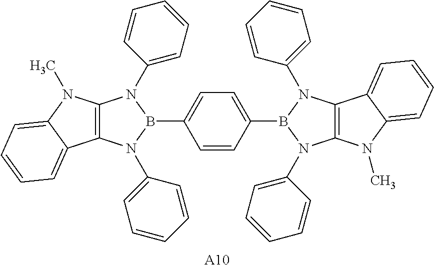 [SMILES: Cn1c2c(c3ccccc31)N(c1ccccc1)B(c1ccc(B3N(c4ccccc4)c4c(n(C)c5ccccc45)N3c3ccccc3)cc1)N2c1ccccc1 ; "A10"] | | | 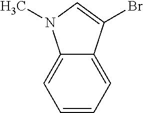 |
| 10 | 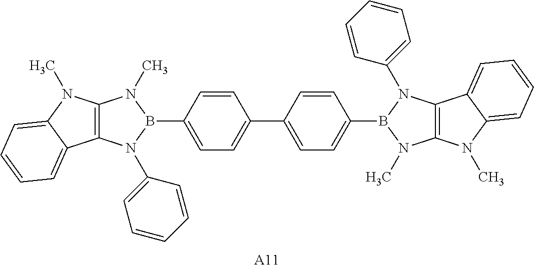 [SMILES: CN1B(c2ccc(-c3ccc(B4N(C)c5c(c6ccccc6n5C)N4c4ccccc4)cc3)cc2)N(c2ccccc2)c2c1n(C)c1ccccc21 ; "A11"] | | | 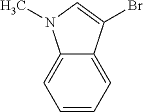 |
| 11 | 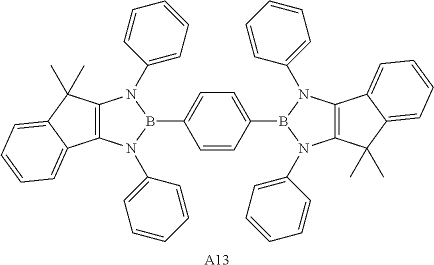 [SMILES: CC1(C)C2=C(c3ccccc31)N(c1ccccc1)B(c1ccc(B3N(c4ccccc4)C4=C(N3c3ccccc3)C(C)(C)c3ccccc34)cc1)N2c1ccccc1 ; "A13"] | | | 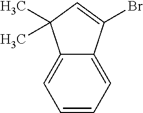 |
| 12 | 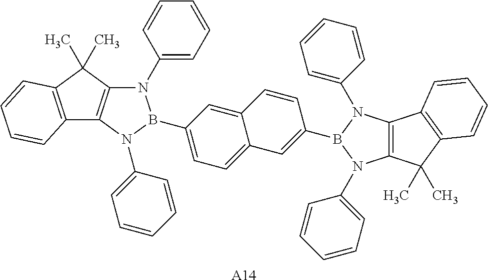 [SMILES: CC1(C)C2=C(c3ccccc31)N(c1ccccc1)B(c1ccc3cc(B4N(c5ccccc5)C5=C(N4c4ccccc4)C(C)(C)c4ccccc45)ccc3c1)N2c1ccccc1 ; "A14"] | | | 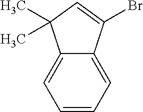 |
| | Raw | | Raw | |
| Exemplary | material | Raw | material | |
| embodiment | 2 | material 3 | 4 | m/z |
| 8 | 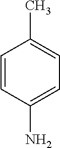 | 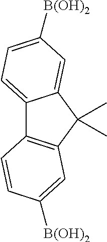 [SMILES: CC1(C)c2cc(B(O)O)ccc2-c2ccc(B(O)O)cc21] | H9 | 714 |
| 9 | H3 | H6 | H8 | 720 |
| 10 | H3 | 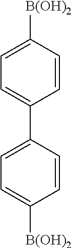 [SMILES: OB(O)c1ccc(-c2ccc(B(O)O)cc2)cc1] | H9 | 672 |
| 11 | H3 | H6 | H8 | 746 |
| 12 | H3 | 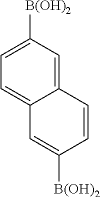 [SMILES: OB(O)c1ccc2cc(B(O)O)ccc2c1] | H8 | 796 |

TABLE 4

| Exemplary | | Raw | Raw | Raw | Raw | |
|---|---|---|---|---|---|---|
| embodiment | Exemplary compound | material 1 | material 2 | material 3 | material 4 | m/z |
| 13 | 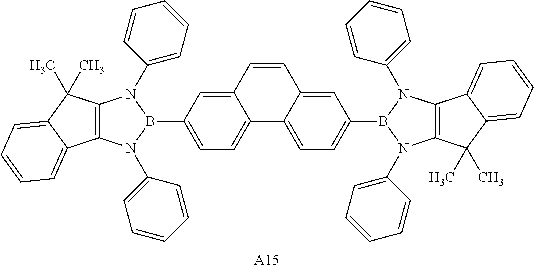 [SMILES: CC1(C)C2=C(c3ccccc31)N(c1ccccc1)B(c1ccc3c(ccc4cc(B5N(c6ccccc6)C6=C(N5c5ccccc5)C(C)(C)c5ccccc56)ccc43)c1)N2c1ccccc1 ; "A15"] | 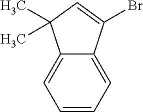 | H3 | 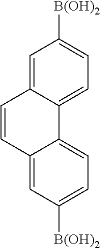 [SMILES: OB(O)c1ccc2c(ccc3cc(B(O)O)ccc32)c1] | H8 | 846 |
| 14 | 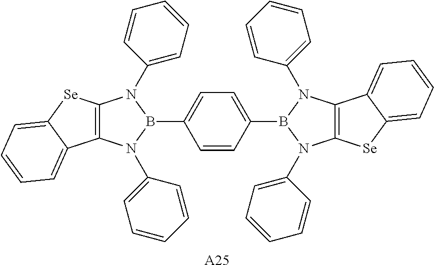 [SMILES: c1ccc(N2B(c3ccc(B4N(c5ccccc5)c5[se]c6ccccc6c5N4c4ccccc4)cc3)N(c3ccccc3)c3c2[se]c2ccccc32)cc1 ; "A25"] | 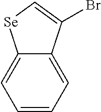 | H3 | H6 | H8 | 822 |
| 15 | 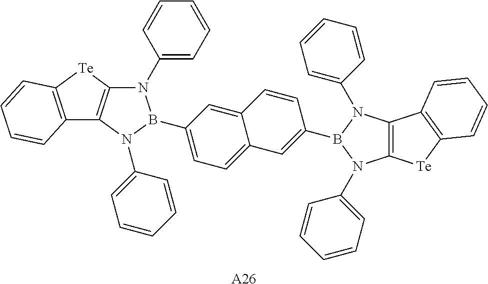 | 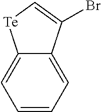 | H3 | 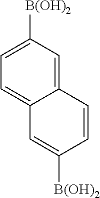 [SMILES: OB(O)c1ccc2cc(B(O)O)ccc2c1] | H8 | 972 |
| 16 | 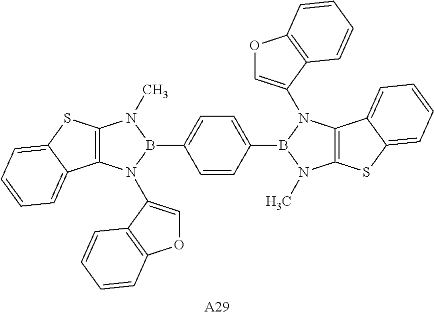 [SMILES: CN1B(c2ccc(B3N(C)c4sc5ccccc5c4N3c3coc4ccccc34)cc2)N(c2coc3ccccc23)c2c1sc1ccccc21 ; "A29"] | H1 | 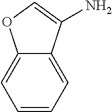 | H6 | H9 | 682 |
| 17 | 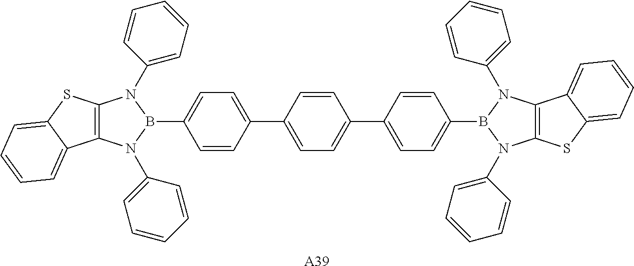 [SMILES: c1ccc(N2B(c3ccc(-c4ccc(-c5ccc(B6N(c7ccccc7)c7sc8ccccc8c7N6c6ccccc6)cc5)cc4)cc3)N(c3ccccc3)c3c2sc2ccccc32)cc1 ; "A39"] | H1 | H3 | 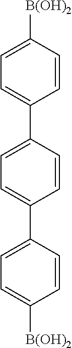 [SMILES: OB(O)c1ccc(-c2ccc(-c3ccc(B(O)O)cc3)cc2)cc1] | H8 | 878 |

TABLE 5

| Exemplary | | Raw material | Raw | Raw | Raw | |
|---|---|---|---|---|---|---|
| embodiment | Exemplary compound | 1 | material 2 | material 3 | material 4 | m/z |
| 18 | 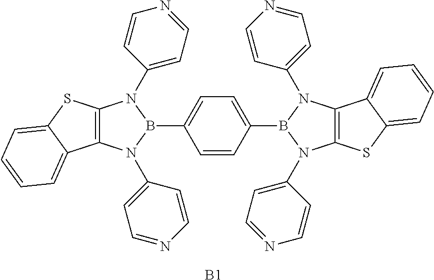 [SMILES: c1ccc2c3c(sc2c1)N(c1ccncc1)B(c1ccc(B2N(c4ccncc4)c4sc5ccccc5c4N2c2ccncc2)cc1)N3c1ccncc1 ; "B1"] | H1 | 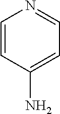 | H6 | 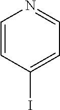 | 730 |
| 19 | 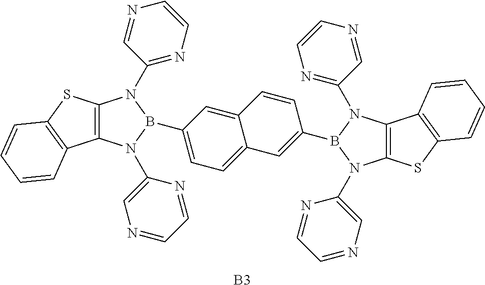 [SMILES: c1ccc2c3c(sc2c1)N(c1cnccn1)B(c1ccc2cc(B4N(c5cnccn5)c5sc6ccccc6c5N4c4cnccn4)ccc2c1)N3c1cnccn1 ; "B3"] | H1 | 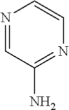 | H6 | 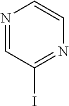 | 784 |
| 20 | 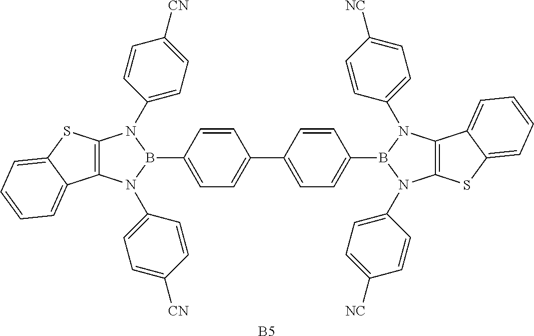 [SMILES: N#Cc1ccc(N2B(c3ccc(-c4ccc(B5N(c6ccc(C#N)cc6)c6sc7ccccc7c6N5c5ccc(C#N)cc5)cc4)cc3)N(c3ccc(C#N)cc3)c3c2sc2ccccc32)cc1 ; "B5"] | H1 | 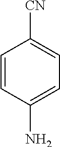 | 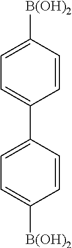 [SMILES: OB(O)c1ccc(-c2ccc(B(O)O)cc2)cc1] | 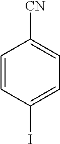 | 902 |
| 21 | 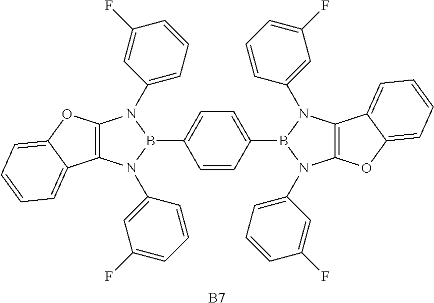 | 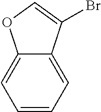 | 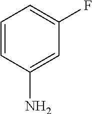 | H6 | 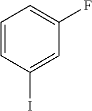 | 766 |
| 22 | 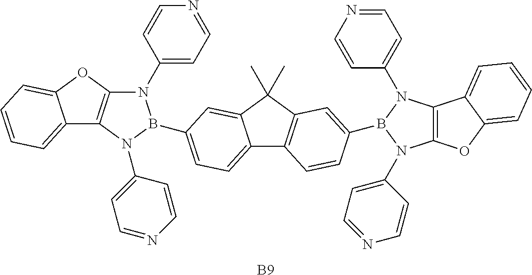 | 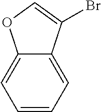 | 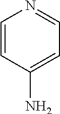 | 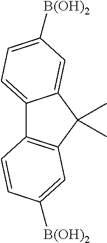 [SMILES: CC1(C)c2cc(B(O)O)ccc2-c2ccc(B(O)O)cc21] | 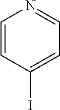 | 814 |
| 23 | 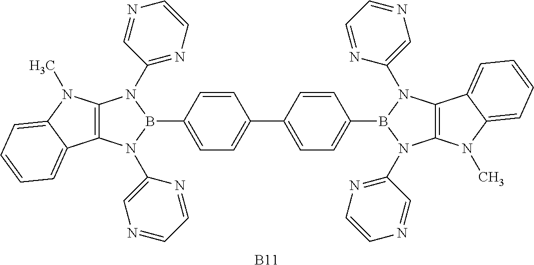 | 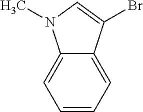 | 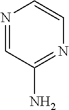 | 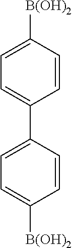 [SMILES: OB(O)c1ccc(-c2ccc(B(O)O)cc2)cc1] | 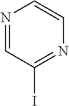 | 804 |
| 24 | 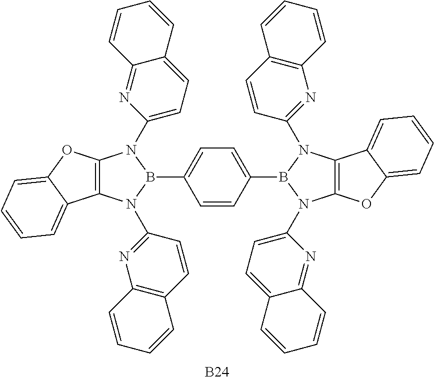 | 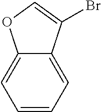 | 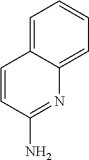 [SMILES: Nc1ccc2ccccc2n1] | H6 | 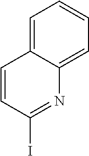 [SMILES: Ic1ccc2ccccc2n1] | 898 |

TABLE 6

| Exemplary | | Raw | Raw | Raw | Raw | |
|---|---|---|---|---|---|---|
| embodiment | Exemplary compound | material 1 | material 2 | material 3 | material 4 | m/z |
| 25 | 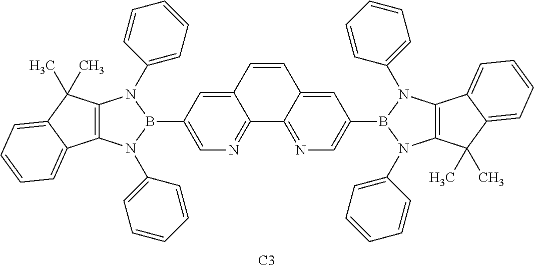 [SMILES: CC1(C)C2=C(c3ccccc31)N(c1ccccc1)B(c1cnc3c(ccc4cc(B5N(c6ccccc6)C6=C(N5c5ccccc5)C(C)(C)c5ccccc56)cnc43)c1)N2c1ccccc1 ; "C3"] | 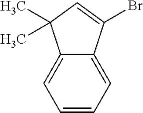 | H3 | 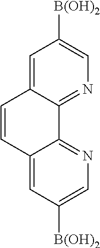 [SMILES: OB(O)c1cnc2c(ccc3cc(B(O)O)cnc32)c1] | H8 | 848 |
| 26 | 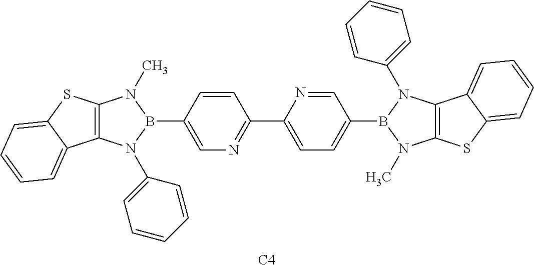 [SMILES: CN1B(c2ccc(-c3ccc(B4N(C)c5sc6ccccc6c5N4c4ccccc4)cn3)nc2)N(c2ccccc2)c2c1sc1ccccc21 ; "C4"] | H1 | H3 | 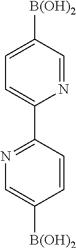 [SMILES: OB(O)c1ccc(-c2ccc(B(O)O)cn2)nc1] | H9 | 680 |
| 27 | 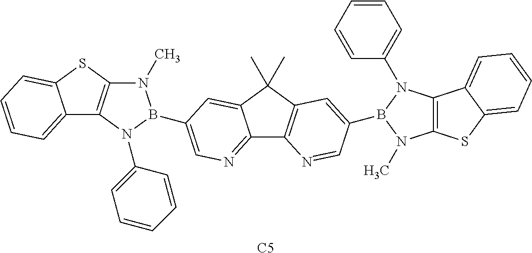 | H1 | H3 | 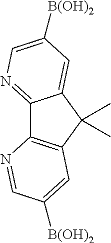 [SMILES: CC1(C)c2cc(B(O)O)cnc2-c2ncc(B(O)O)cc21] | H9 | 720 |
| 28 | 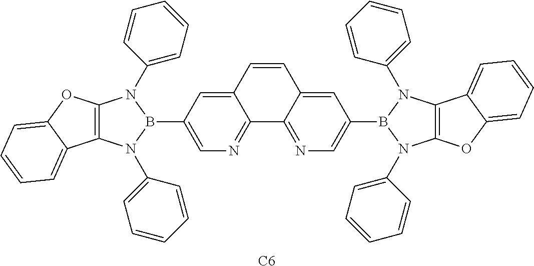 | 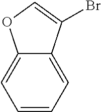 | H3 | 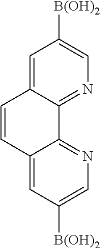 [SMILES: OB(O)c1cnc2c(ccc3cc(B(O)O)cnc32)c1] | H8 | 796 |
| 29 | 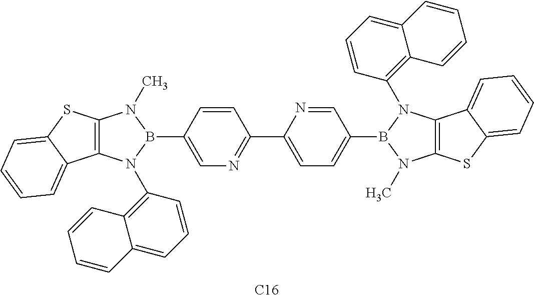 [SMILES: CN1B(c2ccc(-c3ccc(B4N(C)c5sc6ccccc6c5N4c4cccc5ccccc45)cn3)nc2)N(c2cccc3ccccc23)c2c1sc1ccccc21 ; "C16"] | H1 | 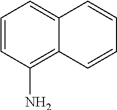 [SMILES: Nc1cccc2ccccc12] | 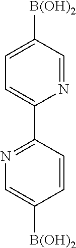 [SMILES: OB(O)c1ccc(-c2ccc(B(O)O)cn2)nc1] | H9 | 780 |
| 30 | 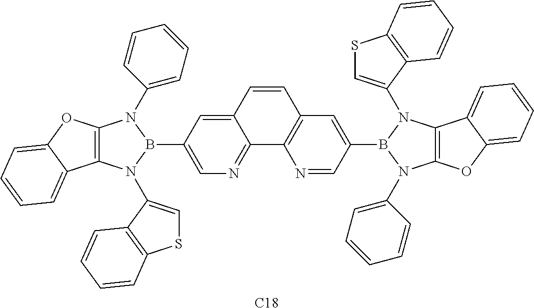 [SMILES: c1ccc(N2B(c3cnc4c(ccc5cc(B6N(c7ccccc7)c7oc8ccccc8c7N6c6csc7ccccc67)cnc54)c3)N(c3csc4ccccc34)c3c2oc2ccccc32)cc1 ; "C18"] | 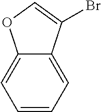 | H1 | 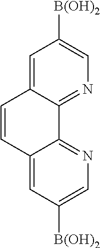 [SMILES: OB(O)c1cnc2c(ccc3cc(B(O)O)cnc32)c1] | H8 | 908 |

### Exemplary Embodiment 31

An organic EL device of a bottom emission type produced in the present exemplary embodiment included a positive electrode, a hole-injection layer, a hole-transport layer, an electron-blocking layer, a light-emitting layer, a hole-blocking layer, an electron-transport layer, an electron-injection layer, and a negative electrode on a substrate.

First, an ITO film was formed on a glass substrate and was subjected to desired patterning to form an ITO electrode (positive electrode). The ITO electrode had a thickness of 100 nm. The substrate on which the ITO electrode was formed was used as an ITO substrate in the following process. Vacuum vapor deposition was then performed by resistance heating in a vacuum chamber to continuously form an organic compound layer and an electrode layer shown in Table 7 on the ITO substrate. The counter electrode (a metal electrode layer, a negative electrode) had an electrode area of 3 mm².

TABLE 7

| | | | | Film |
|---|---|---|---|---|
| | Material | | | thickness (nm) |
| Negative electrode | Al | | | 100 |
| Electron-injection | LiF | | | 1 |
| layer (EIL) | | | | |
| Electron-transport | ET2 | | | 10 |
| layer (ETL) | | | | |
| Hole-blocking | ET12 | | | 20 |
| layer (HBL) | | | | |
| Light-emitting | Host | EM4 | Weight ratio | 30 |
| layer (EML) | Guest | A1 | EM4:A1 = | |
| | | | 99.5:0.5 | |

| | | |
|---|---|---|
| Electron-blocking | HT7 | 15 |
| layer (EBL) | | |
| Hole-transport | HT3 | 30 |
| layer (HTL) | | |
| Hole-injection | HT16 | 5 |
| layer (HIL) | | |

The characteristics of the element were measured and evaluated. The light-emitting element emitted blue light with a maximum current efficiency of 12.5 cd/A. More specifically, the current-voltage characteristics were measured with a microammeter 4140B manufactured by Hewlett-Packard Co., and the luminous brightness was measured with a BM7 manufactured by Topcon Corporation. A continuous operation test was performed at a current density of 20 mA/cm² to measure the time (LT95) when the luminance decay rate reached 500. The LT95 was 110 hours. Table 8 shows the measurement results.

### Exemplary Embodiments 32 to 47, Comparative Example 1

Organic light-emitting elements were produced in the same manner as in Exemplary Embodiment 31 except that the compounds shown in Table 8 were used. Characteristics of the elements were measured and evaluated in the same manner as in Exemplary Embodiment 31. Table 8 shows the measurement results. The comparative compound 1-a is the compound 1-a described in PTL 1.

TABLE 8

| | | | | EML | | | | Current | | |
|---|---|---|---|---|---|---|---|---|---|---|
| | | | | | Light-emitting | | | efficiency | LT95 | Emission |
| | HIL | HTL | EBL | Host | material | HBL | ETL | [cd/A] | [h] | color |
| Exemplary | HT16 | HT3 | HT7 | EM4 | A1 | ET12 | ET2 | 12.5 | 110 | Blue |
| embodiment 31 | | | | | | | | | | |
| Exemplary | HT16 | HT3 | HT12 | EM3 | A3 | ET10 | ET2 | 11.7 | 113 | Blue |
| embodiment 32 | | | | | | | | | | |
| Exemplary | HT16 | HT3 | HT8 | EM2 | A4 | ET12 | ET2 | 11.0 | 107 | Blue |
| embodiment 33 | | | | | | | | | | |
| Exemplary | HT16 | HT3 | HT12 | EM5 | A5 | ET12 | ET2 | 12.0 | 115 | Blue |
| embodiment 34 | | | | | | | | | | |
| Exemplary | HT16 | HT3 | HT12 | EM3 | A9 | ET12 | ET2 | 11.6 | 103 | Blue |
| embodiment 35 | | | | | | | | | | |
| Exemplary | HT16 | HT2 | HT10 | EM6 | A11 | ET12 | ET5 | 12.0 | 110 | Blue |
| embodiment 36 | | | | | | | | | | |
| Exemplary | HT16 | HT3 | HT12 | EM25 | A15 | ET12 | ET2 | 10.8 | 105 | Blue |
| embodiment 37 | | | | | | | | | | |
| Exemplary | HT16 | HT3 | HT8 | EM11 | A39 | ET10 | ET2 | 12.3 | 112 | Blue |
| embodiment 38 | | | | | | | | | | |
| Exemplary | HT16 | HT3 | HT12 | EM3 | B1 | ET12 | ET2 | 10.5 | 115 | Blue |
| embodiment 39 | | | | | | | | | | |
| Exemplary | HT16 | HT3 | HT12 | EM6 | B5 | ET12 | ET2 | 11.8 | 118 | Blue |
| embodiment 40 | | | | | | | | | | |
| Exemplary | HT16 | HT3 | HT12 | EM2 | B7 | ET10 | ET2 | 10.7 | 113 | Blue |
| embodiment 41 | | | | | | | | | | |
| Exemplary | HT16 | HT3 | HT12 | EM3 | B9 | ET12 | ET2 | 10.8 | 115 | Blue |
| embodiment 42 | | | | | | | | | | |
| Exemplary | HT16 | HT3 | HT12 | EM2 | B12 | ET12 | ET2 | 10.5 | 110 | Blue |
| embodiment 43 | | | | | | | | | | |
| Exemplary | HT16 | HT3 | HT12 | EM11 | C3 | ET12 | ET2 | 11.8 | 118 | Blue |
| embodiment 44 | | | | | | | | | | |
| Exemplary | HT16 | HT3 | HT12 | EM26 | C4 | ET12 | ET5 | 11.5 | 115 | Blue |
| embodiment 45 | | | | | | | | | | |
| Exemplary | HT16 | HT3 | HT12 | EM2 | C5 | ET12 | ET2 | 11.0 | 115 | Blue |
| embodiment 46 | | | | | | | | | | |
| Exemplary | HT16 | HT3 | HT9 | EM6 | C16 | ET12 | ET5 | 11.8 | 118 | Blue |
| embodiment 47 | | | | | | | | | | |
| Comparative | HT16 | HT3 | HT7 | EM3 | Comparative | ET12 | ET2 | 8.0 | 70 | Violet |
| example 1 | | | | | compound 1-a | | | | | |

Table 8 shows that Comparative Example 1 including the comparative compound 1-a has a current efficiency of 8.0 cd/A or less and a 5% degradation life (LT95) of 70 hours or less, which are lower than the current efficiency and durability of the blue-light-emitting elements according to the present exemplary embodiments. By contrast, the elements including the organic compounds according to the present embodiment have high durability. This is because the compounds according to the present embodiment, which have a diazaborole skeleton with a fused-ring structure, have an emission wavelength suitable for blue light emission, have a low LUMO level, and have high stability against oxygen.

### Exemplary Embodiment 48

Organic light-emitting elements were produced in the same manner as in Exemplary Embodiment 31 except that the compounds shown in Table 9 were used. Characteristics of the elements were measured and evaluated in the same manner as in Exemplary Embodiment 31.

TABLE 9

| | | | | Film |
|---|---|---|---|---|
| | Material | | | thickness (nm) |
| Negative electrode | Al | | | 100 |
| Electron-injection | LiF | | | 1 |
| layer (EIL) | | | | |
| Electron-transport | ET2 | | | 10 |
| layer (ETL) | | | | |
| Hole-blocking | ET12 | | | 20 |
| layer (HBL) | | | | |
| Light-emitting | First host | EM4 | Weight ratio | 30 |
| layer (EML) | Second host | A5 | EM4:A5:GD1 = | |
| | Guest | GD1 | 89.5:10.0:0.5 | |

| | | |
|---|---|---|
| Electron-blocking | HT7 | 15 |
| layer (EBL) | | |
| Hole-transport | HT3 | 30 |
| layer (HTL) | | |
| Hole-injection | HT16 | 5 |
| layer (HIL) | | |

The characteristics of the element were measured and evaluated. As a result, the light-emitting element emitted good green light. The measuring apparatuses described in Exemplary Embodiment 31 were used. A continuous operation test was performed at a current density of 100 mA/cm² to measure the time (LT95) when the luminance decay rate reached 5%. The LT95 was more than 410 hours. Table 10 shows the measurement results.

### Exemplary Embodiments 49 to 56, Comparative Examples 2 and 3

Organic light-emitting elements were produced in the same manner as in Exemplary Embodiment 48 except that the compounds shown in Table 10 were used. The mass ratio of a first host to the guest was 99.5:0.5 in Exemplary Embodiments 54 to 56 and Comparative Example 3. Characteristics of the elements were measured and evaluated in the same manner as in Exemplary Embodiment 48. Table 10 shows the measurement results.

TABLE 10

| | EML | | | | |
|---|---|---|---|---|---|
| | First | Second | Third | Emission | LT95 |
| | host | host | guest | color | [h] |
| Exemplary | EM4 | A5 | GD1 | Green | 410 |
| embodiment 48 | | | | | |
| Exemplary | EM3 | A39 | GD1 | Green | 450 |
| embodiment 49 | | | | | |
| Exemplary | EM26 | B7 | GD5 | Green | 430 |
| embodiment 50 | | | | | |
| Exemplary | EM3 | B9 | RD1 | Red | 505 |
| embodiment 51 | | | | | |
| Exemplary | EM4 | C3 | RD1 | Red | 530 |
| embodiment 52 | | | | | |
| Exemplary | EM25 | C18 | RD1 | Red | 510 |
| embodiment 53 | | | | | |
| Exemplary | A11 | | GD1 | Green | 455 |
| embodiment 54 | | | | | |
| Exemplary | A15 | | GD1 | Green | 480 |
| embodiment 55 | | | | | |
| Exemplary | C6 | | RD1 | Red | 500 |
| embodiment 56 | | | | | |
| Comparative | EM4 | Comparative | GD1 | Green | 255 |
| example 2 | | compound | | | |
| | | 1-a | | | |
| Comparative | Comparative | | RD1 | Red | 280 |
| example 3 | compound | | | | |
| | 1-a | | | | |

Table 10 shows that Comparative Examples 2 and 3 have a 500 degradation life of 400 hours or less and have low durability, whereas the elements including the organic compounds according to the present embodiment have a 5% degradation life of more than 400 hours. Thus, the exemplary embodiments have a longer life. The elements including the organic compounds according to the present embodiment have high durability.

### Exemplary Embodiment 57

An organic EL device of the top emission type produced in the present exemplary embodiment included a positive electrode, a hole-injection layer, a hole-transport layer, an electron-blocking layer, a first light-emitting layer, a second light-emitting layer, a hole-blocking layer, an electron-transport layer, an electron-injection layer, and a negative electrode on a substrate.

A 40-nm multilayer film of Al and Ti was formed on a glass substrate by a sputtering method and was patterned by photolithography to form a positive electrode. The counter electrode (a metal electrode layer, a negative electrode) had an electrode area of 3 mm². The substrate on which up to a cleaned electrode was formed and a material were mounted in a vacuum evaporator (manufactured by ULVAC, Inc.). After the vacuum evaporator was evacuated to 1.3×10⁻⁴ Pa (1×10⁻⁶ Torr), UV/ozone cleaning was performed. A film with a layer structure shown in Table 11 was then formed and was finally sealed in a nitrogen atmosphere.

TABLE 11

| | | | | Film |
|---|---|---|---|---|
| | Material | | | thickness (nm) |
| Negative electrode | Mg | Mass ratio | | 10 |
| | Ag | Mg:Ag = 50:50 | | |
| Electron-injection | LiF | | | 1 |
| layer (EIL) | | | | |
| Electron-transport | ET2 | | | 30 |
| layer (ETL) | | | | |
| Hole-blocking | ET12 | | | 75 |
| layer (HBL) | | | | |
| Second light-emitting | Second host | EM1 | Weight ratio | 10 |
| layer (2nd EML) | Second guest | A1 | EM1:A1 = | |
| | (Blue dopant) | | 99.5:0.5 | |
| First light-emitting | First host | EM1 | Weight ratio | 10 |
| layer (1st EML) | First guest | RD1 | EM1:RD1:GD6 = | |
| | (Red dopant) | | 97.5:0.5:2.0 | |
| | Third guest | GD6 | | |
| | (Green dopant) | | | |

| | | |
|---|---|---|
| Electron-blocking | HT8 | 10 |
| layer (EBL) | | |
| Hole-transport | HT2 | 20 |
| layer (HTL) | | |
| Hole-injection | HT16 | 5 |
| layer (HIL) | | |

The characteristics of the element were measured and evaluated. The element emitted good white light. Furthermore, a continuous operation test was performed at an initial luminance of 1000 cd/m², and the luminance decay rate after 100 hours was measured. Table 12 shows the results.

### Exemplary Embodiments 58 to 64, Comparative Example 4

Organic light-emitting elements were produced in the same manner as in Exemplary Embodiment 57 except that the compounds shown in Table 12 were used. Characteristics of the elements were measured and evaluated in the same manner as in Exemplary Embodiment 57. Table 12 shows the measurement results.

TABLE 12

| | 1st EML | | | 2nd EML | | Luminance |
|---|---|---|---|---|---|---|
| | First | First | Third | Second | Second | decay rate |
| | host | guest | guest | host | guest | [%] |
| Exemplary | EM1 | RD1 | GD6 | EM1 | A1 | 35 |
| embodiment 57 | | | | | | |
| Exemplary | EM1 | RD1 | GD7 | EM1 | A3 | 32 |
| embodiment 58 | | | | | | |
| Exemplary | EM1 | RD1 | GD5 | EM3 | A39 | 28 |
| embodiment 59 | | | | | | |
| Exemplary | EM26 | RD1 | GD6 | EM15 | B5 | 27 |
| embodiment 60 | | | | | | |
| Exemplary | EM4 | RD1 | GD6 | EM4 | B7 | 35 |
| embodiment 61 | | | | | | |
| Exemplary | EM25 | RD1 | GD6 | EM2 | B9 | 28 |
| embodiment 62 | | | | | | |
| Exemplary | EM4 | RD1 | GD6 | EM3 | C4 | 26 |
| embodiment 63 | | | | | | |
| Exemplary | EM1 | RD1 | GD7 | EM15 | C6 | 28 |
| embodiment 64 | | | | | | |
| Comparative | EM4 | RD1 | GD7 | EM3 | Comparative | 60 |
| example 4 | | | | | compound | |
| | | | | | 1-a | |

Table 12 shows that the luminance decay rate was 6000 in the organic light-emitting element including the comparative compound 1-a. This is because the use of the comparative compound 1-a as a guest increases the LUMO level and reduces stability against oxygen. By contrast, the elements including the organic compounds according to the present embodiment have high durability. This is because the compounds according to the present embodiment, which have the diazaborole skeleton with the fused-ring structure, have a low LUMO level and high stability against oxygen.

Thus, the organic compounds according to the present embodiment can emit blue light with high light emission efficiency, high color purity, and a deep LUMO level (far from the vacuum level) Thus, an organic compound according to the present embodiment can be used for an organic light-emitting element to provide the organic light-emitting element with high color purity, light emission efficiency, and durability.

An organic compound according to the present disclosure is a blue-light-emitting material with high color purity and light emission efficiency. Thus, it is possible to provide an organic light-emitting element with high color purity and light emission efficiency.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-021454 filed Feb. 15, 2022, which is hereby incorporated by reference herein in its entirety.

What is claimed is:

1. An organic compound represented by the following general formula [1]: 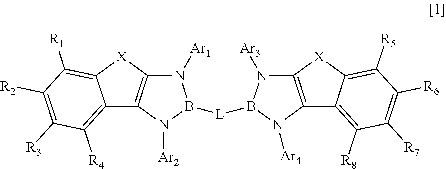
wherein R₁ to R₈ are independently selected from the group consisting of a hydrogen atom, halogen atoms, substituted and unsubstituted alkyl groups, substituted and unsubstituted alkoxy groups, substituted and unsubstituted amino groups, substituted and unsubstituted aryl groups, substituted and unsubstituted aryloxy groups, substituted and unsubstituted heteroaryl groups, substituted and unsubstituted heteroaryloxy groups, cyano groups, substituted and unsubstituted silyl groups, and a deuterium atom,
Ar₁ to Ar₄ are independently selected from the group consisting of substituted and unsubstituted alkyl groups, substituted and unsubstituted aryl groups, and substituted and unsubstituted heteroaryl groups,
L denotes a substituted or unsubstituted arylene group or a substituted or unsubstituted heteroarylene group, and
X is independently selected from the group consisting of an oxygen atom, a sulfur atom, a selenium atom, a tellurium atom, N(Z), and C(W₁)(W₂), wherein Z is independently selected from the group consisting of a hydrogen atom, substituted and unsubstituted alkyl groups, substituted and unsubstituted aryl groups, substituted and unsubstituted heteroaryl groups, and a deuterium atom, and W₁ and W₂ are independently selected from the group consisting of a hydrogen atom, substituted and unsubstituted alkyl groups, substituted and unsubstituted aryl groups, substituted and unsubstituted heteroaryl groups, and a deuterium atom.

2. The organic compound according to claim 1, represented by the following general formula [2-1] or [2-2]: 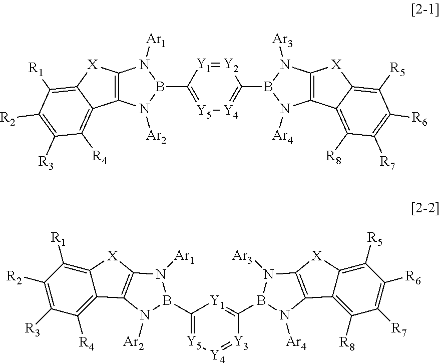
wherein Y₁ to Y₅ are independently selected from the group consisting of C(A) and a nitrogen atom, wherein A is independently selected from the group consisting of a hydrogen atom, halogen atoms, substituted and unsubstituted alkyl groups, substituted and unsubstituted aryl groups, substituted and unsubstituted heteroaryl groups, cyano groups, substituted and unsubstituted silyl groups, and a deuterium atom.

3. The organic compound according to claim 1, represented by the following general formula [3-1], [3-2], or [3-3]: 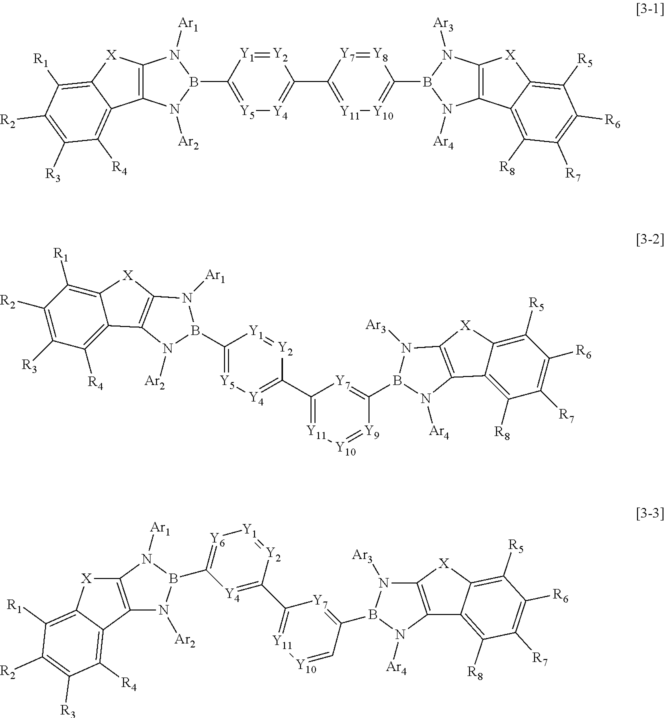
wherein Y₁ and Y₂ and Y₄ to Yu are independently selected from the group consisting of C(A) and a nitrogen atom, wherein A is independently selected from the group consisting of a hydrogen atom, halogen atoms, substituted and unsubstituted alkyl groups, substituted and unsubstituted aryl groups, substituted and unsubstituted heteroaryl groups, cyano groups, substituted and unsubstituted silyl groups, and a deuterium atom, and
when Y₂ and Y₇, and Y₄ and Y₁₁ are C(A), A's are optionally bonded together to form a ring.

4. The organic compound according to claim 1, represented by the following general formula [4-1], [4-2], [4-3], or [4-4]: 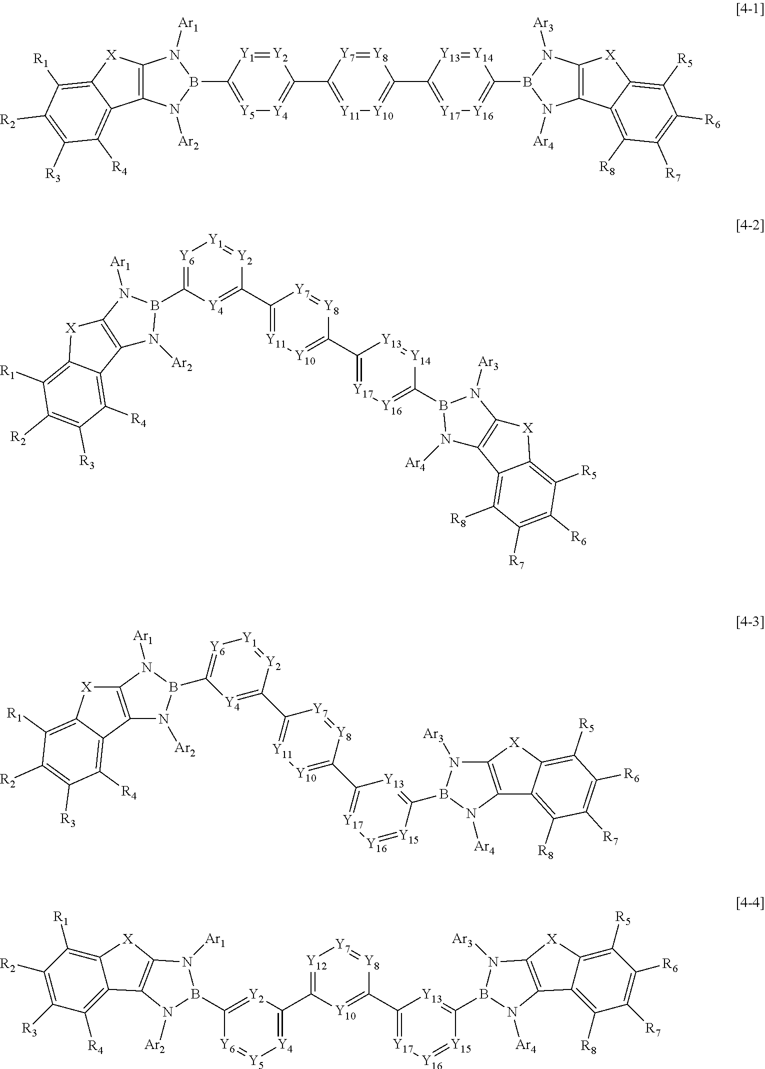
wherein Y₁ and Y₂, Y₄ to Y₈, and Y₁₀ to Y₁₇ are independently selected from the group consisting of C(A) and a nitrogen atom, wherein A is independently selected from the group consisting of a hydrogen atom, halogen atoms, substituted and unsubstituted alkyl groups, substituted and unsubstituted aryl groups, substituted and unsubstituted heteroaryl groups, cyano groups, substituted and unsubstituted silyl groups, and a deuterium atom,
in the general formula [4-1], [4-2], or [4-3], when Y₂ and Y₇, Y₄ and Y₁₁, Y₈ and Y₁₃, and Y₁₀ and Y₁₇ are C(A), A's are optionally bonded together to form a ring, and
in the general formula [4-4], when Y₂ and Y₁₂, Y₄ and Y₁₀, Y₈ and Y₁₃, and Y₁₀ and Y₁₇ are C(A), A's are optionally bonded together to form a ring.

5. The organic compound according to claim 1, represented by the following general formula [5-1] or [5-2]: 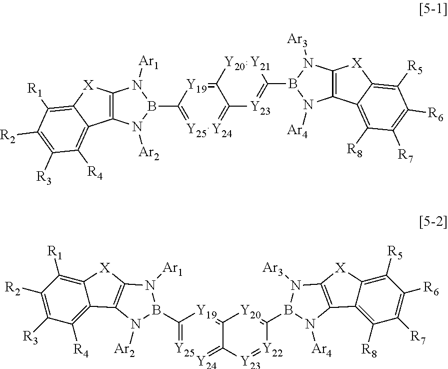
wherein Y₁₉ to Y₂₅ are independently selected from the group consisting of C(A) and a nitrogen atom, wherein A is independently selected from the group consisting of a hydrogen atom, halogen atoms, substituted and unsubstituted alkyl groups, substituted and unsubstituted aryl groups, substituted and unsubstituted heteroaryl groups, cyano groups, substituted and unsubstituted silyl groups, and a deuterium atom.

6. The organic compound according to claim 1, represented by the following general formula [6]: 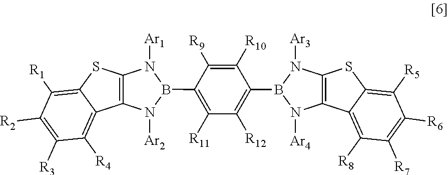
wherein R₉ to R₁₂ are independently selected from the group consisting of a hydrogen atom, halogen atoms, substituted and unsubstituted alkyl groups, substituted and unsubstituted aryl groups, substituted and unsubstituted heteroaryl groups, cyano groups, substituted and unsubstituted silyl groups, and a deuterium atom.

7. The organic compound according to claim 1, represented by the following general formula [7]: 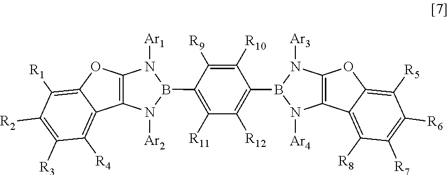
wherein R₉ to R₁₂ are independently selected from the group consisting of a hydrogen atom, halogen atoms, substituted and unsubstituted alkyl groups, substituted and unsubstituted aryl groups, substituted and unsubstituted heteroaryl groups, cyano groups, substituted and unsubstituted silyl groups, and a deuterium atom.

8. The organic compound according to claim 1, represented by the following general formula [8]: 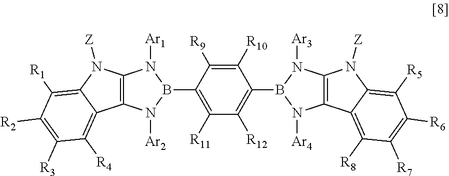
wherein R₉ to R₁₂ are independently selected from the group consisting of a hydrogen atom, halogen atoms, substituted and unsubstituted alkyl groups, substituted and unsubstituted aryl groups, substituted and unsubstituted heteroaryl groups, cyano groups, substituted and unsubstituted silyl groups, and a deuterium atom.

9. The organic compound according to claim 1, represented by the following general formula [9]: 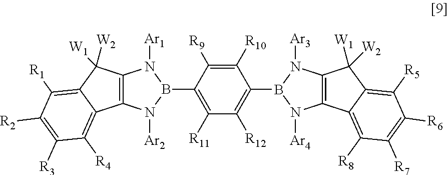
wherein R₉ to R₁₂ are independently selected from the group consisting of a hydrogen atom, halogen atoms, substituted and unsubstituted alkyl groups, substituted and unsubstituted aryl groups, substituted and unsubstituted heteroaryl groups, cyano groups, substituted and unsubstituted silyl groups, and a deuterium atom.

10. The organic compound according to claim 1, represented by the following general formula [10]: 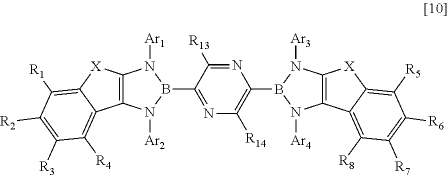
wherein R₁₃ and R₁₄ are independently selected from the group consisting of a hydrogen atom, halogen atoms, substituted and unsubstituted alkyl groups, substituted and unsubstituted aryl groups, substituted and unsubstituted heteroaryl groups, cyano groups, substituted and unsubstituted silyl groups, and a deuterium atom.

11. The organic compound according to claim 1, represented by the following general formula [11]: 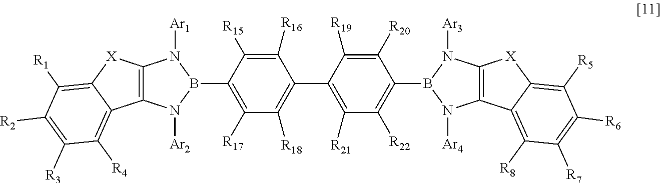
wherein R₁₅ to R₂₂ are independently selected from the group consisting of a hydrogen atom, halogen atoms, substituted and unsubstituted alkyl groups, substituted and unsubstituted aryl groups, substituted and unsubstituted heteroaryl groups, cyano groups, substituted and unsubstituted silyl groups, and a deuterium atom, and
R₁₆ and R₁₉, and R₁₈ and R₂₁ are optionally bonded together to form a ring.

12. The organic compound according to claim 1, represented by the following general formula [12]: 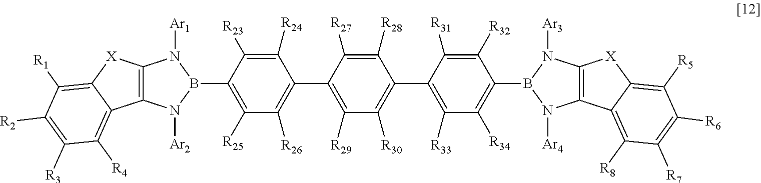
wherein R₂₃ to R₃₄ are independently selected from the group consisting of a hydrogen atom, halogen atoms, substituted and unsubstituted alkyl groups, substituted and unsubstituted aryl groups, substituted and unsubstituted heteroaryl groups, cyano groups, substituted and unsubstituted silyl groups, and a deuterium atom, and
R₂₄ and R₂₇, R₂₆ and R₂₉, R₂₈ and R₃₁, and R₃₀ and R₃₃ are optionally bonded together to form a ring.

13. The organic compound according to claim 1, represented by the following general formula [13]: 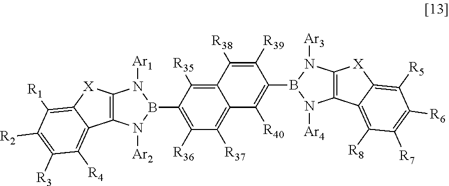
wherein R₃₅ to R₄₀ are independently selected from the group consisting of a hydrogen atom, halogen atoms, substituted and unsubstituted alkyl groups, substituted and unsubstituted aryl groups, substituted and unsubstituted heteroaryl groups, cyano groups, substituted and unsubstituted silyl groups, and a deuterium atom.

14. The organic compound according to claim 1, represented by the following general formula [14]: 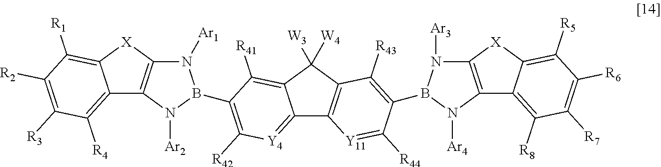
wherein R₄₁ to R₄₄ are independently selected from the group consisting of a hydrogen atom, halogen atoms, substituted and unsubstituted alkyl groups, substituted and unsubstituted aryl groups, substituted and unsubstituted heteroaryl groups, cyano groups, substituted and unsubstituted silyl groups, and a deuterium atom, and
W₃ and W₄ are independently selected from the group consisting of a hydrogen atom, substituted and unsubstituted alkyl groups, substituted and unsubstituted aryl groups, substituted and unsubstituted heteroaryl groups, and a deuterium atom.

15. An organic light-emitting element comprising:
a first electrode;
a second electrode; and
one or more organic compound layers between the first electrode and the second electrode,
wherein at least one layer of the organic compound layers contains the organic compound according to claim 1.

16. The organic light-emitting element according to claim 15, wherein the layer containing the organic compound is a light-emitting layer.

17. The organic light-emitting element according to claim 16, further comprising another light-emitting layer on the light-emitting layer, wherein the other light-emitting layer emits light of a color different from an emission color of the light-emitting layer.

18. A display apparatus comprising a plurality of pixels, wherein at least one of the plurality of pixels includes the organic light-emitting element according to claim 15 and a transistor coupled to the organic light-emitting element.

19. A photoelectric conversion apparatus comprising:
an optical unit with a plurality of lenses;
an imaging element configured to receive light passing through the optical unit; and
a display unit configured to display an image taken by the imaging element,
wherein the display unit includes the organic light-emitting element according to claim 15.

20. Electronic equipment comprising:
a display unit including the organic light-emitting element according to claim 15;
a housing in which the display unit is provided; and
a communication unit provided in the housing and configured to communicate with an outside.

21. Alighting apparatus comprising:
a light source including the organic light-emitting element according to claim 15; and
a light-diffusing unit or an optical filter configured to transmit light emitted by the light source.

22. A moving body comprising:
a lamp including the organic light-emitting element according to claim 15; and
a body to which the lamp is provided.

23. An exposure light source for an electrophotographic image-forming apparatus, comprising the organic light-emitting element according to claim 15.
